(19) United States
(12) Patent Application Publication
(10) Pub. No.: US 2024/0295819 A1
(43) Pub. Date: Sep. 5, 2024

(54) COMPOSITION FOR FORMING SILICON-CONTAINING RESIST UNDERLAYER FILM

(71) Applicant: NISSAN CHEMICAL CORPORATION, Tokyo (JP)

(72) Inventors: Satoshi TAKEDA, Toyama-shi (JP); Kodai KATO, Toyama-shi (JP); Wataru SHIBAYAMA, Toyama-shi (JP); Shuhei SHIGAKI, Toyama-shi (JP); Ken ISHIBASHI, Toyama-shi (JP)

(73) Assignee: NISSAN CHEMICAL CORPORATION, Tokyo (JP)

(21) Appl. No.: 18/567,671

(22) PCT Filed: Jun. 10, 2022
(86) PCT No.: PCT/JP2022/023396

§ 371 Date: Dec. 6, 2023

(30) Foreign Application Priority Data
Jun. 11, 2021 (JP) 2021-098049

(51) Int. Cl. G03F 7/11; C09D 183/04

(52) U.S. Cl. CPC G03F 7/11; C09D 183/04

(57) ABSTRACT

A composition for forming a silicon-containing resist underlayer film, the composition including: component [A]: a polysiloxane; and component [C]: a solvent, wherein the polysiloxane contains a constituent unit derived from a hydrolyzable silane (A) having an alkyl iodide group.

### TECHNICAL FIELD

The present invention relates to a composition for forming a silicon-containing resist underlayer film.

### BACKGROUND ART

Conventionally, fine processing by lithography using a photoresist has been performed in manufacturing a semiconductor device. The fine processing is a processing method in which a photoresist thin film is formed on a semiconductor substrate such as a silicon wafer; irradiation with an active ray such as an ultraviolet ray is performed thereon through a mask pattern drawing a semiconductor device pattern; development is performed; the obtained photoresist pattern is used as a protective film to etch the substrate; and thereby fine irregularities corresponding to the pattern is formed on the substrate surface.

In recent years, the degree of integration of semiconductor devices has been increased, and active rays to be used also tend to be shortened from KrF excimer laser (248 nm) to ArF excimer laser (193 nm). With the shortening of the active rays, the influence of active ray reflection from the semiconductor substrate becomes a major problem, and methods of providing a resist underlayer film called an antireflection film (Bottom Anti-Reflective Coating, BARC) between the photoresist and the substrate to be processed have been widely applied.

As advanced microfabrication technology, mass production of 10 nm node devices by double patterning of ArF immersion lithography has been performed. As the next generation technology, preparation for mass production of 7 nm node by double patterning of ArF immersion lithography is in progress. As mass production technology of 5 nm node, which is the after next generation technology, extreme ultraviolet (EUV) lithography having a wavelength of 13.5 nm is a candidate.

As a composition for forming a resist underlayer film for EUV lithography, a composition for forming a silicon-containing resist underlayer film for EUV lithography containing a thermosetting silicon-containing material having a specific repeating unit containing iodine and a crosslinking catalyst has been proposed (Patent Literature 1).

### CITATION LIST

### Patent Literature

Patent Literature 1: JP 2020-84175 A

### SUMMARY OF INVENTION

### Technical Problem

Since the energy density of light increases as the wavelength of active rays used for lithography becomes shorter, the number of photons generated by exposure decreases. The variation in the number of photons causes line width roughness (LWR) of the line pattern. On the other hand, as the exposure amount is increased, the number of photons increases, and variation in the number of photons decreases, but the sensitivity naturally decreases. That is, LWR and sensitivity have a trade-off relationship.

The present invention has been made in view of such circumstances, and an object thereof is to provide a composition for forming a silicon-containing resist underlayer film for forming a resist underlayer film capable of improving the sensitivity of a resist without lowering the LWR of the resist.

### Solution to Problem

As a result of intensive studies to solve the above problems, the present inventors have found that the above problems can be solved, and have completed the present invention having the following gist.

That is, the present invention includes the following.

[1] A composition for forming a silicon-containing resist underlayer film, the composition including:
component [A]: a polysiloxane; and
component [C]: a solvent,
wherein the polysiloxane contains a constituent unit derived from a hydrolyzable silane (A) having an alkyl iodide group.

[2] A composition for forming a silicon-containing resist underlayer film, the composition including:
component [A′]: a polysiloxane;
component [B]: a hydrolyzable silane (A) having an alkyl iodide group; and
component [C]: a solvent.

[3] The composition for forming a silicon-containing resist underlayer film according to [1] or [2], wherein the hydrolyzable silane (A) having an alkyl iodide group is a compound represented by the following formula (A-1):

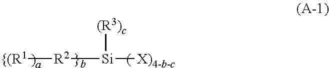

wherein, in the formula (A-1), “a” and “b” each independently represent an integer of 1 to 3,
“c” represents an integer of 0 to 2,
“b+c” represents an integer of 1 to 3,
R¹ represents an alkyl iodide group,
when “a” is 1, R² represents a single bond or a (a+1)-valent group other than a saturated hydrocarbon group, and when “a” is 2 or 3, R² represents a (a+1)-valent group other than a saturated hydrocarbon group,
R³ represents: an optionally substituted alkyl group, an optionally substituted aryl group, an optionally substituted aralkyl group, an optionally substituted halogenated alkyl group (excluding an alkyl iodide group), an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group; an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group; or a combination of two or more thereof,
X represents an alkoxy group, an aralkyloxy group, an acyloxy group, or a halogen atom, and
for a plurality of each of R¹, R², R³, and X, the plurality of R¹, R², R³, and X may be the same or different.

[4] The composition for forming a silicon-containing resist underlayer film according to [3], wherein the compound represented by the formula (A-1) is a compound represented by the following formula (A-2):

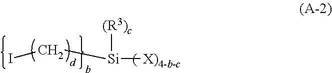

wherein, in the formula (A-2), “b” represents an integer of 1 to 3,
“c” represents an integer of 0 to 2,
“d” represents an integer of 1 to 20,
“b+c” represents an integer of 1 to 3,
R³ represents: an optionally substituted alkyl group, an optionally substituted aryl group, an optionally substituted aralkyl group, an optionally substituted halogenated alkyl group (excluding an alkyl iodide group), an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group; an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group; or a combination of two or more thereof,
X represents an alkoxy group, an aralkyloxy group, an acyloxy group, or a halogen atom, and
for a plurality of each of R³, X, and a group of —(CH₂)_{d}—I, the plurality of R³, X, and a group of —(CH₂)_{d}—I may be the same or different.

[5] The composition for forming a silicon-containing resist underlayer film according to any of [1] to [4], wherein the component [C] contains an alcohol-based solvent.

[6] The composition for forming a silicon-containing resist underlayer film according to [5], wherein the component [C] contains propylene glycol monoalkyl ether.

[7] The composition for forming a silicon-containing resist underlayer film according to any of [1] to [6], the composition further including component [D]: a curing catalyst.

[8] The composition for forming a silicon-containing resist underlayer film according to any of [1] to [7], the composition further including component [E]: nitric acid.

[9] The composition for forming a silicon-containing resist underlayer film according to any of [1] to [8], wherein the component [C] contains water.

[10] The composition for forming a silicon-containing resist underlayer film according to any of [1] to [9], which is for forming a resist underlayer film for EUV lithography.

[11] The composition for forming a silicon-containing resist underlayer film according to any of [1] to [10], which is used in EUV lithography using a metal oxide resist.

[12] A resist underlayer film, which is a cured product of the composition for forming a silicon-containing resist underlayer film according to any of [1] to [11]

[13] A substrate for semiconductor processing, including: a semiconductor substrate; and the resist underlayer film according to [12].

[14] A method for manufacturing a semiconductor element, the method including:
a step of forming an organic underlayer film on a substrate;
a step of forming a resist underlayer film on the organic underlayer film using the composition for forming a silicon-containing resist underlayer film according to [1] to [11]; and
a step of forming a resist film on the resist underlayer film.

[15] The method for manufacturing a semiconductor element according to [14], wherein, in the step of forming a resist underlayer film, a composition for forming a silicon-containing resist underlayer film filtered through a nylon filter is used.

[16] A patterning process including:
a step of forming an organic underlayer film on a semiconductor substrate;
a step of forming a resist underlayer film by applying and baking the composition for forming a silicon-containing resist underlayer film according to any of [1] to [11] on the organic underlayer film;
a step of forming a resist film by applying a composition for forming a resist film on the resist underlayer film;
a step of obtaining a resist pattern by exposing and developing the resist film;
a step of etching the resist underlayer film by using the resist pattern as a mask; and
a step of etching the organic underlayer film by using the patterned resist underlayer film as a mask.

[17] The patterning process according to [16], further including
a step of removing the resist underlayer film by a wet method using a chemical liquid after the step of etching the organic underlayer film.

### Advantageous Effects of Invention

According to the present invention, it is possible to provide a composition for forming a silicon-containing resist underlayer film for forming a resist underlayer film capable of improving the sensitivity of a resist without lowering the LWR of the resist.

### DESCRIPTION OF EMBODIMENTS

### (Composition for Forming a Silicon-Containing Resist Underlayer Film)

### First Embodiment

The first embodiment of the composition for forming a silicon-containing resist underlayer of the present invention contains a polysiloxane as the component [A] and a solvent as the component [C], and further contains other components as necessary.

The polysiloxane as the component [A] contains a constituent unit (monomer unit or repeating unit) derived from a hydrolyzable silane (A) having an alkyl iodide group.

### Second Embodiment

The second embodiment of the composition for forming a silicon-containing resist underlayer of the present invention contains a polysiloxane as the component [A′], a hydrolyzable silane (A) having an alkyl iodide group as the component [B], and a solvent as the component [C], and further contains other components as necessary.

The resist underlayer film formed from the composition for forming a silicon-containing resist underlayer of the present invention has an alkyl iodide group, thereby improving the sensitivity of a resist without lowering the LWR of the resist.

### <Hydrolysable Silane (A) Having Alkyl Iodide Group>

The alkyl iodide group of the hydrolyzable silane (A) having an alkyl iodide group may be directly bonded to a silicon atom or bonded to a silicon atom via a linking group.

The alkyl iodide group may be linear or branched.

The hydrolyzable silane (A) may have two or more alkyl iodide groups. In that case, the two or more alkyl iodide groups may have the same structure or different structures. In addition, the two or more alkyl iodide groups may be each bonded to one linking group bonded to a silicon atom, or the two or more alkyl iodide groups may be each directly bonded to a silicon atom, or may be bonded via different linking groups.

The number of iodine atoms in one alkyl iodide group may be one or two or more. When the number of iodine atoms in one alkyl iodide group is two or more, the two or more iodine atoms may be bonded to the same carbon atom or may be bonded to different carbon atoms, but are preferably bonded to different carbon atoms.

The carbon atom to which the iodine atom is bonded is preferably a primary carbon atom from the viewpoint of structural stability of the alkyl iodide group.

The number of carbon atoms in the alkyl iodide group is not particularly limited, but is preferably 1 to 20, more preferably 1 to 15, and still more preferably 1 to 10.

The hydrolyzable silane (A) having an alkyl iodide group is preferably a compound represented by the following formula (A-1):

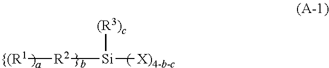

wherein, in the formula (A-1), “a” and “b” each independently represent an integer of 1 to 3,
“c” represents an integer of 0 to 2,
“b+c” represents an integer of 1 to 3,
R¹ represents an alkyl iodide group,
when “a” is 1, R² represents a single bond or a (a+1)-valent group other than a saturated hydrocarbon group, and when “a” is 2 or 3, R² represents a (a+1)-valent group other than a saturated hydrocarbon group,
R³ represents: an optionally substituted alkyl group, an optionally substituted aryl group, an optionally substituted aralkyl group, an optionally substituted halogenated alkyl group (excluding an alkyl iodide group), an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group; an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group; or a combination of two or more thereof,
X represents an alkoxy group, an aralkyloxy group, an acyloxy group, or a halogen atom, and
for a plurality of each of R¹, R², R³, and X, the plurality of R¹, R², R³, and X may be the same or different.

Specific examples and preferred embodiments of the alkyl iodide group of R¹ include the specific examples and preferred embodiments described above for the alkyl iodide group of the hydrolyzable silane (A) having an alkyl iodide group.

The number of atoms of the (a+1)-valent group other than a saturated hydrocarbon group is not particularly limited, but is preferably 1 to 30, and more preferably 1 to 20.

The (a+1)-valent group other than a saturated hydrocarbon group may or may not have a carbon atom.

The (a+1)-valent group other than a saturated hydrocarbon group may or may not have an oxygen atom.

The (a+1)-valent group other than a saturated hydrocarbon group may or may not have a nitrogen atom.

The (a+1)-valent group other than a saturated hydrocarbon group may or may not have a ring structure. Examples of the ring structure include a non-aromatic ring and an aromatic ring. Examples of the aromatic ring include an aromatic hydrocarbon ring and an aromatic heterocyclic ring.

The (a+1)-valent group other than a saturated hydrocarbon group may have a saturated hydrocarbon group as a partial structure.

The compound represented by the formula (A-1) is preferably a compound represented by the following formula (A-2):

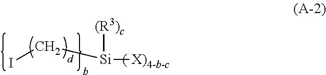

wherein, in the formula (A-2), “b” represents an integer of 1 to 3,
“c” represents an integer of 0 to 2,
“d” represents an integer of 1 to 20,
“b+c” represents an integer of 1 to 3,
R³ represents: an optionally substituted alkyl group, an optionally substituted aryl group, an optionally substituted aralkyl group, an optionally substituted halogenated alkyl group (excluding an alkyl iodide group), an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group; an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group; or a combination of two or more thereof,
X represents an alkoxy group, an aralkyloxy group, an acyloxy group, or a halogen atom, and
for a plurality of each of R³, X, and a group of —(CH₂)_{d}—I, the plurality of R³, X, and a group of —(CH₂)_{d}—I may be the same or different.
“d” is preferably 1 to 20, more preferably 1 to 15, and even more preferably 1 to 10.

### «R³ in Formulas (A-1) and (A-2)»

The alkyl group may be linear, branched, or cyclic, and the number of carbon atoms thereof is not particularly limited, but is preferably 40 or less, more preferably 30 or less, still more preferably 20 or less, and still more preferably 10 or less.

Specific examples of the linear or branched alkyl group as the alkyl group include a methyl group, an ethyl group, a n-propyl group, an i-propyl group, a n-butyl group, an i-butyl group, a s-butyl group, a t-butyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group.

In the present specification, “i” means “iso”, “s” means “sec”, and “t” means “tert”.

Specific examples of the cyclic alkyl group include: cycloalkyl groups, such as a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group; and bridged cyclic cycloalkyl groups, such as a bicyclobutyl group, a bicyclopentyl group, a bicyclohexyl group, a bicycloheptyl group, a bicyclooctyl group, a bicyclononyl group, and a bicyclodecyl group.

The aryl group may be any of a phenyl group, a monovalent group derived by removing one hydrogen atom from a condensed cyclic aromatic hydrocarbon compound, and a monovalent group derived by removing one hydrogen atom from a ring-linked aromatic hydrocarbon compound, and the number of carbon atoms is not particularly limited, but is preferably 40 or less, more preferably 30 or less, and still more preferably 20 or less.

Examples of the aryl group include an aryl group having 6 to 20 carbon atoms, and examples thereof include a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 5-naphthacenyl group, a 2-chrysenyl group, a 1-pyrenyl group, a 2-pyrenyl group, a pentacenyl group, a benzopyrenyl group, and a triphenylenyl group; a biphenyl-2-yl group (o-biphenylyl group), a biphenyl-3-yl group (m-biphenylyl group), a biphenyl-4-yl group (p-biphenylyl group), a paraterphenyl-4-yl group, a metaterphenyl-4-yl group, an orthoterphenyl-4-yl group, a 1,1′-binaphthyl-2-yl group, and a 2,2′-binaphthyl-1-yl group, but are not limited thereto.

The aralkyl group is an alkyl group substituted with an aryl group, and specific examples of such an aryl group and an alkyl group include the same groups as those described above. The number of carbon atoms in the aralkyl group is not particularly limited, but is preferably 40 or less, more preferably 30 or less, and still more preferably 20 or less.

Specific examples of the aralkyl group include a phenylmethyl group (benzyl group), a 2-phenylethylene group, a 3-phenyl-n-propyl group, a 4-phenyl-n-butyl group, a 5-phenyl-n-pentyl group, a 6-phenyl-n-hexyl group, a 7-phenyl-n-heptyl group, an 8-phenyl-n-octyl group, a 9-phenyl-n-nonyl group, and a 10-phenyl-n-decyl group, but are not limited thereto.

The halogenated alkyl group, the halogenated aryl group, and the halogenated aralkyl group are each an alkyl group, an aryl group, and an aralkyl group substituted with one or more halogen atoms, and specific examples of such an alkyl group, an aryl group, and an aralkyl group include the same groups as those described above.

Examples of the halogen atom include a fluorine atom, a chlorine atom, a bromine atom, and an iodine atom.

The number of carbon atoms in the halogenated alkyl group is not particularly limited, but is preferably 40 or less, more preferably 30 or less, still more preferably 20 or less, and still more preferably 10 or less.

Specific examples of the halogenated alkyl group include a monofluoromethyl group, a difluoromethyl group, a trifluoromethyl group, a bromodifluoromethyl group, a 2-chloroethyl group, a 2-bromoethyl group, a 1,1-difluoroethyl group, a 2,2,2-trifluoroethyl group, a 1,1,2,2-tetrafluoroethyl group, a 2-chloro-1,1,2-trifluoroethyl group, a pentafluoroethyl group, a 3-bromopropyl group, a 2,2,3,3-tetrafluoropropyl group, a 1,1,2,3,3,3-hexafluoropropyl group, a 1,1,1,3,3,3-hexafluoropropane-2-yl group, a 3-bromo-2-methylpropyl group, a 4-bromobutyl group, and a perfluoropentyl group, but are not limited thereto.

The number of carbon atoms in the halogenated aryl group is not particularly limited, but is preferably 40 or less, more preferably 30 or less, and still more preferably 20 or less.

Specific examples of the halogenated aryl group include a 2-fluorophenyl group, a 3-fluorophenyl group, a 4-fluorophenyl group, a 2,3-difluorophenyl group, a 2,4-difluorophenyl group, a 2,5-difluorophenyl group, a 2,6-difluorophenyl group, a 3,4-difluorophenyl group, a 3,5-difluorophenyl group, a 2,3,4-trifluorophenyl group, a 2,3,5-trifluorophenyl group, a 2,3,6-trifluorophenyl group, a 2,4,5-trifluorophenyl group, a 2,4,6-trifluorophenyl group, a 3,4,5-trifluorophenyl group, a 2,3,4,5-tetrafluorophenyl group, a 2,3,4,6-tetrafluorophenyl group, a 2,3,5,6-tetrafluorophenyl group, a pentafluorophenyl group, a 2-fluoro-1-naphthyl group, a 3-fluoro-1-naphthyl group, a 4-fluoro-1-naphthyl group, a 6-fluoro-1-naphthyl group, a 7-fluoro-1-naphthyl group, an 8-fluoro-1-naphthyl group, a 4,5 difluoro-1-naphthyl group, a 5,7-difluoro-1-naphthyl group, a 5,8-difluoro-1-naphthyl group, a 5,6,7,8-tetrafluoro-1-naphthyl group, a heptafluoro-1-naphthyl group, a 1-fluoro-2-naphthyl group, a 5-fluoro-2-naphthyl group, a 6-fluoro-2-naphthyl group, a 7-fluoro-2-naphthyl group, a 5,7-difluoro-2-naphthyl group, a heptafluoro-2-naphthyl group, and groups obtained by optionally substituting a fluorine atom (fluoro group) of these groups with a chlorine atom (chloro group), a bromine atom (bromo group), or an iodine atom (iodine group), but not limited thereto.

The number of carbon atoms in the halogenated aralkyl group is not particularly limited, but is preferably 40 or less, more preferably 30 or less, and still more preferably 20 or less.

Specific examples of the halogenated aralkyl group include a 2-fluorobenzyl group, a 3-fluorobenzyl group, a 4-fluorobenzyl group, a 2,3-difluorobenzyl group, a 2,4-difluorobenzyl group, a 2,5-difluorobenzyl group, a 2,6-difluorobenzyl group, a 3,4-difluorobenzyl group, a 3,5-difluorobenzyl group, a 2,3,4-trifluorobenzyl group, a 2,3,5-trifluorobenzyl group, a 2,3,6-trifluorobenzyl group, a 2,4,5-trifluorobenzyl group, a 2,4,6-trifluorobenzyl group, a 2,3,4,5-tetrafluorobenzyl group, a 2,3,4,6-tetrafluorobenzyl group, a 2,3,5,6-tetrafluorobenzyl group, a 2,3,4,5,6-pentafluorobenzyl group, and the like, and include groups obtained by optionally substituting a fluorine atom (fluoro group) of these groups with a chlorine atom (chloro group), a bromine atom (bromo group), or an iodine atom (iodine group), but not limited thereto.

The alkoxyalkyl group, the alkoxyaryl group, and the alkoxyaralkyl group are each an alkyl group, an aryl group, and an aralkyl group substituted with one or more alkoxy groups, and specific examples of such an alkyl group, an aryl group, and an aralkyl group include the same groups as those described above.

Examples of the alkoxy group as a substituent include an alkoxy group having at least any of a linear, branched, and cyclic alkyl moiety having 1 to 20 carbon atoms.

Examples of the linear or branched alkoxy group include a methoxy group, an ethoxy group, an n-propoxy group, an i-propoxy group, an n-butoxy group, an i-butoxy group, an s-butoxy group, a t-butoxy group, an n-pentoxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, a n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, and a 1-ethyl-2-methyl-n-propoxy group.

Examples of the cyclic alkoxy group include a cyclopropoxy group, a cyclobutoxy group, a 1-methyl-cyclopropoxy group, a 2-methyl-cyclopropoxy group, a cyclopentyloxy group, a 1-methyl-cyclobutoxy group, a 2-methyl-cyclobutoxy group, a 3-methyl-cyclobutoxy group, a 1,2-dimethyl-cyclopropoxy group, a 2,3-dimethyl-cyclopropoxy group, a 1-ethyl-cyclopropoxy group, a 2-ethyl-cyclopropoxy group, a cyclohexyloxy group, a 1-methyl-cyclopentyloxy group, a 2-methyl-cyclopentyloxy group, a 3-methyl-cyclopentyloxy group, a 1-ethyl-cyclobutoxy group, a 2-ethyl-cyclobutoxy group, a 3-ethyl-cyclobutoxy group, a 1,2-dimethyl-cyclobutoxy group, 1,3-dimethyl-cyclobutoxy group, 2,2-dimethyl-cyclobutoxy group, 2,3-dimethyl-cyclobutoxy group, 2,4-dimethyl-cyclobutoxy group, 3,3-dimethyl-cyclobutoxy group, 1-n-propyl-cyclopropoxy group, 2-n-propyl-cyclopropoxy group, 1-i-propyl-cyclopropoxy group, 2-i-propyl-cyclopropoxy group, 1,2,2-trimethyl-cyclopropoxy group, 1,2,3-trimethyl-cyclopropoxy group, 2,2,3-trimethyl-cyclopropoxy group, 1-ethyl-2-methyl-cyclopropoxy group, 2-ethyl-1-methyl-cyclopropoxy group, 2-ethyl-2-methyl-cyclopropoxy group, 2-ethyl-3-methyl-cyclopropoxy group, and the like.

Specific examples of the alkoxyalkyl group include lower (about 5 or less carbon atoms) alkyloxy lower (about 5 or less carbon atoms) alkyl groups such as a methoxymethyl group, an ethoxymethyl group, a 1-ethoxyethyl group, a 2-ethoxyethyl group, and an ethoxymethyl group, but are not limited thereto.

Specific examples of the alkoxyaryl group include a 2-methoxyphenyl group, a 3-methoxyphenyl group, a 4-methoxyphenyl group, a 2-(1-ethoxy)phenyl group, a 3-(1-ethoxy)phenyl group, a 4-(1-ethoxy)phenyl group, a 2-(2-ethoxy)phenyl group, a 3-(2-ethoxy)phenyl group, a 4-(2-ethoxy)phenyl group, a 2-methoxynaphthalene-1-yl group, a 3-methoxynaphthalene-1-yl group, a 4-methoxynaphthalene-1-yl group, a 5-methoxynaphthalene-1-yl group, a 6-methoxynaphthalene-1-yl group, and a 7-methoxynaphthalene-1-yl group, but are not limited thereto.

Specific examples of the alkoxyaralkyl group include a 3-(methoxyphenyl)benzyl group and a 4-(methoxyphenyl)benzyl group, but are not limited thereto.

The alkenyl group may be linear or branched, and the number of carbon atoms thereof is not particularly limited, but is preferably 40 or less, more preferably 30 or less, still more preferably 20 or less, and still more preferably 10 or less.

Specific examples of the alkenyl group include an ethenyl group (vinyl group), a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, and a 3-cyclohexenyl group, and also include a bridged cyclic alkenyl group such as a bicycloheptenyl group (norbornyl group).

Examples of the substituent in the alkyl group, aryl group, aralkyl group, halogenated alkyl group, halogenated aryl group, halogenated aralkyl group, alkoxyalkyl group, alkoxyaryl group, alkoxyaralkyl group, and alkenyl group described above include an alkyl group, an aryl group, an aralkyl group, a halogenated alkyl group, a halogenated aryl group, a halogenated aralkyl group, an alkoxyalkyl group, an aryloxy group, an alkoxyaryl group, an alkoxyaralkyl group, an alkenyl group, an alkoxy group, and an aralkyloxy group, and specific examples thereof and suitable carbon numbers thereof include the same as those described above or below.

The aryloxy group mentioned in the substituent is a group in which an aryl group is bonded via an oxygen atom (—O—), and specific examples of such an aryl group include the same groups as those described above. The number of carbon atoms in the aryloxy group is not particularly limited, but is preferably 40 or less, more preferably 30 or less, and still more preferably 20 or less, and specific examples thereof include a phenoxy group and a naphthalene-2-yloxy group, but are not limited thereto.

When there are two or more substituents, the substituents may be bonded to each other to form a ring.

Examples of the organic group having an epoxy group include a glycidoxymethyl group, a glycidoxyethyl group, a glycidoxypropyl group, a glycidoxybutyl group, and an epoxy cyclohexyl group.

Examples of the organic group having an acryloyl group include an acryloylmethyl group, an acryloylethyl group, and an acryloylpropyl group.

Examples of the organic group having a methacryloyl group include a methacryloyl methyl group, a methacryloyl ethyl group, and a methacryloyl propyl group.

Examples of the organic group having a mercapto group include a mercaptoethyl group, a mercaptobutyl group, a mercaptohexyl group, a mercaptooctyl group, and a mercaptophenyl group.

Examples of the organic group having an amino group include an amino group, an aminomethyl group, an aminoethyl group, an aminophenyl group, a dimethylaminoethyl group, and a dimethylaminopropyl group, but are not limited thereto. The organic group having an amino group will be described later in more detail.

Examples of the organic group having an alkoxy group include, but are not limited to, a methoxymethyl group and a methoxyethyl group. However, a group in which an alkoxy group is directly bonded to a silicon atom is excluded.

Examples of the organic group having a sulfonyl group include, but are not limited to, a sulfonylalkyl group and a sulfonylaryl group.

Examples of the organic group having a cyano group include a cyanoethyl group, a cyanopropyl group, a cyanophenyl group, and a thiocyanate group.

Examples of the organic group having an amino group include an organic group having at least any of a primary amino group, a secondary amino group, and a tertiary amino group. It is preferable to use a hydrolysis condensate in which a hydrolyzable silane having a tertiary amino group is hydrolyzed with a strong acid to form a counter cation having a tertiary ammonium group. The organic group may contain a hetero atom such as an oxygen atom or a sulfur atom in addition to the nitrogen atom constituting the amino group.

Preferable examples of the organic group having an amino group include a group represented by the following formula (A1).

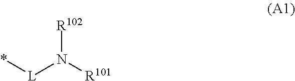

In the formula (A1), R¹⁰¹ and R¹⁰² each independently represent a hydrogen atom or a hydrocarbon group, and L each independently represents an optionally substituted alkylene group. * represents a bonding arm.

Examples of the hydrocarbon group include, but are not limited to, an alkyl group, an alkenyl group, an aryl group, and the like. Specific examples of the alkyl group, alkenyl group, and aryl group include the same groups as those described above for R³.

The alkylene group may be either linear or branched, and the number of carbon atoms is usually 1 to 10 and preferably 1 to 5. Examples thereof include linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group.

Examples of the organic group having an amino group include an amino group, an aminomethyl group, an aminoethyl group, an aminophenyl group, a dimethylaminoethyl group, and a dimethylaminopropyl group, but are not limited thereto.

### «X in Formulas (A-1) and (A-2)»

Examples of the alkoxy group in X include the alkoxy groups exemplified in the description of R³.

Examples of the halogen atom in X include the halogen atoms exemplified in the description of R³.

The aralkyloxy group is a monovalent group derived by removing a hydrogen atom from a hydroxy group of an aralkyl alcohol, and specific examples of the aralkyl group in the aralkyloxy group include the same groups as those described above.

The number of carbon atoms in the aralkyloxy group is not particularly limited, but can be, for example, 40 or less, preferably 30 or less, and more preferably 20 or less.

Specific examples of the aralkyloxy group include a phenylmethyloxy group (benzyloxy group), a 2-phenylethyleneoxy group, a 3-phenyl-n-propyloxy group, a 4-phenyl-n-butyloxy group, a 5-phenyl-n-pentyloxy group, a 6-phenyl-n-hexyloxy group, a 7-phenyl-n-heptyloxy group, an 8-phenyl-n-octyloxy group, a 9-phenyl-n-nonyloxy group, and a 10-phenyl-n-decyloxy group, but are not limited thereto.

The acyloxy group is a monovalent group derived by removing a hydrogen atom from a carboxyl group (—COOH) of a carboxylic acid compound, and typically includes, but is not limited to, an alkylcarbonyloxy group, an arylcarbonyloxy group, or an aralkylcarbonyloxy group derived by removing a hydrogen atom from a carboxyl group of an alkyl carboxylic acid, an aryl carboxylic acid, or an aralkyl carboxylic acid. Specific examples of the alkyl group, the aryl group, and the aralkyl group in the alkyl carboxylic acid, the aryl carboxylic acid, and the aralkyl carboxylic acid include the same groups as those described above.

Specific examples of the acyloxy group include an acyloxy group having 2 to 20 carbon atoms, and examples thereof include a methylcarbonyloxy group, an ethylcarbonyloxy group, a n-propylcarbonyloxy group, an i-propylcarbonyloxy group, a n-butylcarbonyloxy group, an i-butylcarbonyloxy group, a s-butylcarbonyloxy group, a t-butylcarbonyloxy group, a n-pentylcarbonyloxy group, a 1-methyl-n-butylcarbonyloxy group, a 2-methyl-n-butylcarbonyloxy group, a 3-methyl-n-butylcarbonyloxy group, a 1,1-dimethyl-n-propylcarbonyloxy group, a 1,2-dimethyl-n-propylcarbonyloxy group, a 2,2-dimethyl-n-propylcarbonyloxy group, a 1-ethyl-n-propylcarbonyloxy group, a n-hexylcarbonyloxy group, 1-methyl-n-pentylcarbonyloxy group, 2-methyl-n-pentylcarbonyloxy group, 3-methyl-n-pentylcarbonyloxy group, 4-methyl-n-pentylcarbonyloxy group, 1,1-dimethyl-n-butylcarbonyloxy group, 1,2-dimethyl-n-butylcarbonyloxy group, 1,3-dimethyl-n-butylcarbonyloxy group, 2,2-dimethyl-n-butylcarbonyloxy group, 2,3-dimethyl-n-butylcarbonyloxy group, 3,3-dimethyl-n-butylcarbonyloxy group, 1-ethyl-n-butylcarbonyloxy group, 2-ethyl-n-butylcarbonyloxy group, 1,1,2-trimethyl-n-propylcarbonyloxy group, 1,2,2-trimethyl-n-propylcarbonyloxy group, a 1-ethyl-1-methyl-n-propylcarbonyloxy group, a 1-ethyl-2-methyl-n-propylcarbonyloxy group, a phenylcarbonyloxy group, and a tosylcarbonyloxy group.

Specific examples of the hydrolyzable silane (A) having an alkyl iodide group include the following compounds, but the hydrolyzable silane (A) having an alkyl iodide group is not limited to these compounds.

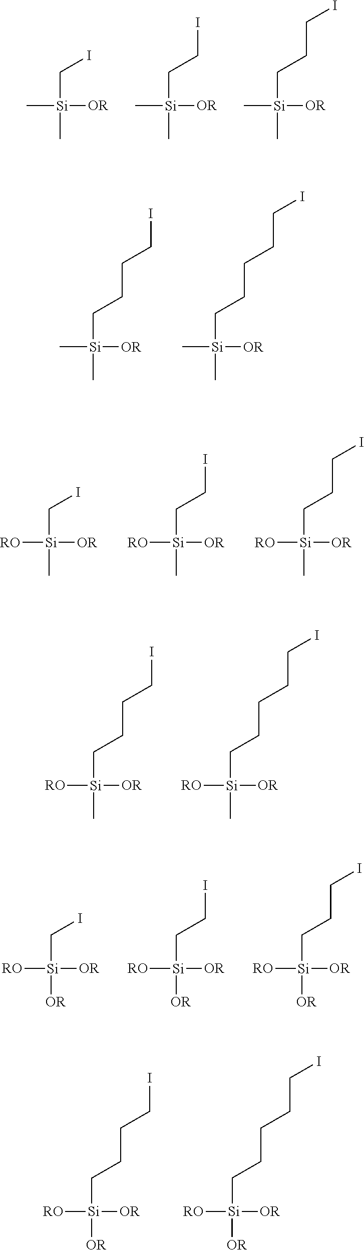

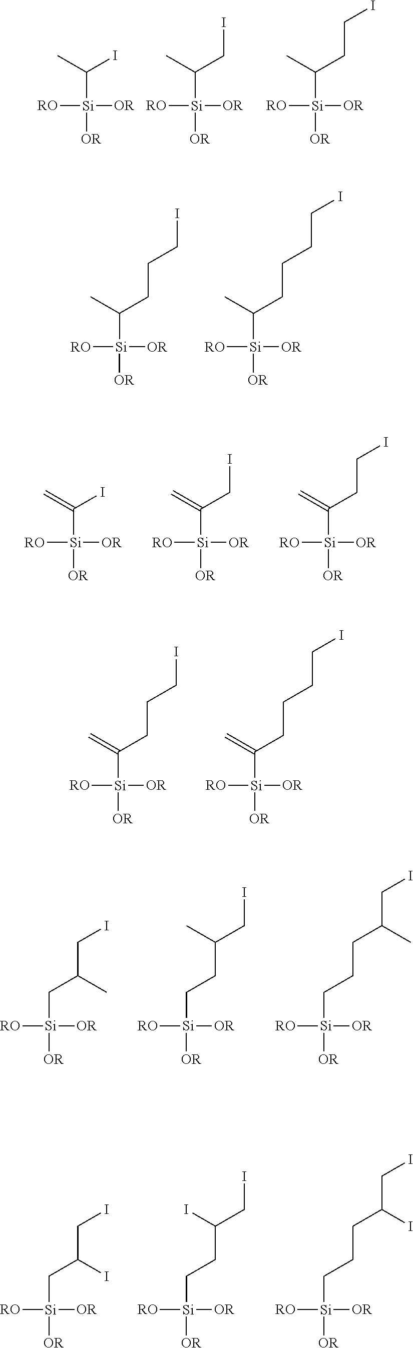

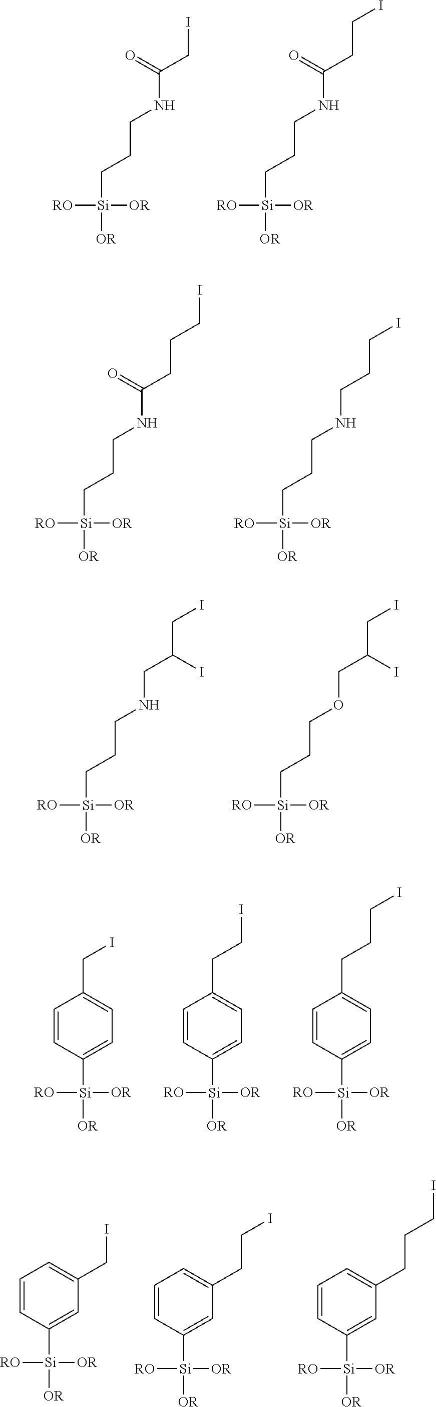

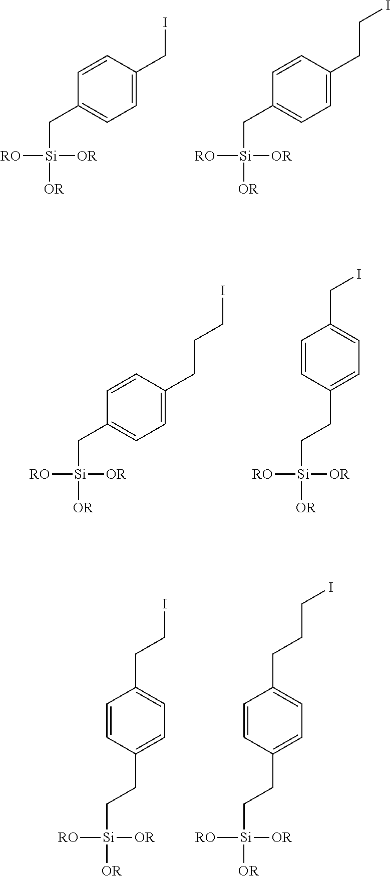

In the formula, R represents a methyl group or an ethyl group.

In the first embodiment, the amount of the hydrolyzable silane (A) in synthesizing [A] the polysiloxane containing a constituent unit derived from a hydrolyzable silane (A) having an alkyl iodide group is preferably 0.01 to 100 parts by mass, more preferably 0.05 to 50 parts by mass, and still more preferably 0.1 to 30 parts by mass, based on 100 parts by mass of the total amount of the hydrolyzable silane used for synthesizing the polysiloxane, from the viewpoint of more sufficiently obtaining the effect of the present invention.

In the second embodiment, the content of the hydrolyzable silane (A) having an alkyl iodide group as the component [B] in the composition for forming a silicon-containing resist underlayer is preferably 0.01 to 100 parts by mass, more preferably 0.05 to 50 parts by mass, and still more preferably 0.1 to 30 parts by mass, based on 100 parts by mass of [A′] the polysiloxane, from the viewpoint of more sufficiently obtaining the effect of the present invention.

### <Component [A] and Component [A′]: Polysiloxane>

The polysiloxane as the component [A] is not particularly limited as long as it contains a constituent unit derived from a hydrolyzable silane (A) having an alkyl iodide group and is a polymer having a siloxane bond.

The polysiloxane as the component [A′] is not particularly limited as long as it is a polymer having a siloxane bond. The polysiloxane as the component [A′] may be a polysiloxane as the component [A].

The polysiloxane may be a modified polysiloxane in which a part of silanol groups is modified, for example, a polysiloxane modified product in which a part of silanol groups is alcohol-modified or acetal-protected.

In addition, the polysiloxane may be, as an example, a hydrolysis condensate of a hydrolyzable silane, or may be a modified product in which at least a part of silanol groups of the hydrolysis condensate is alcohol-modified or acetal-protected (Hereinafter, it may be referred to as a “modified product of a hydrolysis condensate”.). The hydrolyzable silane related to the hydrolysis condensate may contain one or two or more hydrolyzable silanes.

In addition, the polysiloxane as the component [A] or [A′] may have a structure whose main chain is any of cage type, ladder type, linear type, and branched type. Further, as the polysiloxane as the component [A′], a commercially available polysiloxane can be used.

In the present invention, the “hydrolysis condensate” of the hydrolyzable silane, that is, the product of the hydrolysis condensation includes not only a polyorganosiloxane polymer that is a condensation product in which condensation is completely completed but also a polyorganosiloxane polymer that is a partial hydrolysis condensate in which condensation is not completely completed. Such a partial hydrolysis condensate is also a polymer obtained by hydrolysis and condensation of a hydrolyzable silane similarly to a condensation product in which condensation is completely completed, but the polymer is partially stopped in hydrolysis and is not condensed, and therefore has remaining Si—OH groups. In addition to the hydrolysis condensate, an uncondensed hydrolysate (complete hydrolysate, partial hydrolysate) or a monomer (hydrolyzable silane) may remain in the composition for forming a silicon-containing resist underlayer film.

In the present specification, the “hydrolyzable silane” may also be simply referred to as a “silane compound”.

Examples of the polysiloxane as the component [A] include a hydrolysis condensate of a hydrolyzable silane including a hydrolyzable silane (A) having an alkyl iodide group or a modified product thereof.

Examples of the polysiloxane as the component [A] include a hydrolysis condensate of hydrolyzable silanes including a hydrolyzable silane (A) having an alkyl iodide group and at least one hydrolyzable silane represented by the following formula (1) or a modified product thereof.

Examples of the polysiloxane as the component [A′] include a hydrolysis condensate of a hydrolyzable silane including at least one hydrolyzable silane represented by the following formula (1) or a modified product thereof.

«Formula (1)»

R¹ₐSi(R²)₄₋ₐ (1)

In the formula (1), R¹ is a group bonded to a silicon atom, and independently represents: an optionally substituted alkyl group, an optionally substituted aryl group, an optionally substituted aralkyl group, an optionally substituted halogenated alkyl group (excluding an alkyl iodide group), an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group; an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group; or a combination of two or more thereof.

R² is a group or atom bonded to a silicon atom, and independently represents an alkoxy group, an aralkyloxy group, an acyloxy group, or a halogen atom.

“a” represents an integer of 0 to 3.

Specific examples of each group and atom in R¹ in the formula (1), and suitable carbon numbers thereof may include the groups and carbon numbers described above for R³ in the formulas (A-1) and (A-2).

Specific examples of each group and atom in R² in the formula (1), and suitable carbon numbers thereof may include the groups and atoms and carbon numbers described above for X in the formulas (A-1) and (A-2).

### <<<Specific Example of Hydrolyzable Silane Represented by Formula (1)>>>

Specific examples of the hydrolyzable silane represented by the formula (1) include tetramethoxysilane, tetrachlorosilane, tetraacetoxysilane, tetraethoxysilane, tetra-n-propoxysilane, tetra-i-propoxysilane, tetra-n-butoxysilane, methyltrimethoxysilane, methyltrichlorosilane, methyltriacetoxysilane, methyltriethoxysilane, methyltripropoxysilane, methyltributoxysilane, methyltriamyloxysilane, methyltriphenoxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl) methyltrimethoxysilane, (3,4-epoxycyclohexyl) methyltriethoxysilane, β-(3,4-epoxycyclohexyl) ethyltrimethoxysilane, β-(3,4-epoxycyclohexyl) ethyltriethoxysilane, β-(3,4-epoxycyclohexyl) ethyltripropoxysilane, β-(3,4-epoxycyclohexyl) ethyltributoxysilane, β-(3,4-epoxycyclohexyl) ethyltriphenoxysilane, γ-(3,4-epoxycyclohexyl) propyltrimethoxysilane, γ-(3,4-epoxycyclohexyl) propyltriethoxysilane, δ-(3,4-epoxycyclohexyl) butyltrimethoxysilane, δ-(3,4-epoxycyclohexyl) butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, ethyltrimethoxysilane, ethyltriethoxysilane, vinyltrimethoxysilane, vinyltriethoxysilane, vinyltrichlorosilane, vinyltriacetoxysilane, methylvinyldimethoxysilane, methylvinyldiethoxysilane, methylvinyldichlorosilane, methylvinyldiacetoxysilane, dimethylvinylmethoxysilane, dimethylvinylethoxysilane, dimethylvinylchlorosilane, dimethylvinylacetoxysilane, divinyldimethoxysilane, divinyldiethoxysilane, divinyldichlorosilane, divinyldiacetoxysilane, γ-glycidoxypropylvinyldimethoxysilane, γ-glycidoxypropylvinyldiethoxysilane, allyltrimethoxysilane, allyltriethoxysilane, allyltrichlorosilane, allyltriacetoxysilane, allylmethyldimethoxysilane, allylmethyldiethoxysilane, allylmethyldichlorosilane, allylmethyldiacetoxysilane, allyldimethylmethoxysilane, allyldimethylethoxysilane, allyldimethylchlorosilane, allyldimethylacetoxysilane, diallyldimethoxysilane, diallyldiethoxysilane, diallyldichlorosilane, diallyldiacetoxysilane, 3-allylaminopropyltrimethoxysilane, 3-allylaminopropyltriethoxysilane, p-styryltrimethoxysilane, phenyltrimethoxysilane, phenyltriethoxysilane, phenyltrichlorosilane, phenyltriacetoxysilane, phenylmethyldimethoxysilane, phenylmethyldiethoxysilane, phenylmethyldichlorosilane, phenylmethyldiacetoxysilane, phenyldimethylmethoxysilane, phenyldimethylethoxysilane, phenyldimethylchlorosilane, phenyldimethylacetoxysilane, diphenylmethylmethoxysilane, diphenylmethylethoxysilane, diphenylmethylchlorosilane, diphenylmethylacetoxysilane, diphenyldimethoxysilane, diphenyldiethoxysilane, diphenyldichlorosilane, diphenyldiacetoxysilane, triphenylmethoxysilane, triphenylethoxysilane, triphenylacetoxysilane, triphenylchlorosilane, 3-phenylaminopropyltrimethoxysilane, 3-phenylaminopropyltriethoxysilane, dimethoxymethyl-3-(3-phenoxypropylthiopropyl) silane, triethoxy ((2-methoxy-4-(methoxymethyl)phenoxy)methyl)silane, benzyltrimethoxysilane, benzyltriethoxysilane, benzylmethyldimethoxysilane, benzylmethyldiethoxysilane, benzyldimethylmethoxysilane, benzyldimethylethoxysilane, benzyldimethylchlorosilane, phenethyltrimethoxysilane, phenethyltriethoxysilane, phenethyltrichlorosilane, phenethyltriacetoxysilane, phenethylmethyldimethoxysilane, phenethylmethyldiethoxysilane, phenetylmethyldichlorosilane, phenethylmethyldiacetoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenetyltriethoxysilane, methoxyphenetyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, i-propoxyphenyltrimethoxysilane, i-propoxyphenyltriethoxysilane, i-propoxyphenyltriacetoxysilane, i-propoxyphenyltrichlorosilane, i-propoxybenzyltrimethoxysilane, i-propoxybenzyltriethoxysilane, i-propoxybenzyltriacetoxysilane, i-propoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphtyltriacetoxysilane, methoxynaphtyltrichlorosilane, ethoxynaphtyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, thiocyanate propyltriethoxysilane, chloromethyltrimethoxysilane, chloromethyltriethoxysilane, triethoxysilylpropyldiallyl isocyanurate, bicyclo [2,2,1] heptenyltriethoxysilane, benzenesulfonylpropyltriethoxysilane, benzenesulfoneamidepropyltriethoxysilane, dimethylaminopropyltrimethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptomethyldiethoxysilane, methylvinyldimethoxysilane, methylvinyldiethoxysilane, silanes represented by the following formulas (A-1) to (A-41), silanes represented by the following formulas (1-1) to (1-290), and the like, but are not limited thereto.

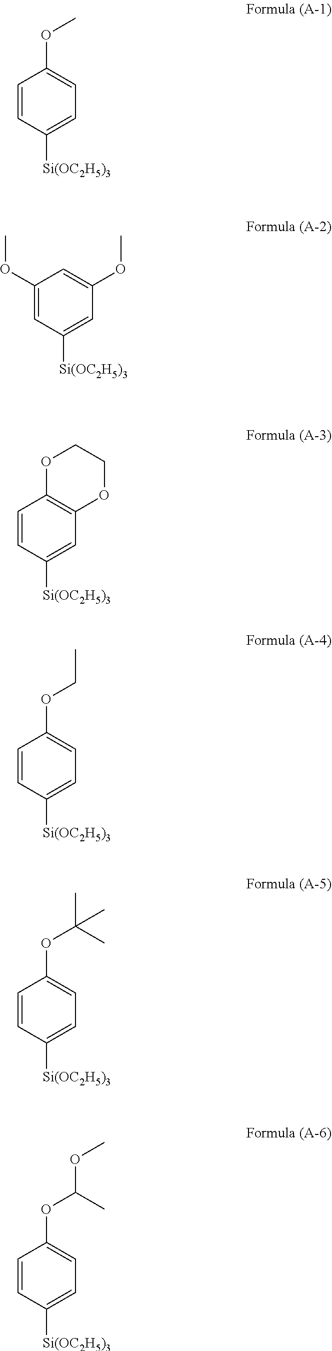

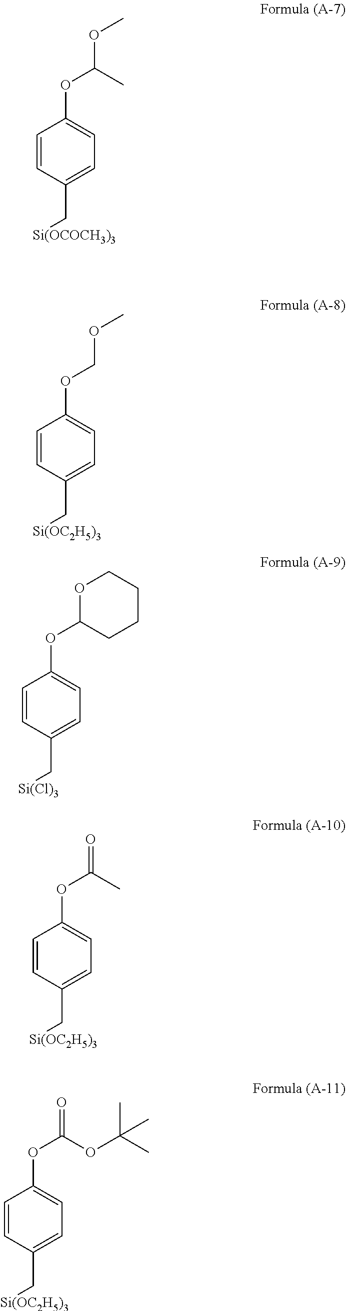

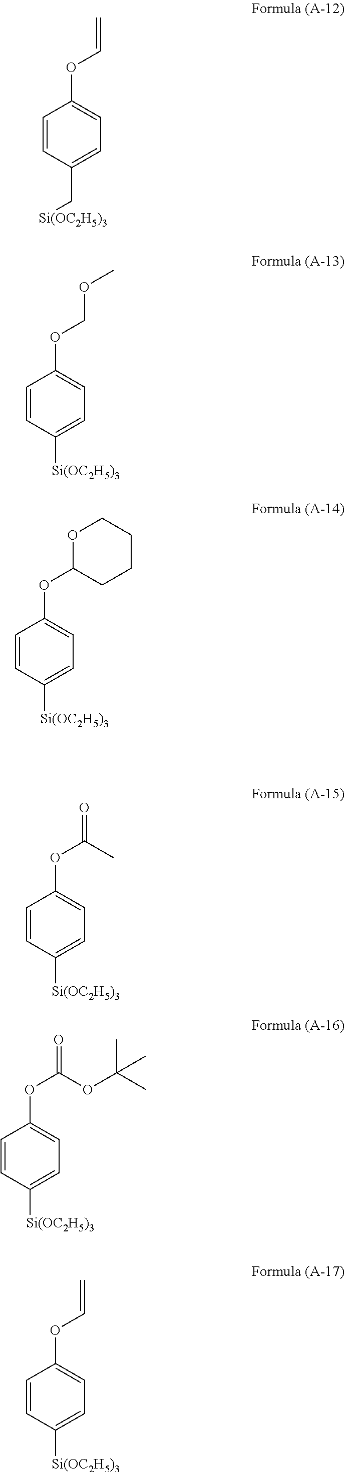

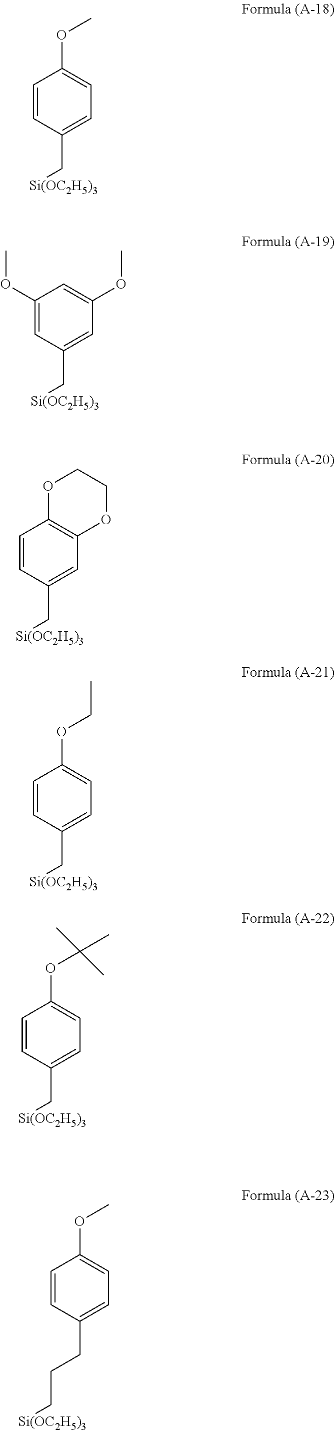

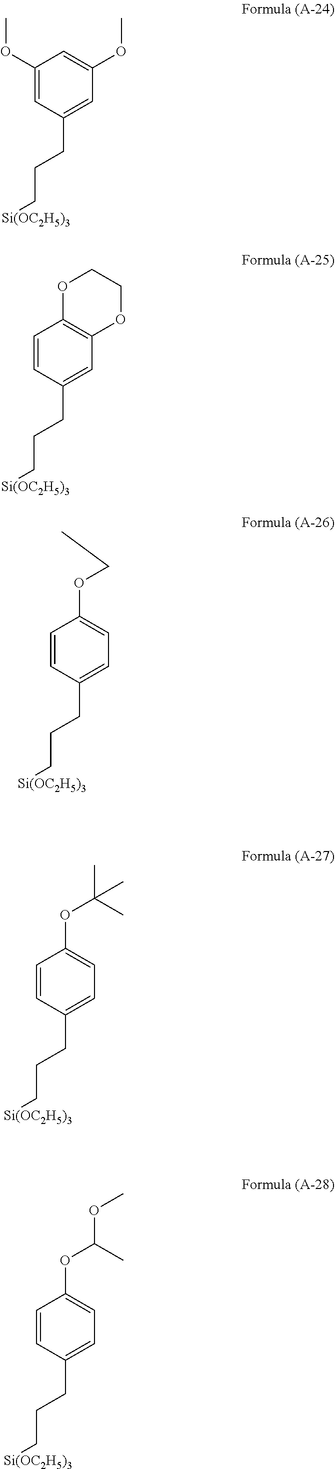

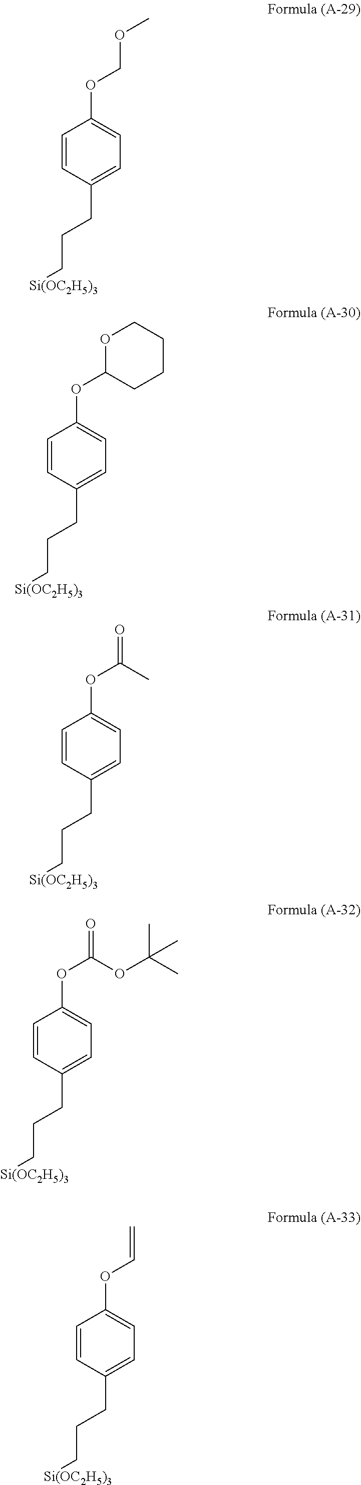

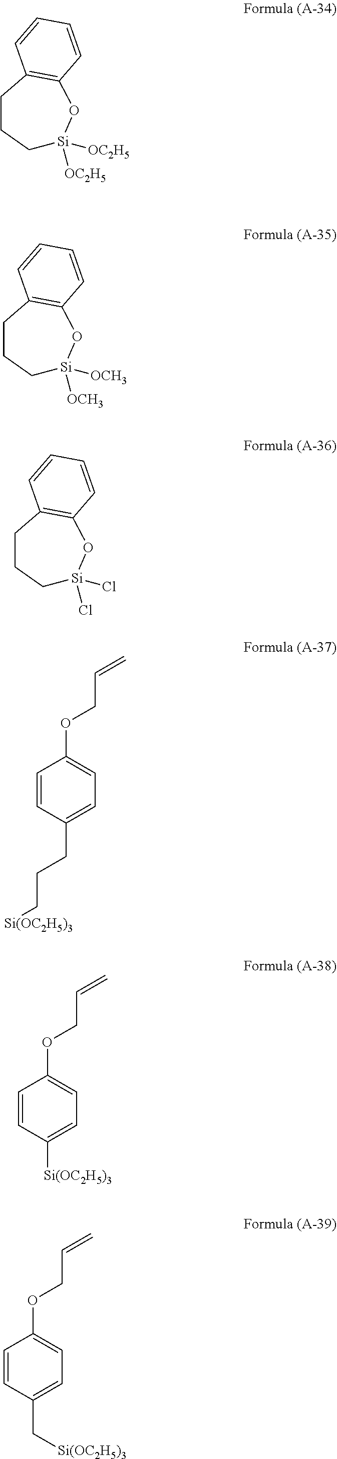

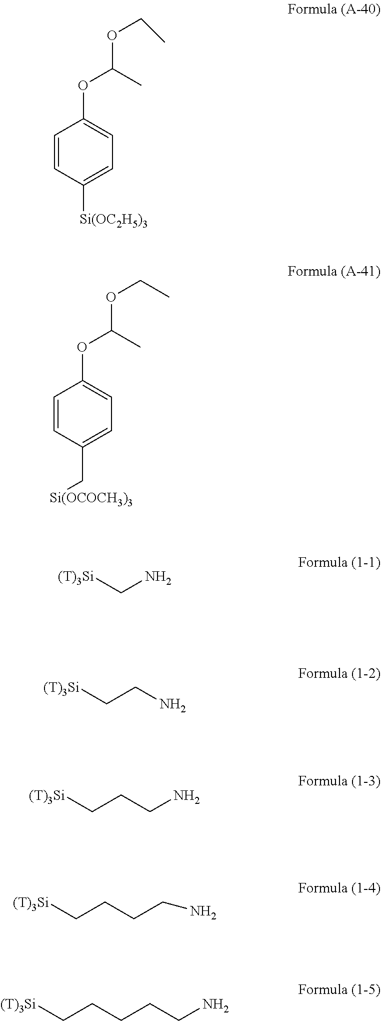

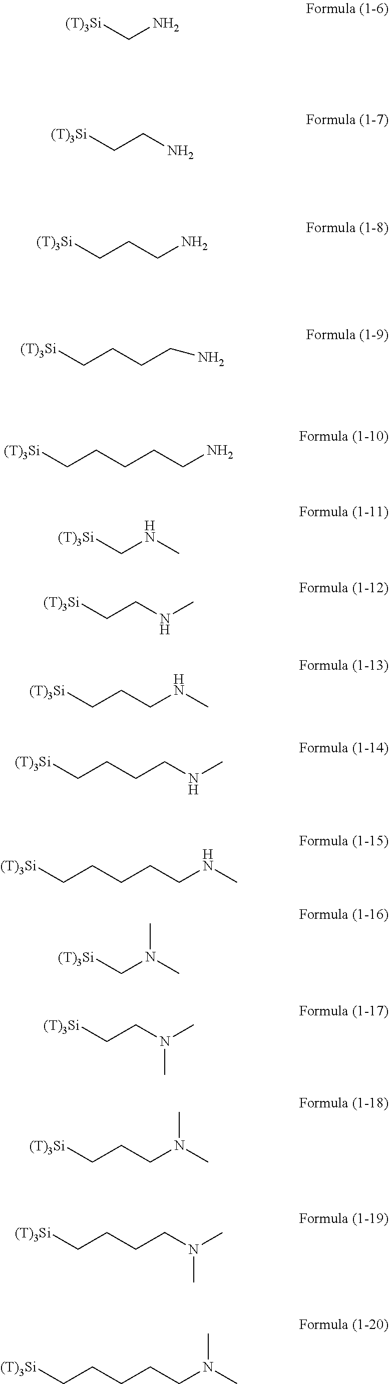

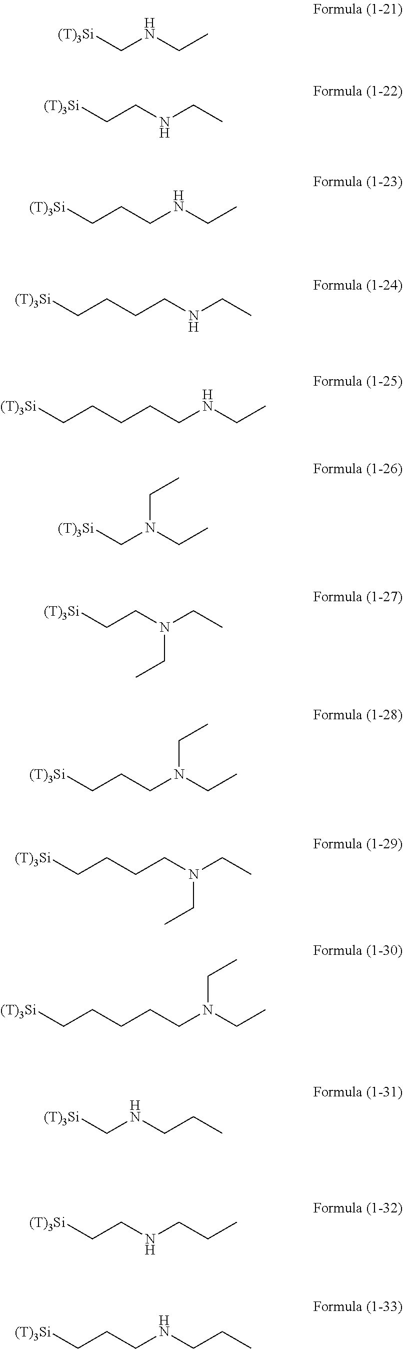

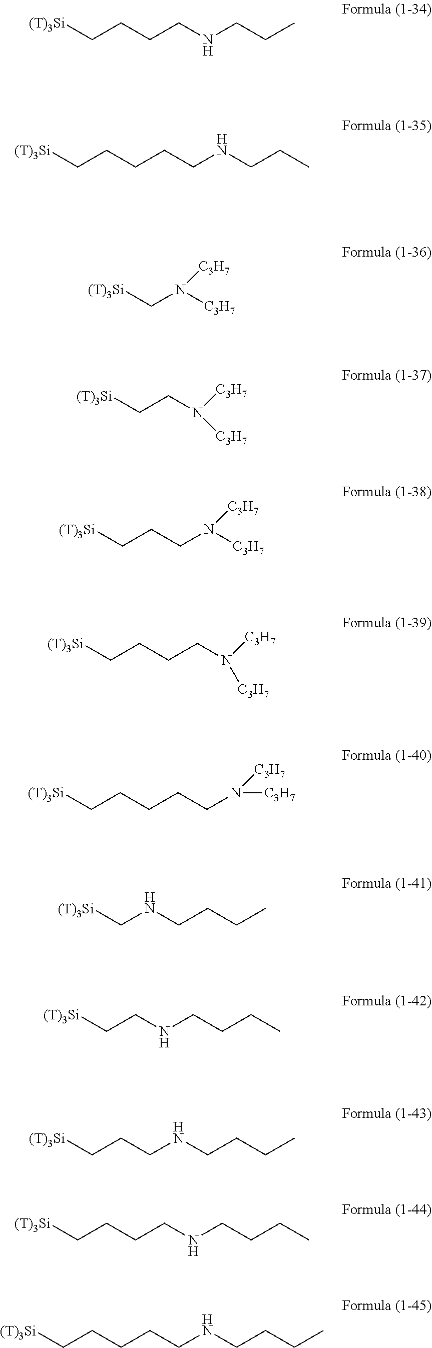

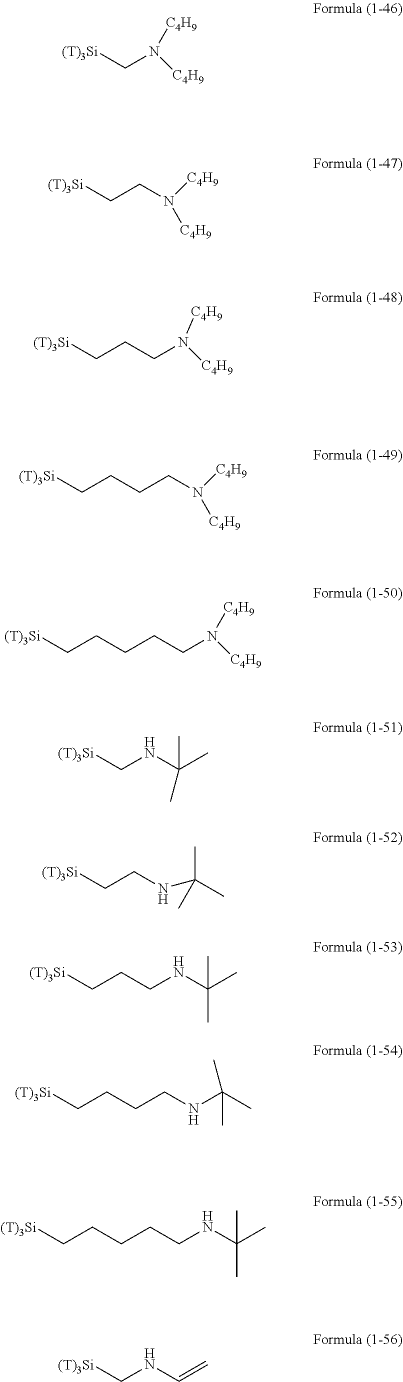

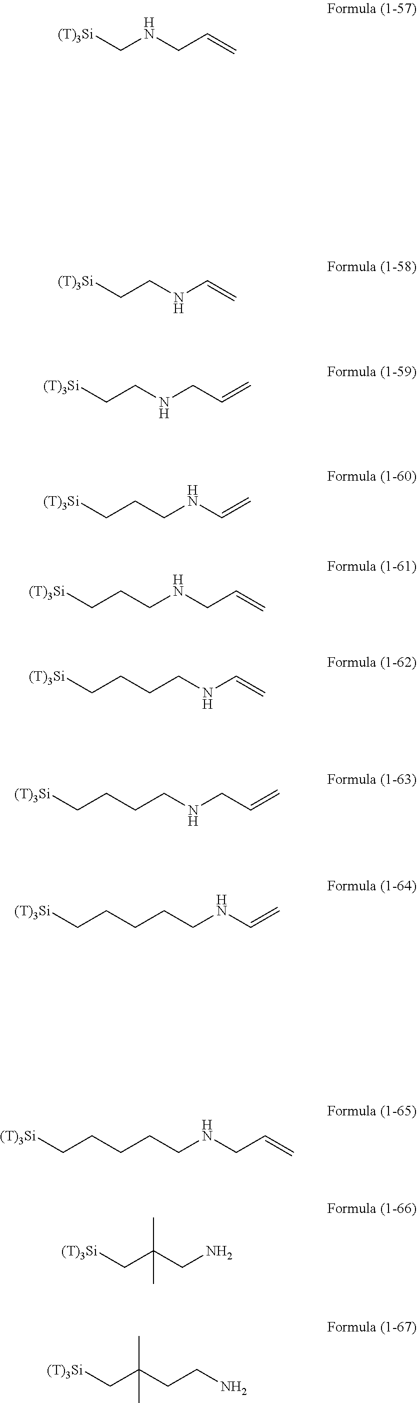

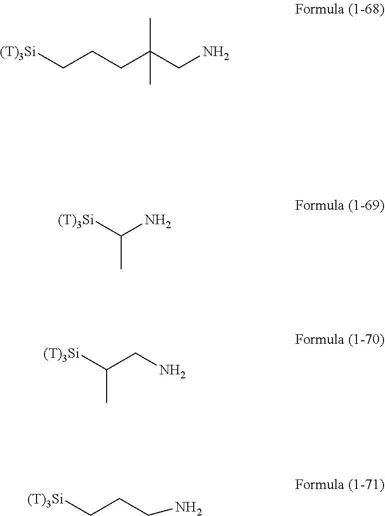

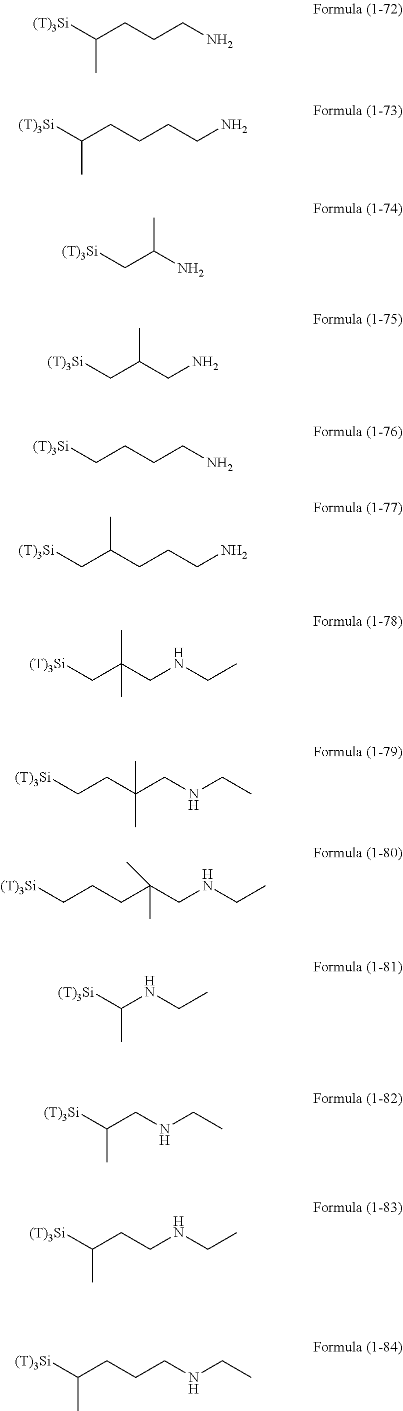

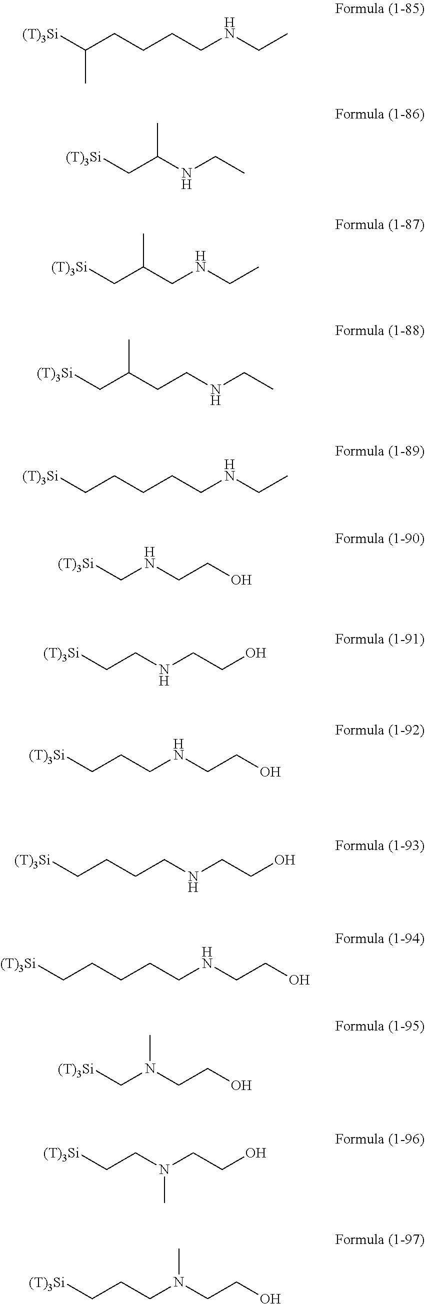

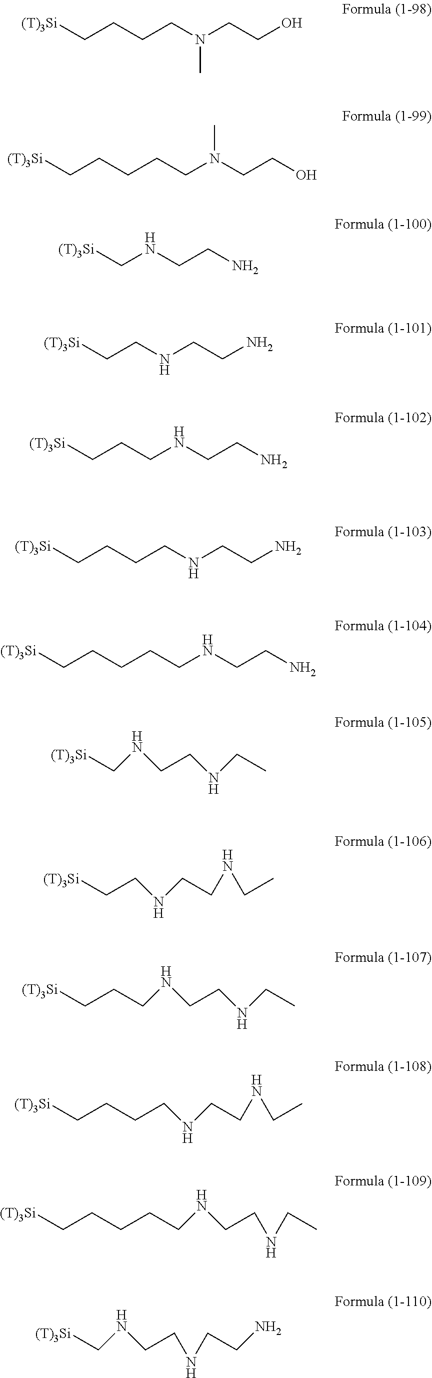

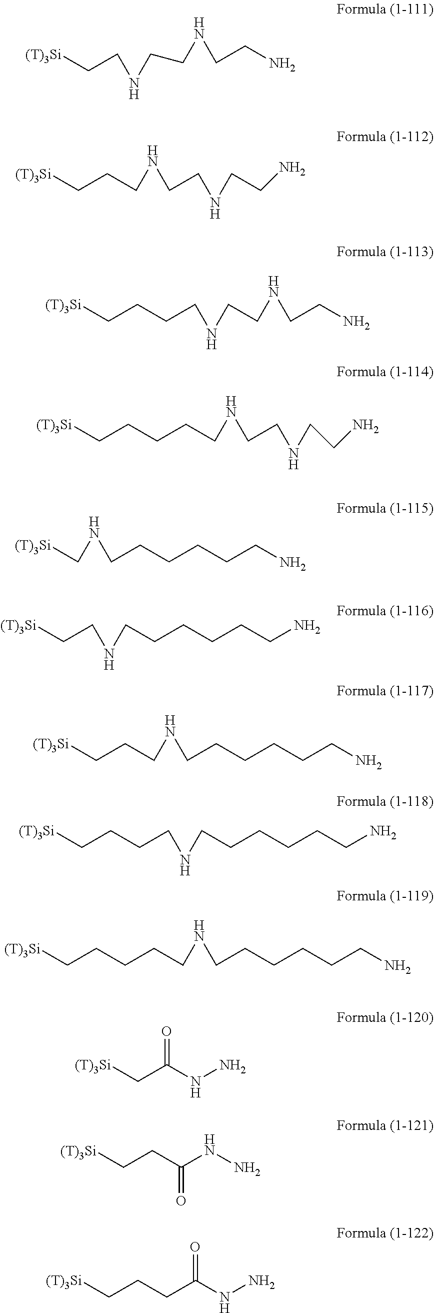

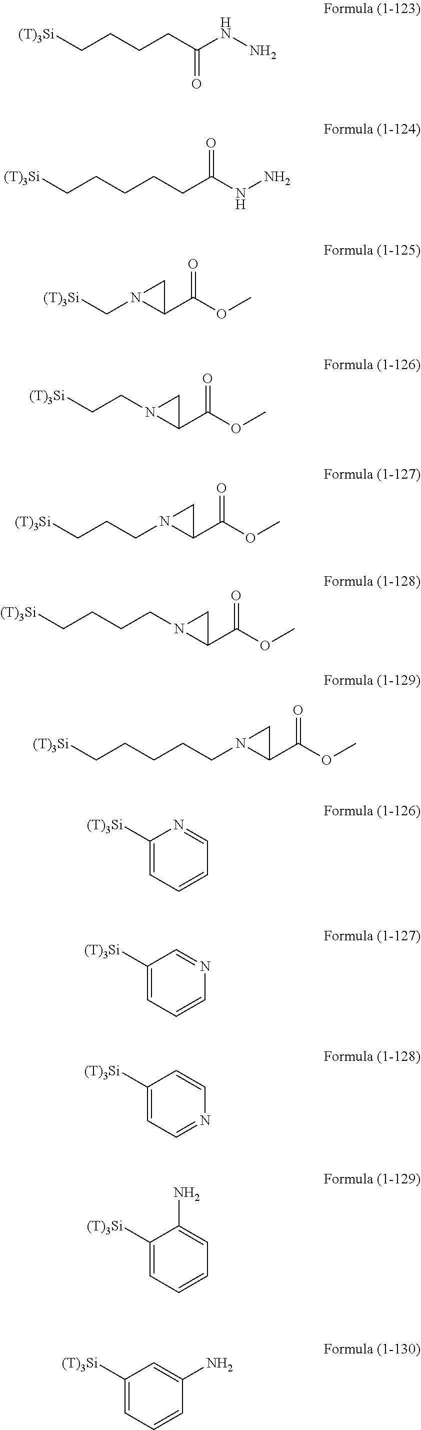

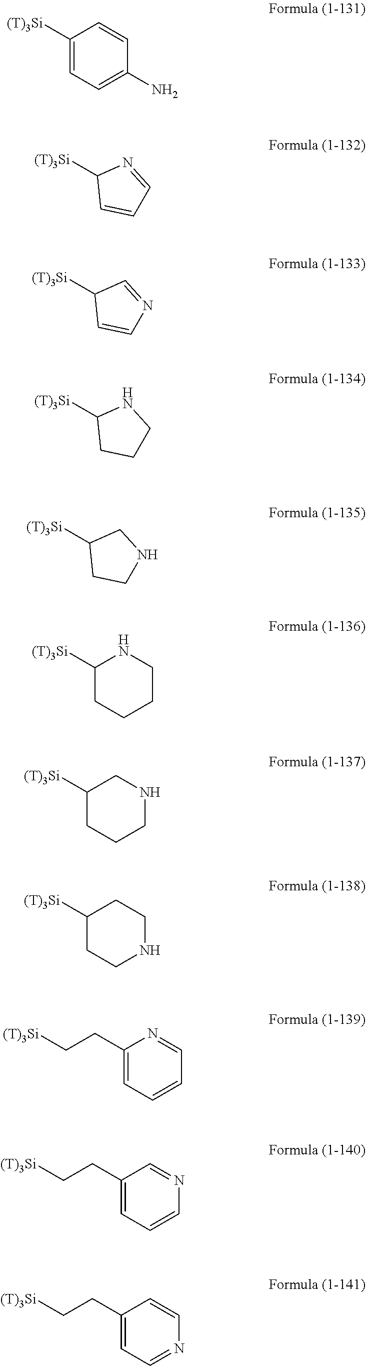

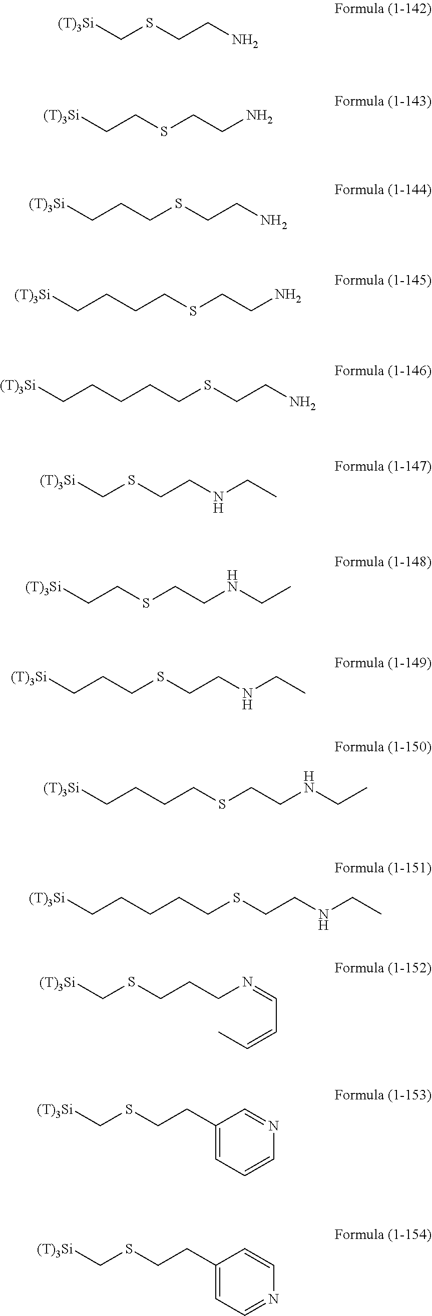

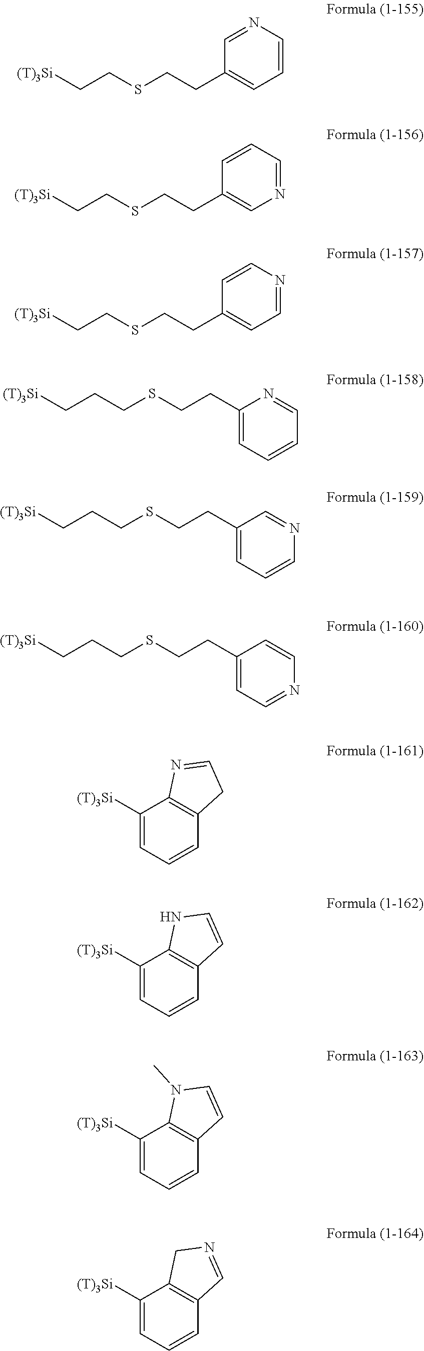

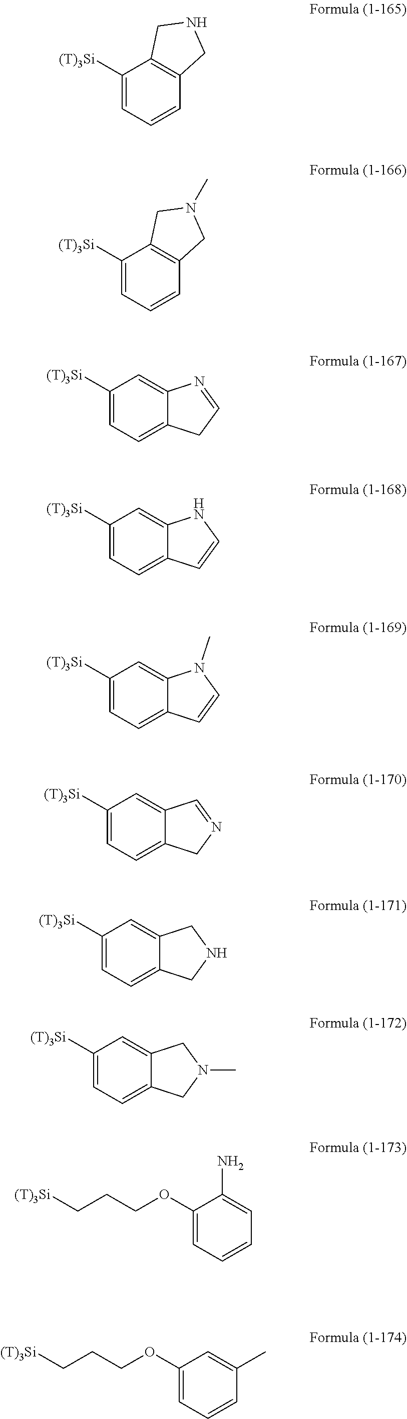

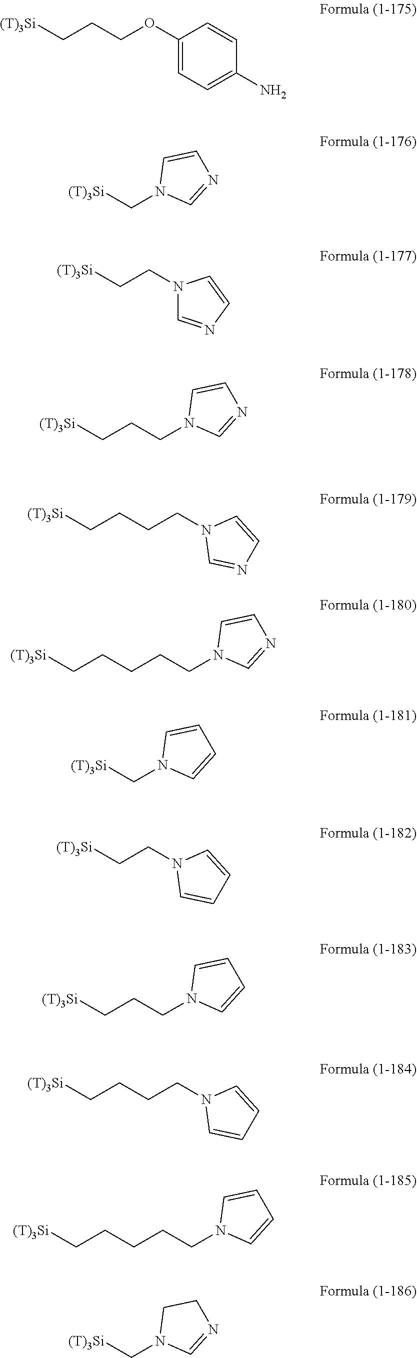

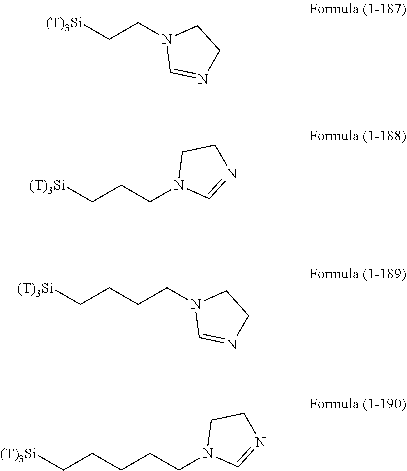

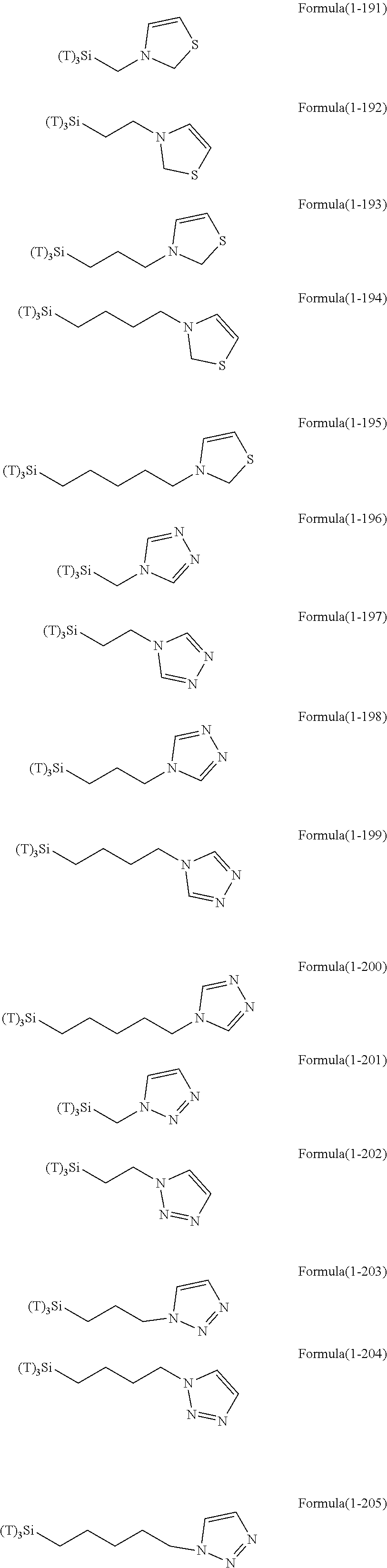

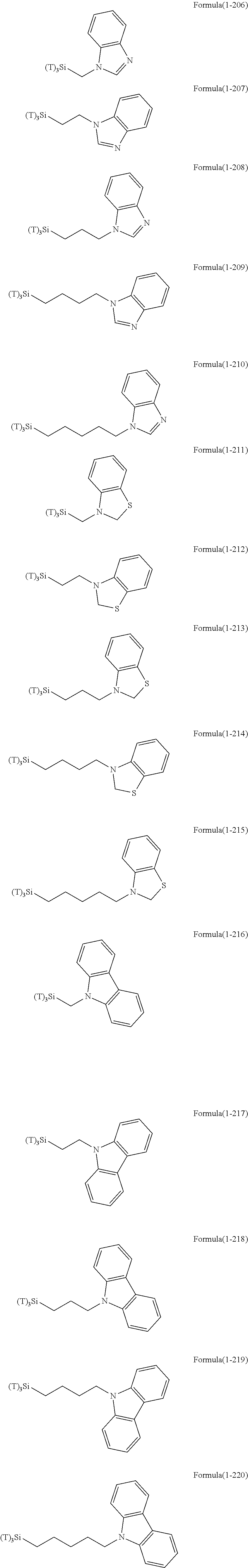

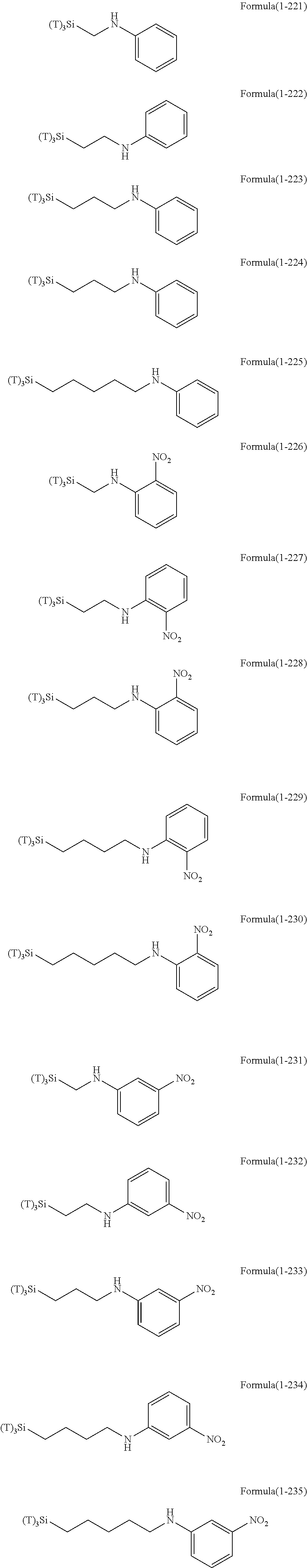

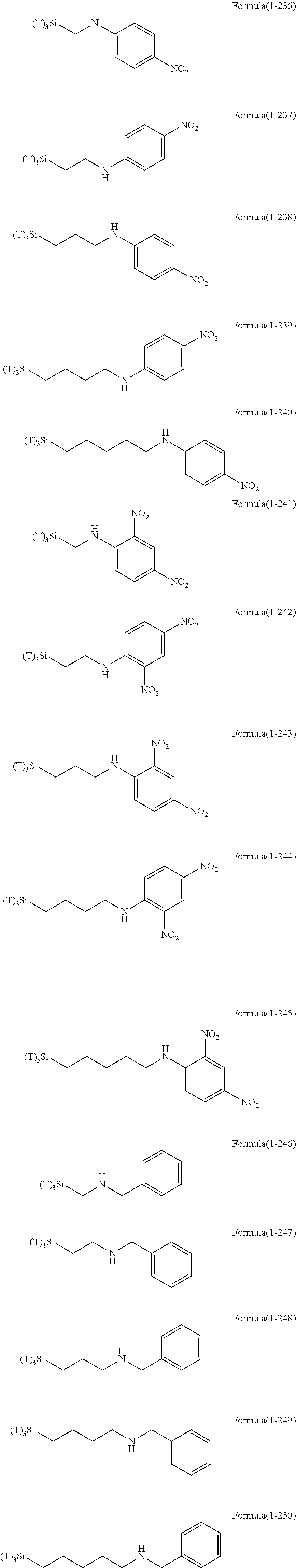

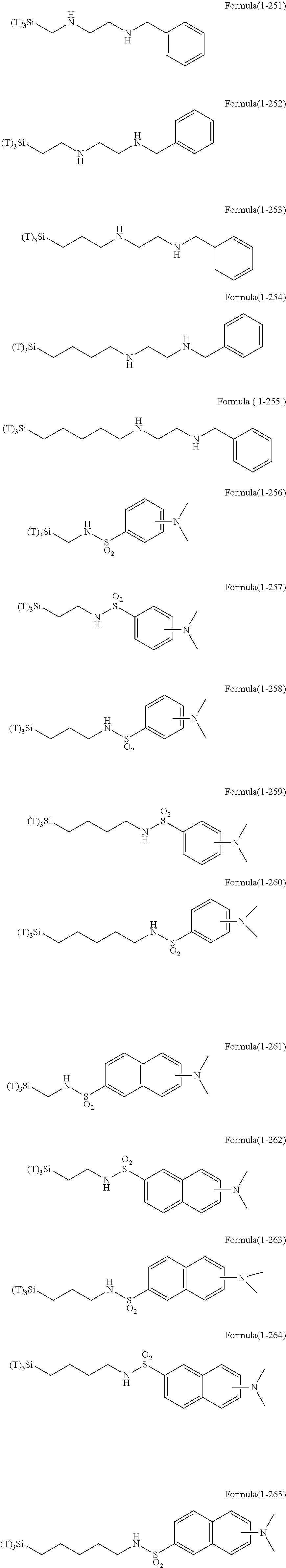

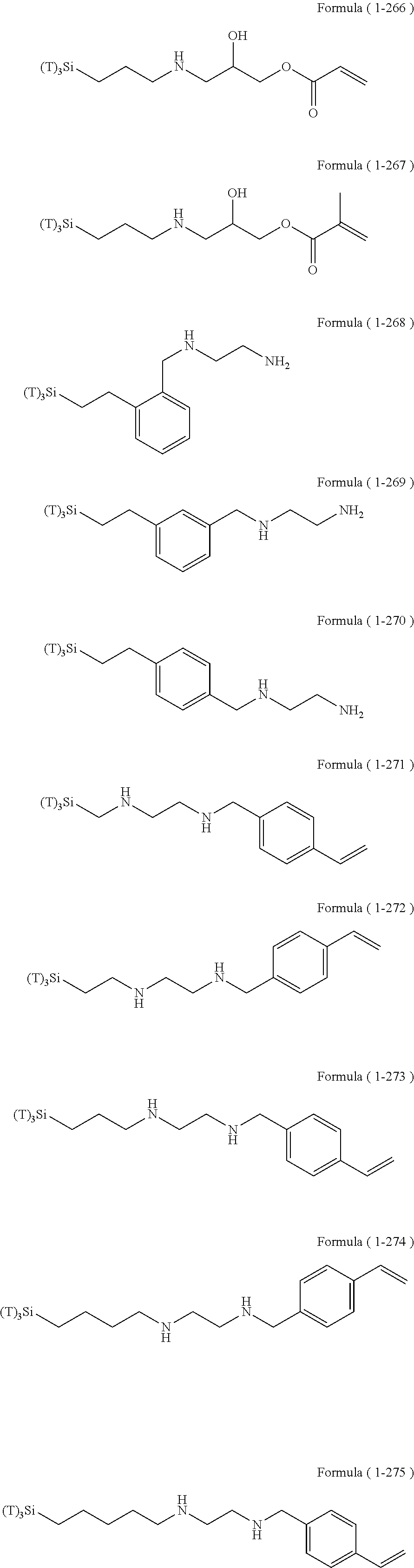

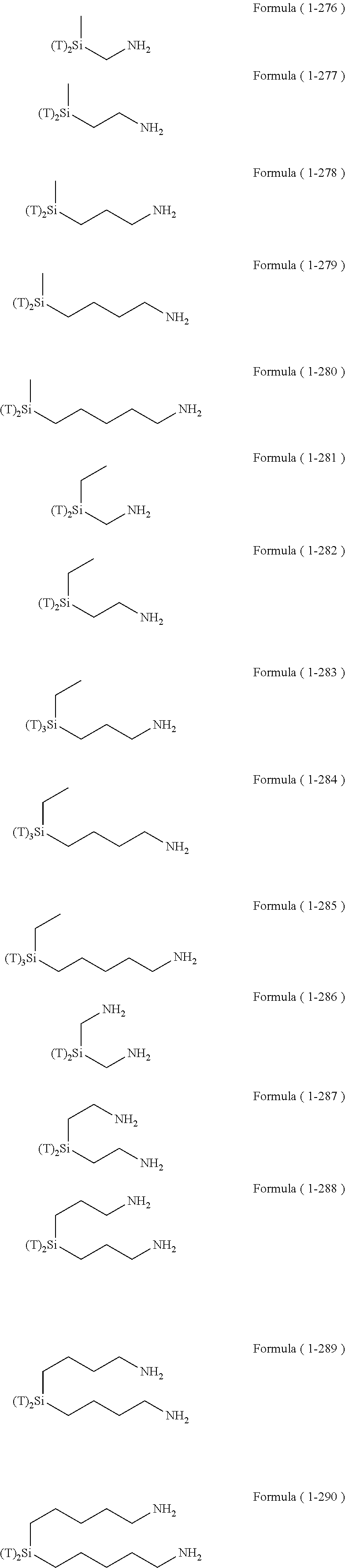

In the formulas (1-1) to (1-290), T represents, independently from each other, an alkoxy group, an acyloxy group, or a halogen group, for example, preferably a methoxy group or an ethoxy group.

Examples of [A] the polysiloxane include a hydrolysis condensate of hydrolyzable silanes including a hydrolyzable silane (A) having an alkyl iodide group and a hydrolyzable silane represented by the following formula (2), or a modified product thereof.

Examples of [A] the polysiloxane include a hydrolysis condensate of hydrolyzable silanes including a hydrolyzable silane (A) having an alkyl iodide group, a hydrolyzable silane represented by the formula (1), and a hydrolyzable silane represented by the following formula (2), or a modified product thereof.

Examples of [A′] the polysiloxane include a hydrolysis condensate of hydrolyzable silanes including a hydrolyzable silane represented by the following formula (2) together with the hydrolyzable silane represented by the formula (1) or in place of the hydrolyzable silane represented by the formula (1), or a modified product thereof.

<Formula (2)>

[R³_{b}Si(R⁴)_{3-b}]₂R⁵_{c} (2)

In the formula (2), R³ is a group bonded to a silicon atom, and independently represents: an optionally substituted alkyl group, an optionally substituted aryl group, an optionally substituted aralkyl group, an optionally substituted halogenated alkyl group (excluding an alkyl iodide group), an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group; an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group; or a combination of two or more thereof.

R⁴ is a group or atom bonded to a silicon atom, and independently represents an alkoxy group, an aralkyloxy group, an acyloxy group, or a halogen atom.

R⁵ is a group bonded to a silicon atom, and independently represents an alkylene group or an arylene group.

“b” represents 0 or 1, and “c” represents 0 or 1.

Specific examples of each group and atom in R³ and the preferred number of carbon atoms thereof can include the groups and the number of carbon atoms described above for R³ in the formulas (A-1) and (A-2).

Specific examples of each group and atom in R⁴ and the preferred number of carbon atoms thereof can include the groups and atoms and the number of carbon atoms described above for X in the formulas (A-1) and (A-2).

Specific examples of the alkylene group in R⁵ include: alkylene groups such as linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group; branched alkylene groups such as a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, and a 1-ethyltrimethylene group; and alkanetriyl groups such as a methanetriyl group, an ethane-1,1,2-triyl group, an ethane-1,2,2-triyl group, an ethane-2,2,2-triyl group, a propane-1,1,1-triyl group, a propane-1,1,2-triyl group, a propane-1,2,3-triyl group, a propane-1,2,2-triyl group, a propane-1,1,3-triyl group, a butane-1,1,1-triyl group, a butane-1,1,2-triyl group, a butane-1,1,3-triyl group, a butane-1,2,3-triyl group, a butane-1,2,4-triyl group, a butane-1,2,2-triyl group, a butane-2,2,3-triyl group, a 2-methylpropane-1,1,1-triyl group, a 2-methylpropane-1,1,2-triyl group, and a 2-methylpropane-1,1,3-triyl group, but are not limited thereto.

Specific examples of the arylene group in R⁵ include: a 1,2-phenylene group, a 1,3-phenylene group, and a 1,4-phenylene group; groups derived by removing two hydrogen atoms on the aromatic ring of a fused ring aromatic hydrocarbon compound such as a 1,5-naphthalenediyl group, a 1,8-naphthalenediyl group, a 2,6-naphthalenediyl group, a 2,7-naphthalenediyl group, a 1,2-anthracenediyl group, a 1,3-anthracenediyl group, a 1,4-anthracenediyl group, a 1,5-anthracenediyl group, a 1,6-anthracenediyl group, a 1,7-anthracenediyl group, a 1,8-anthracenediyl group, a 2,3-anthracenediyl group, a 2,6-anthracenediyl group, a 2,7-anthracenediyl group, a 2,9-anthracenediyl group, a 2,10-anthracenediyl group, and a 9,10-anthracenediyl group; and a group derived by removing two hydrogen atoms on the aromatic rings of a ring-linked aromatic hydrocarbon compound such as a 4,4′-biphenyldiyl group and a 4,4″-paraterphenyldiyl group, but are not limited thereto.

“b” is preferably 0.

“c” is preferably 1.

Specific examples of the hydrolyzable silane represented by the formula (2) include, but are not limited to, methylene bistrimethoxysilane, methylene bistrichlorosilane, methylene bistriacetoxysilane, ethylene bistriethoxysilane, ethylene bistrichlorosilane, ethylene bistriacetoxysilane, propylene bistriethoxysilane, butylene bistrimethoxysilane, phenylene bistrimethoxysilane, phenylene bistriethoxysilane, phenylene bismethyldiethoxysilane, phenylene bismethyldimethoxysilane, naphthylene bistrimethoxysilane, bistrimethoxydisilane, bistriethoxydisilane, bisethyldiethoxydisilane, and bismethyldimethoxydisilane.

Examples of [A] the polysiloxane include a hydrolysis condensate of hydrolyzable silanes including another hydrolyzable silane listed below, in addition to the hydrolyzable silane (A) having an alkyl iodide group; and the hydrolyzable silane represented by the formula (1) and/or the hydrolyzable silane represented by the formula (2), and a modified product thereof.

Examples of [A′] the polysiloxane include a hydrolysis condensate of a hydrolyzable silane including another hydrolyzable silane listed below, in addition to the hydrolyzable silane represented by the formula (1) and/or the hydrolyzable silane represented by the formula (2), and a modified product thereof.

Examples of another hydrolyzable silane include, but are not limited to, silane compounds having an onium group in the molecule, silane compounds having a sulfone group, silane compounds having a sulfonamide group, and silane compounds having a cyclic urea skeleton in the molecule.

### «Silane Compound Having Onium Group in Molecule (Hydrolyzable Organosilane)»

The silane compound having an onium group in the molecule is expected to effectively and efficiently promote a crosslinking reaction of the hydrolyzable silane.

A preferred example of the silane compound having an onium group in the molecule is represented by the formula (3).

R¹¹_{f}+R¹²_{g}Si(R¹³)_{4-(f+g)} (3)

R¹¹ is a group bonded to the silicon atom, and represents an onium group or an organic group having the onium group.

R¹² represents a group which is bonded to the silicon atom and independently represents: an optionally substituted alkyl group, an optionally substituted aryl group, an optionally substituted aralkyl group, an optionally substituted halogenated alkyl group (excluding an alkyl iodide group), an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group; an organic group having an epoxy group, an organic group having an acryloyl group, an organic group having a methacryloyl group, an organic group having a mercapto group, an organic group having an amino group, or an organic group having a cyano group; or a combination of two or more thereof.

R¹³ is a group or atom bonded to the silicon atom, and independently represents an alkoxy group, an aralkyloxy group, an acyloxy group, or a halogen atom.

“f” represents 1 or 2, “g” represents 0 or 1, and 1≤f+g≤2 is satisfied.

Regarding specific examples of an alkyl group, an aryl group, an aralkyl group, a halogenated alkyl group, a halogenated aryl group, a halogenated aralkyl group, an alkoxyalkyl group, an alkoxyaryl group, an alkoxyaralkyl group, and an alkenyl group; an organic group having an epoxy group, an organic group having an acryloyl group, an organic group having a methacryloyl group, an organic group having a mercapto group, an organic group having an amino group, and an organic group having a cyano group; and an alkoxy group, an aralkyloxy group, an acyloxy group, and a halogen atom, and specific examples of substituents of an alkyl group, an aryl group, an aralkyl group, a halogenated alkyl group, a halogenated aryl group, a halogenated aralkyl group, an alkoxyalkyl group, an alkoxyaryl group, an alkoxyaralkyl group, and an alkenyl group, and preferred numbers of carbon atoms thereof, those described above for R³ in the formulas (A-1) and (A-2) are included for R¹², and those described above for X in the formulas (A-1) and (A-2) are included for R¹³.

More specifically, specific examples of the onium group include a cyclic ammonium group or a chain ammonium group, and a tertiary ammonium group or a quaternary ammonium group is preferable.

That is, suitable specific examples of the onium group or the organic group having the onium group include a cyclic ammonium group, a chain ammonium group, or an organic group having at least one of them, and preferable is a tertiary ammonium group, a quaternary ammonium group, or an organic group having at least one of them.

When the onium group is a cyclic ammonium group, the nitrogen atom constituting the ammonium group also serves as an atom constituting the ring. At this time, the nitrogen atom constituting the ring and the silicon atom may be bonded each other directly or via a divalent linking group, or a carbon atom constituting the ring and the silicon atom may be bonded each other directly or via a divalent linking group.

In an example of a preferred embodiment, R¹¹, which is a group bonding to the silicon atom, is a heteroaromatic cyclic ammonium group represented by the following formula (S1).

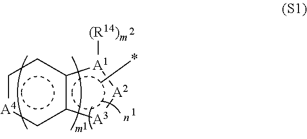

In the formula (S1), A¹, A², A³, and A⁴ each independently represent a group represented by any of the following formulas (J1) to (J3), and at least one of A¹ to A⁴ is a group represented by the following formula (J2), and it is determined whether a bond between each of A¹ to A⁴ and an atom adjacent to each of them and constituting the ring together is a single bond or a double bond such that the ring to be constituted exhibits aromaticity, according to which of A¹ to A⁴ the silicon atom in the formula (3) is bonded with. * represents a bonding arm.

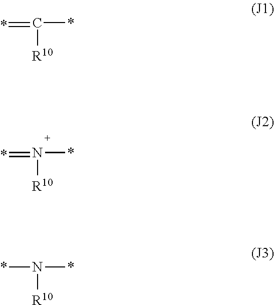

In the formulas (J1) to (J3), R¹⁰ independently represents a single bond, a hydrogen atom, an alkyl group, an aryl group, an aralkyl group, a halogenated alkyl group (excluding an alkyl iodide group), a halogenated aryl group, a halogenated aralkyl group, or an alkenyl group, and specific examples of the alkyl group, the aryl group, the aralkyl group, the halogenated alkyl group, the halogenated aryl group, the halogenated aralkyl group, and the alkenyl group and suitable carbon numbers thereof include those described above. * represents a bonding arm.

In the formula (S1), R¹⁴ independently represents an alkyl group, an aryl group, an aralkyl group, a halogenated alkyl group, a halogenated aryl group, a halogenated aralkyl group, an alkenyl group, or a hydroxy group, and when there are two or more R¹⁴s, the two R¹⁴s may be bonded to each other to form a ring, and the ring formed by the two R¹⁴s may have a bridged ring structure, and in such a case, the cyclic ammonium group has an adamantane ring, a norbornene ring, a spiro ring, or the like.

Specific examples of such an alkyl group, an aryl group, an aralkyl group, a halogenated alkyl group, a halogenated aryl group, a halogenated aralkyl group, and an alkenyl group, and the preferred number of carbon atoms thereof include those described above.

In the formula (S1), n¹ is an integer of 1 to 8, m¹ is 0 or 1, and m² is 0 or a positive integer from 1 to the maximum substitutable number of the monocyclic or polycyclic ring.

When m¹ is 0, a (4+n¹)-membered ring containing A¹ to A⁴ is formed. That is, a 5-membered ring is formed when n¹ is 1, a 6-membered ring is formed when n¹ is 2, a 7-membered ring is formed when n¹ is 3, an 8-membered ring is formed when n¹ is 4, a 9-membered ring is formed when n¹ is 5, a 10-membered ring is formed when n¹ is 6, a 11-membered ring is formed when n¹ is 7, and a 12-membered ring is formed when n¹ is 8.

When m¹ is 1, a (4+n¹)-membered ring containing A¹ to A³ and a 6-membered ring containing A⁴ are fused to form a fused ring.

A¹ to A⁴ may or may not have a hydrogen atom on the atom constituting the ring depending on which of the formula (J1) to (J3) they are, but when A¹ to A⁴ have a hydrogen atom on the atom constituting the ring, the hydrogen atom may be replaced by R¹⁴. R¹⁴ may be substituted for a ring-constituting atom other than the ring-constituting atom in A¹ to A⁴. Under such circumstances, as described above, m² is 0 or selected from integers from 1 to the maximum substitutable number of the monocyclic or polycyclic ring.

The bonding arm of the heteroaromatic cyclic ammonium group represented by the formula (S1) is present on any carbon atom or nitrogen atom present in such a single ring or condensed ring, and is directly bonded to the silicon atom, or is bonded with a linking group to form an organic group having the cyclic ammonium, which is bonded to the silicon atom.

Examples of such a linking group include an alkylene group, an arylene group, and an alkenylene group, but are not limited thereto.

Specific examples of the alkylene group and the arylene group and suitable carbon numbers thereof include the same as those described above.

The alkenylene group is a divalent group derived by further removing one hydrogen atom from an alkenyl group, and specific examples of such an alkenyl group include the same groups as those described above. The number of carbon atoms in the alkenylene group is not particularly limited, but is preferably 40 or less, more preferably 30 or less, and still more preferably 20 or less.

Specific examples thereof include vinylene, 1-methylvinylene, propenylene, 1-butenylene, 2-butenylene, 1-pentenylene, and 2-pentenylene groups, but are not limited thereto.

Specific examples of the silane compound (hydrolyzable organosilane) represented by the formula (3) having a heteroaromatic cyclic ammonium group represented by the formula (S1) include silanes represented by the following formulas (I-1) to (I-50), but are not limited thereto.

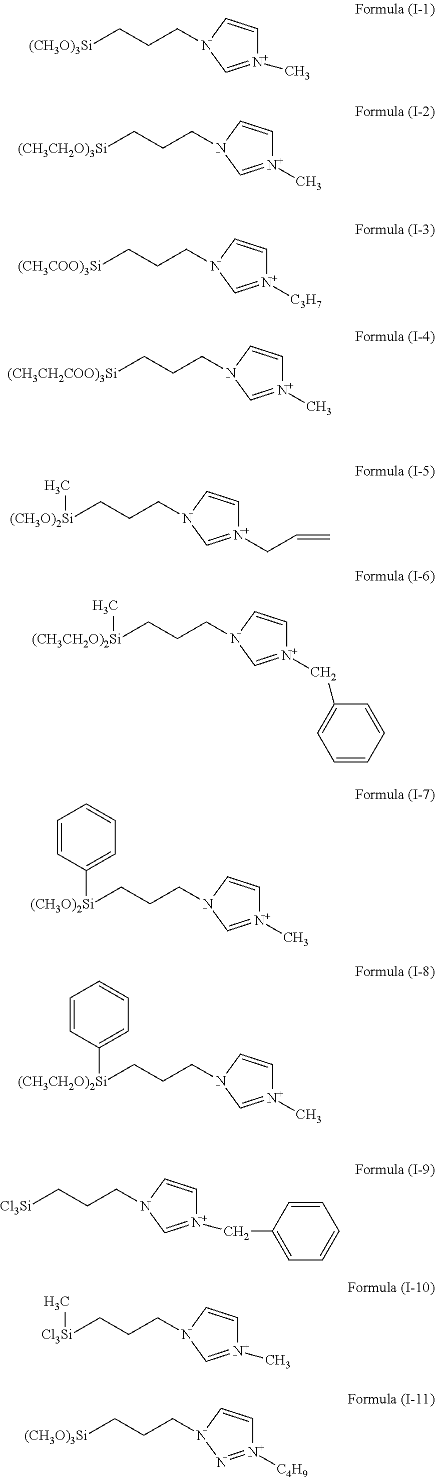

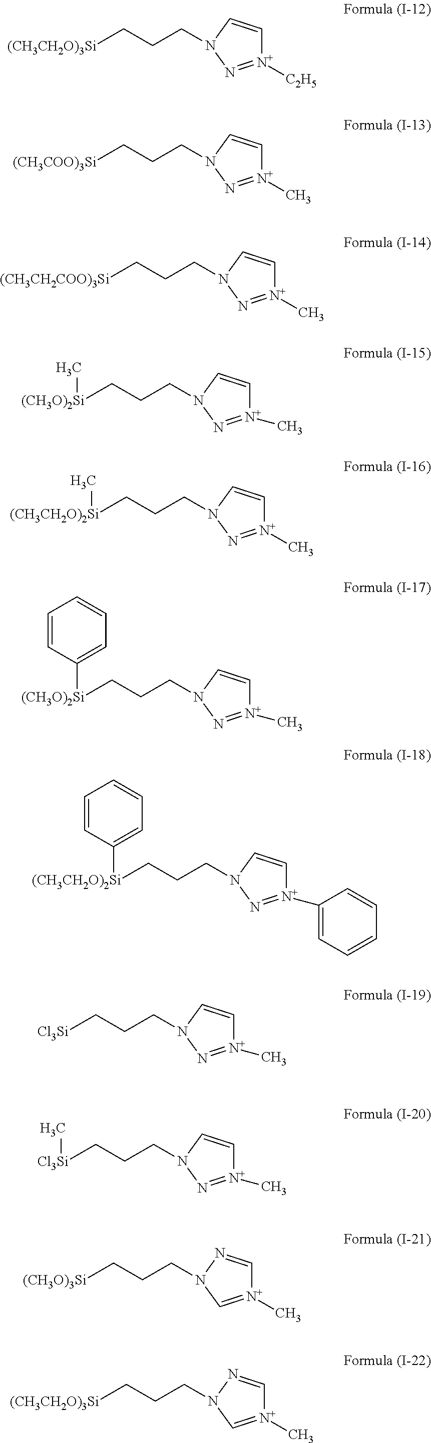

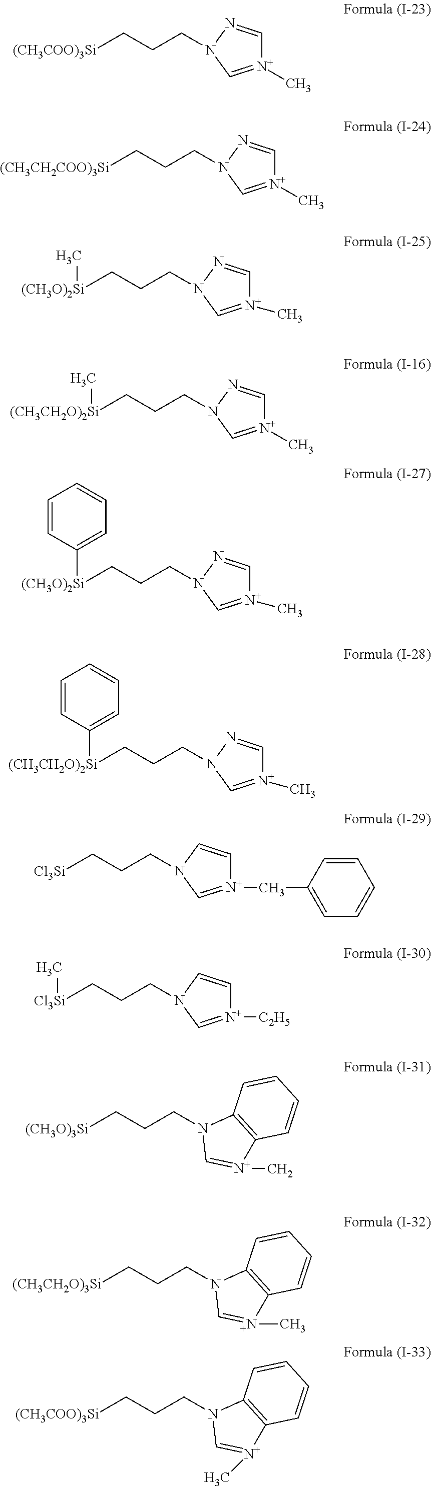

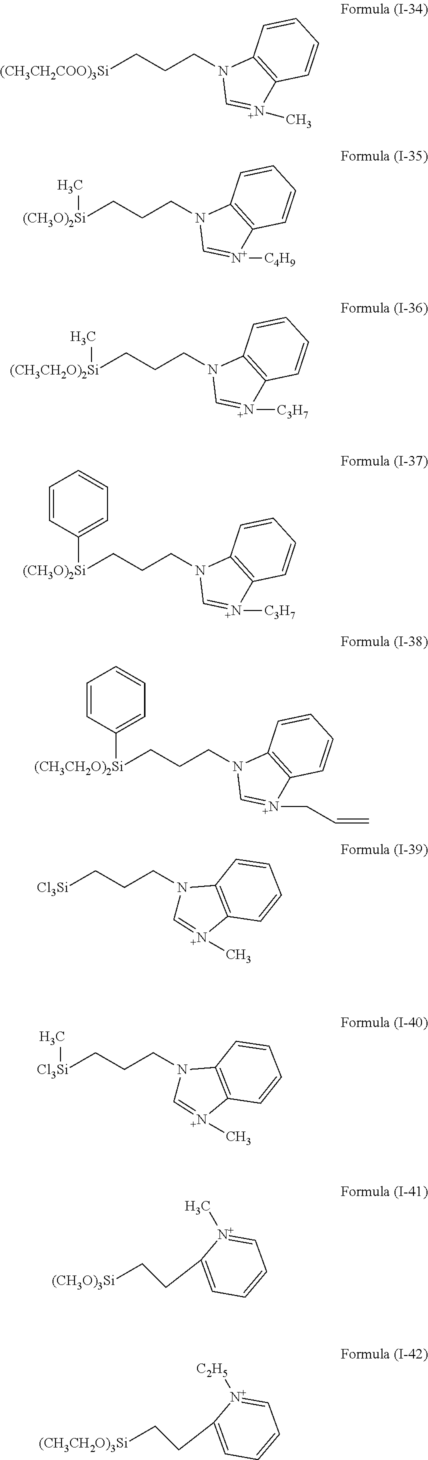

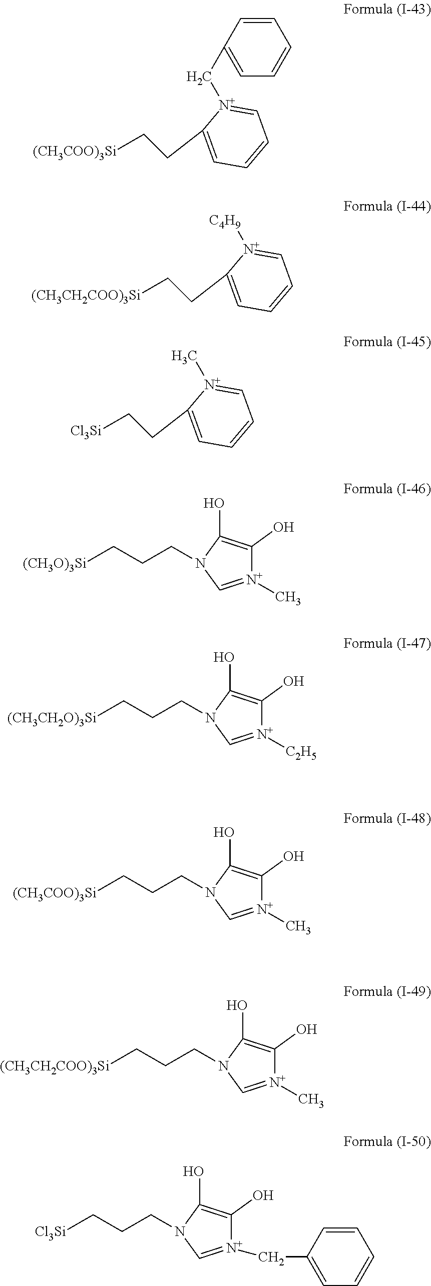

In another example, R¹¹ which is a group bonding to the silicon atom in the formula (3), may be a heteroaliphatic cyclic ammonium group represented by the following formula (S2).

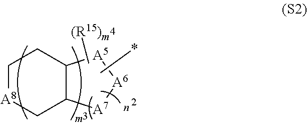

In the formula (S2), A⁵, A⁶, A⁷ and A⁸ each independently represent a group represented by any of the following formulas (J4) to (J6), and at least one of A⁵ to A⁸ represents a group represented by the following formula (J5). Depending on which of A⁵ to A⁸ the silicon atom in the formula (3) is bonded to, it is determined whether a bond between each of A⁵ to A⁸ and an atom adjacent to each of them and constituting the ring together is a single bond or a double bond such that the ring to be constituted exhibits non-aromaticity. * represents a bonding arm.

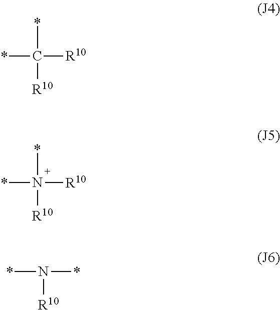

In the formulas (J4) to (J6), R¹⁰ independently represents a single bond, a hydrogen atom, an alkyl group, an aryl group, an aralkyl group, a halogenated alkyl group (excluding an alkyl iodide group), a halogenated aryl group, a halogenated aralkyl group, or an alkenyl group, and specific examples of the alkyl group, the aryl group, the aralkyl group, the halogenated alkyl group, the halogenated aryl group, the halogenated aralkyl group, and the alkenyl group and suitable carbon numbers thereof include those described above. * represents a bonding arm.

In the formula (S2), R¹⁵ independently represents an alkyl group, an aryl group, an aralkyl group, a halogenated alkyl group, a halogenated aryl group, a halogenated aralkyl group, an alkenyl group, or a hydroxy group, and when there are two or more R¹⁵s, the two R¹⁵s may be bonded to each other to form a ring, and the ring formed by the two R¹⁵s may have a bridged ring structure, and in such a case, the cyclic ammonium group has an adamantane ring, a norbornene ring, a spiro ring, or the like.

Specific examples of the alkyl group, the aryl group, the aralkyl group, the halogenated alkyl group, the halogenated aryl group, the halogenated aralkyl group, and the alkenyl group, and preferred carbon numbers thereof include those described above.

In the formula (S2), n² is an integer of 1 to 8, m³ is 0 or 1, and m⁴ is 0 or a positive integer from 1 to the maximum substitutable number of the monocyclic or polycyclic ring.

When m³ is 0, a (4+n²)-membered ring containing A⁵ to A⁸ is formed. That is, a 5-membered ring is formed when n² is 1, a 6-membered ring is formed when n² is 2, a 7-membered ring is formed when n² is 3, an 8-membered ring is formed when n² is 4, a 9-membered ring is formed when n² is 5, a 10-membered ring is formed when n² is 6, a 11-membered ring is formed when n² is 7, and a 12-membered ring is formed when n² is 8.

When m³ is 1, a (4+n²)-membered ring containing A⁵ to A⁷ and a 6-membered ring containing A⁸ are fused to form a fused ring.

A⁵ to A⁸ may or may not have a hydrogen atom on the atom constituting the ring depending on which of the formula (J4) to (J6) they are, but when A⁵ to A⁸ have a hydrogen atom on the atom constituting the ring, the hydrogen atom may be replaced by R¹⁵. R¹⁵ may be substituted for a ring-constituting atom other than the ring-constituting atom in A⁵ to A⁸.

Under such circumstances, as described above, m⁴ is 0 or selected from integers from 1 to the maximum substitutable number of the monocyclic or polycyclic ring.

The bonding arm of the heteroaliphatic cyclic ammonium group represented by the formula (S2) is present on any carbon atom or nitrogen atom present in such a monocyclic or condensed ring, and is directly bonded to the silicon atom, or is bonded with a linking group to form an organic group having the cyclic ammonium, which is bonded to the silicon atom.

Examples of such a linking group include an alkylene group, an arylene group, and an alkenylene group, and specific examples of the alkylene group, the arylene group, and the alkenylene group and preferred carbon numbers thereof include the same as described above.

Specific examples of the silane compound (hydrolyzable organosilane) represented by the formula (3) having a heteroaliphatic cyclic ammonium group represented by the formula (S2) include silanes represented by the following formulas (II-1) to (II-30), but are not limited thereto.

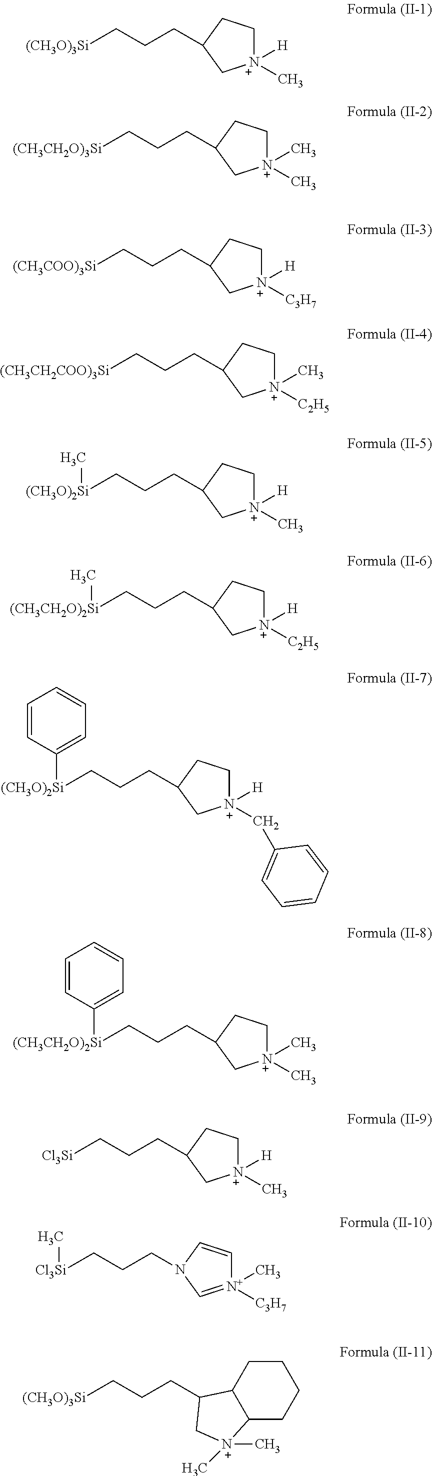

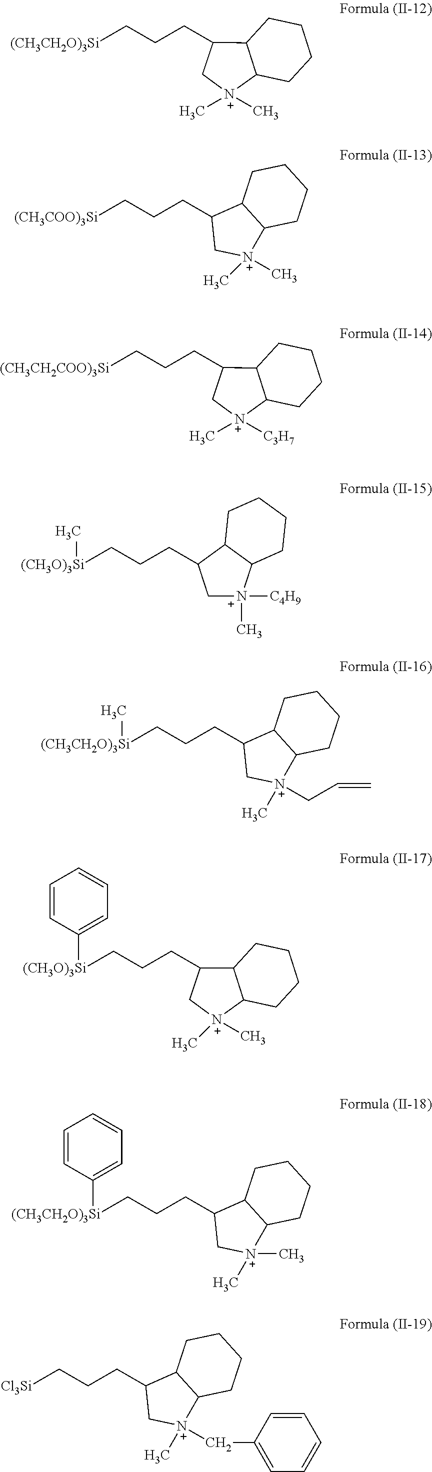

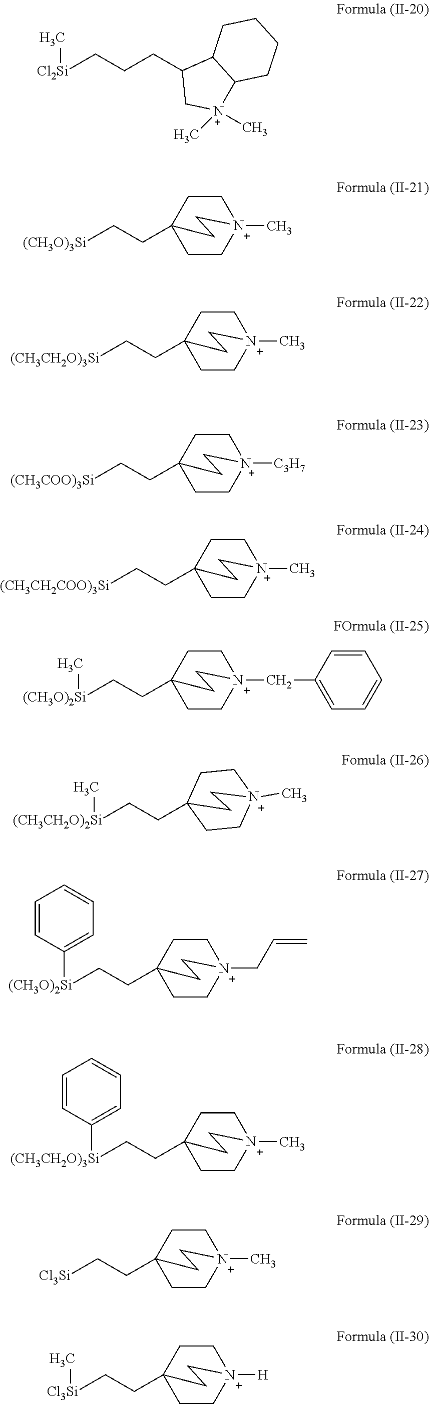

In still another example, R¹¹ which is a group bonding to the silicon atom in the formula (3), may be a chain ammonium group represented by the following formula (S3).

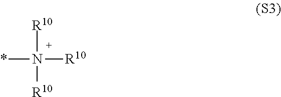

In the formula (S3), R¹⁰ independently represents a hydrogen atom, an alkyl group, an aryl group, an aralkyl group, a halogenated alkyl group (excluding an alkyl iodide group), a halogenated aryl group, a halogenated aralkyl group, or an alkenyl group, and specific examples of the alkyl group, the aryl group, the aralkyl group, the halogenated alkyl group, the halogenated aryl group, the halogenated aralkyl group, and the alkenyl group and suitable carbon numbers thereof include those described above. * represents a bonding arm.

The chain ammonium group represented by the formula (S3) is directly bonded to the silicon atom, or is bonded with a linking group to form an organic group having the chain ammonium group, which is bonded to the silicon atom.

Examples of such a linking group include an alkylene group, an arylene group, and an alkenylene group, and specific examples of the alkylene group, the arylene group, and the alkenylene group include the same groups as described above.

Specific examples of the silane compound (hydrolyzable organosilane) represented by the formula (3) having a chain ammonium group represented by the formula (S3) include silanes represented by the following formulas (III-1) to (III-28), but are not limited thereto.

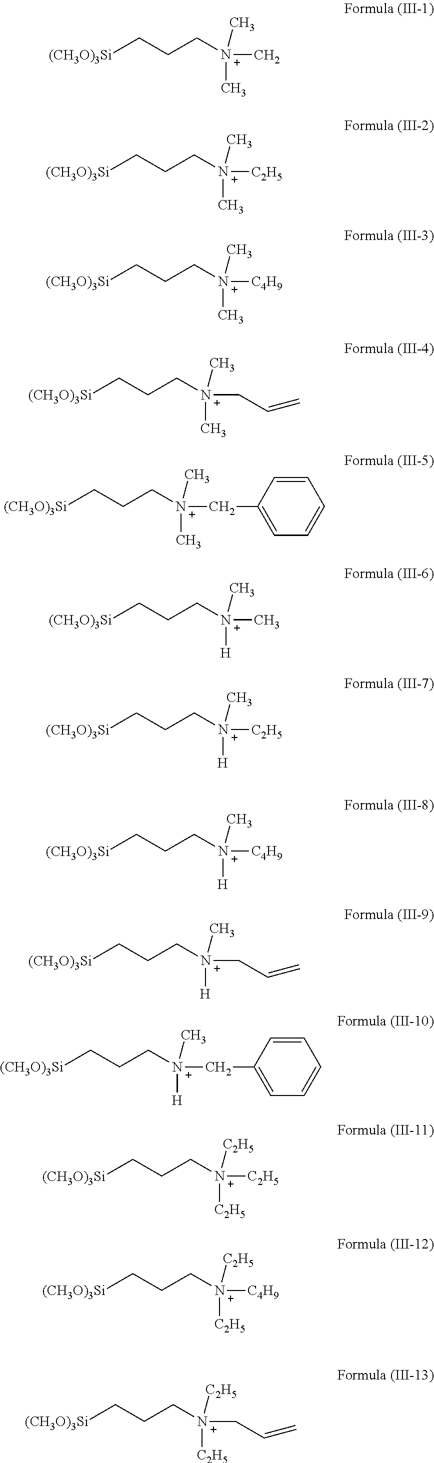

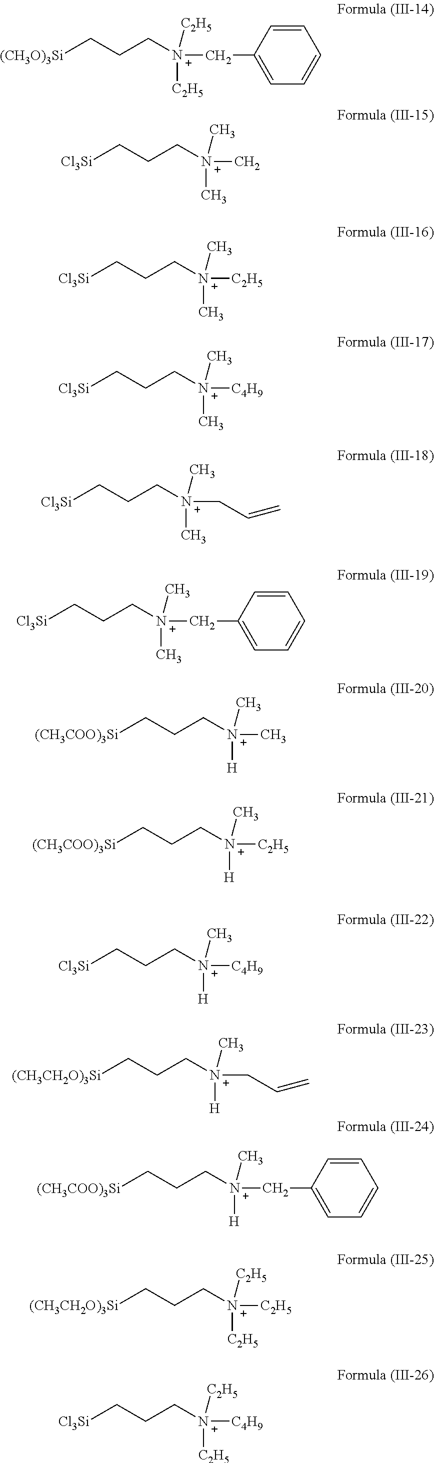

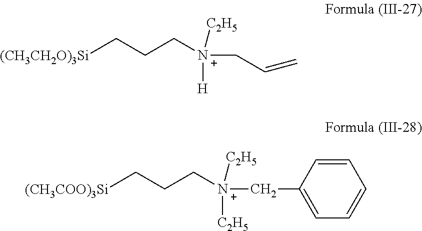

### «Silane Compound (Hydrolyzable Organosilane) Having Sulfone Group or Sulfonamide Group»

Examples of the silane compound having a sulfone group and the silane compound having a sulfonamide group include compounds represented by the following formulas (B-1) to (B-36), but are not limited thereto.

In the following formulas, Me represents a methyl group, and Et represents an ethyl group.

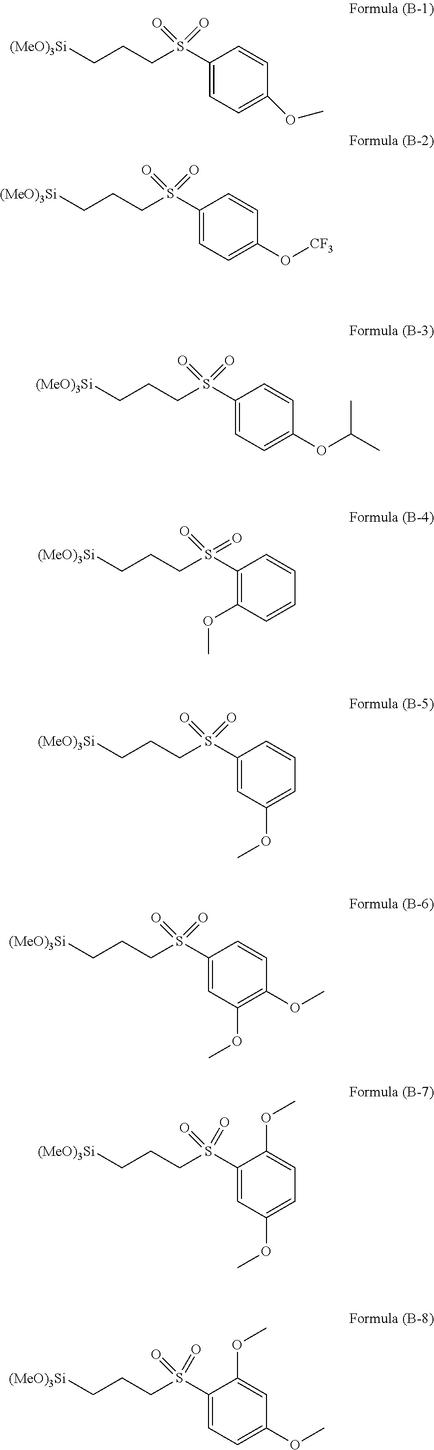

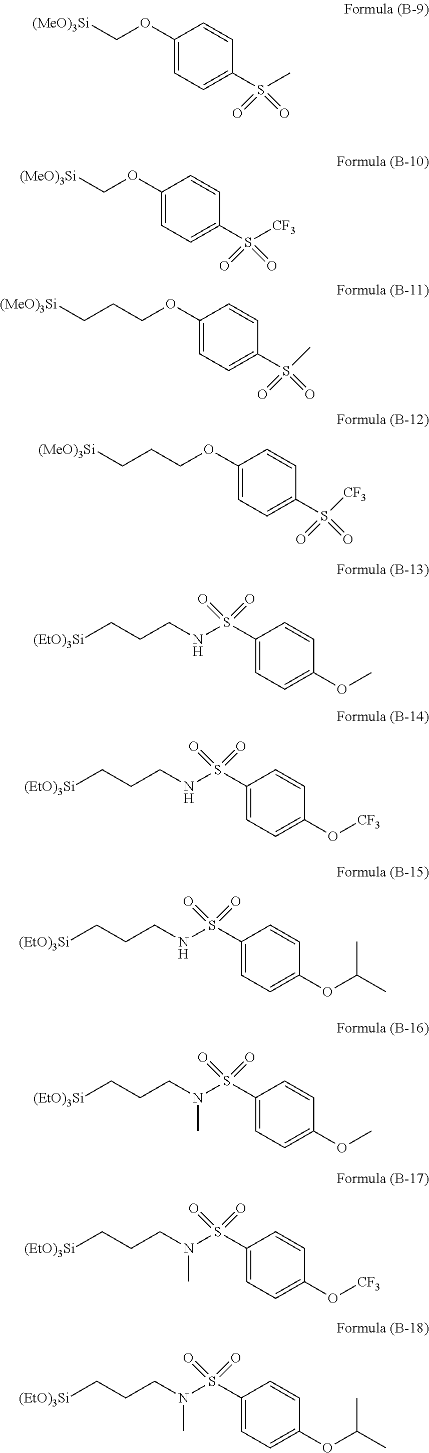

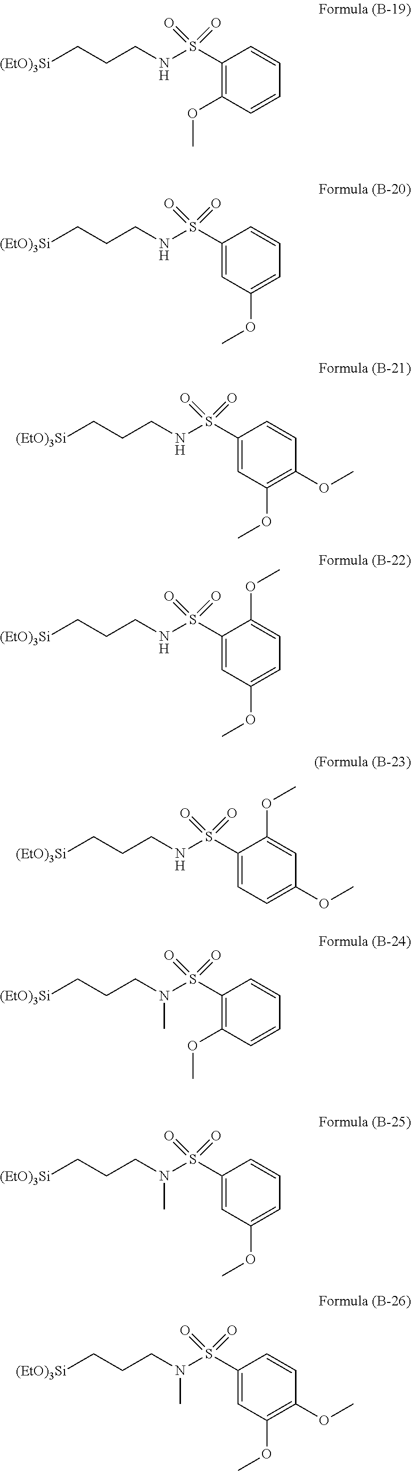

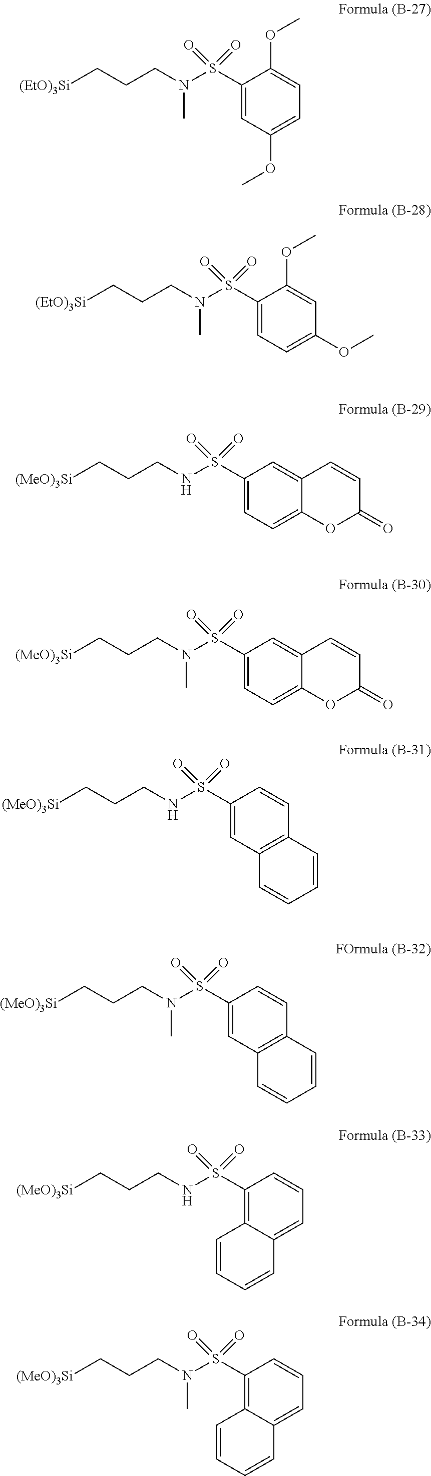

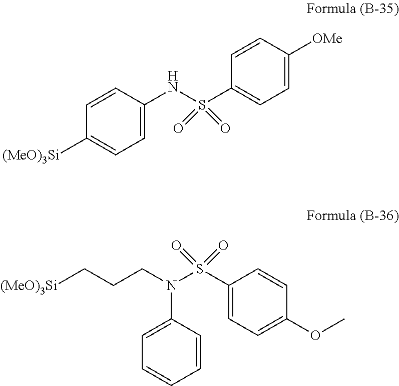

### «Silane Compound (Hydrolyzable Organosilane) Having Cyclic Urea Skeleton in Molecule»

Examples of the hydrolyzable organosilane having a cyclic urea skeleton in the molecule include a hydrolyzable organosilane represented by the following formula (4-1).

R⁴⁰¹ₓR⁴⁰²_{y}Si(R⁴⁰³)_{4-(x+y)} (4-1)

In the formula (4-1), R⁴⁰¹ is a group bonded to the silicon atom, and independently represents a group represented by the following formula (4-2).

R⁴⁰² is a group bonded to the silicon atom, and represents: an optionally substituted alkyl group, an optionally substituted aryl group, an optionally substituted aralkyl group, an optionally substituted halogenated alkyl group (excluding an alkyl iodide group), an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group; an organic group having an epoxy group, an organic group having an acryloyl group, an organic group having a methacryloyl group, an organic group having a mercapto group, or an organic group having a cyano group; or a combination of two or more thereof.

R⁴⁰³ is a group or atom bonded to the silicon atom, and independently represents an alkoxy group, an aralkyloxy group, an acyloxy group, or a halogen atom.

“x” is 1 or 2, “y” is 0 or 1, and x+y≤2 is satisfied.

Specific examples of R⁴⁰²: the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, the alkenyl group, the organic group having an epoxy group, the organic group having an acryloyl group, the organic group having a methacryloyl group, the organic group having a mercapto group, and the organic group having a cyano group; R⁴⁰³: the alkoxy group, the aralkyloxy group, the acyloxy group, and the halogen atom; and examples of substituents thereof, suitable carbon numbers thereof, and the like include those described above for R³ and X in the formulas (A-1) and (A-2).

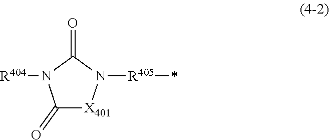

In the formula (4-2), R⁴⁰⁴ each independently represents a hydrogen atom, an optionally substituted alkyl group, an optionally substituted alkenyl group, an organic group having an epoxy group, or an organic group having a sulfonyl group, and R⁴⁰⁵ each independently represents an alkylene group, a hydroxyalkylene group, a sulfide bond (—S—), an ether bond (—O—), or an ester bond (—CO—O— or —O—CO—). * represents a bonding arm.

Specific examples and suitable carbon numbers of the optionally substituted alkyl group, the optionally substituted alkenyl group, and the organic group having an epoxy group of R⁴⁰⁴ are the same as those described above for R³ in the formulas (A-1) and (A-2). In addition, as the optionally substituted alkyl group of R⁴⁰⁴, an alkyl group in which a terminal hydrogen atom is substituted with a vinyl group is preferable, and specific examples thereof include an allyl group, a 2-vinylethyl group, a 3-vinylpropyl group, and a 4-vinylbutyl group.

The organic group having a sulfonyl group is not particularly limited as long as it contains a sulfonyl group, and examples thereof include an optionally substituted alkylsulfonyl group, an optionally substituted arylsulfonyl group, an optionally substituted aralkylsulfonyl group, an optionally substituted halogenated alkylsulfonyl group, an optionally substituted halogenated arylsulfonyl group, an optionally substituted halogenated aralkylsulfonyl group, an optionally substituted alkoxyalkylsulfonyl group, an optionally substituted alkoxyarylsulfonyl group, an optionally substituted alkoxyaralkylsulfonyl group, and an optionally substituted alkenylsulfonyl group.

Specific examples and suitable carbon numbers of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, and the alkenyl group in these groups, and the substituents thereof may be the same as those described above for R³ in the formulas (A-1) and (A-2).

The alkylene group is a divalent group derived by further removing one hydrogen atom from an alkyl group, and may be any of a linear form, a branched form, and a cyclic form. Specific examples of such an alkylene group include the same as those described above. The number of carbon atoms in the alkylene group is not particularly limited, but is preferably 40 or less, more preferably 30 or less, still more preferably 20 or less, and still more preferably 10 or less.

The alkylene group of R⁴⁰⁵ may have one or two or more selected from a sulfide bond, an ether bond, and an ester bond at the end or in the middle, preferably in the middle.

Specific examples of the alkylene group include: linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group; branched alkylene groups such as a methylethylene group, a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, and a 1-ethyltrimethylene group; cyclic alkylene groups such as a 1,2-cyclopropanediyl group, a 1,2-cyclobutanediyl group, a 1,3-cyclobutanediyl group, a 1,2-cyclohexanediyl group, and a 1,3-cyclohexanediyl group; and alkylene groups containing an ether group or the like such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, and —CH₂OCH₂CH₂SCH₂—, but are not limited thereto.

The hydroxyalkylene group is one in which at least one of the hydrogen atoms of the above-mentioned alkylene group is replaced with a hydroxy group, and specific examples thereof include a hydroxymethylene group, a 1-hydroxyethylene group, a 2-hydroxyethylene group, a 1,2-dihydroxyethylene group, a 1-hydroxytrimethylene group, a 2-hydroxytrimethylene group, a 3-hydroxytrimethylene group, a 1-hydroxytetramethylene group, a 2-hydroxytetramethylene group, a 3-hydroxytetramethylene group, a 4-hydroxytetramethylene group, a 1,2-dihydroxytetramethylene group, a 1,3-dihydroxytetramethylene group, a 1,4-dihydroxytetramethylene group, a 2,3-dihydroxytetramethylene group, a 2,4-dihydroxytetramethylene group, and a 4,4-dihydroxytetramethylene group, but are not limited thereto.

In the formula (4-2), X₄₀₁ independently represents any of the groups represented by the following formulas (4-3) to (4-5), and the carbon atom of the ketone group in the following formulas (4-4) and (4-5) is bonded to the nitrogen atom to which R⁴⁰⁵ is bonded in the formula (4-2).

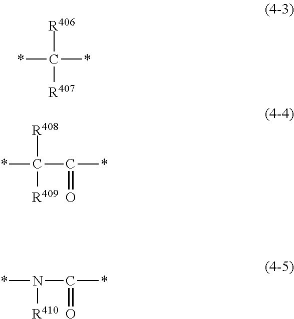

In the formulas (4-3) to (4-5), R⁴⁰⁶ to R⁴¹⁰ each independently represent a hydrogen atom, an optionally substituted alkyl group, an optionally substituted alkenyl group, or an organic group having an epoxy group or a sulfonyl group. Specific examples and suitable carbon numbers of the optionally substituted alkyl group, the optionally substituted alkenyl group, and the organic group having an epoxy group or a sulfonyl group are the same as those described above for R³ in the formulas (A-1) and (A-2). Specific examples and suitable carbon numbers of the organic group having a sulfonyl group are the same as those described above for R⁴⁰⁴. * represents a bonding arm.

Among them, from the viewpoint of realizing excellent lithography characteristics with good reproducibility, X₄₀₁ is preferably a group represented by the formula (4-5).

From the viewpoint of realizing excellent lithography characteristics with good reproducibility, at least one of R⁴⁰⁴ and R⁴⁰⁶ to R⁴¹⁰ is preferably an alkyl group in which the terminal hydrogen atom is substituted with a vinyl group.

As the hydrolyzable organosilane represented by the formula (4-1), a commercially available product may be used, and the hydrolyzable organosilane can also be synthesized by a known method described in WO 2011/102470 A and the like.

Hereinafter, specific examples of the hydrolyzable organosilane represented by the formula (4-1) include silanes represented by the following formulas (4-1-1) to (4-1-29), but are not limited thereto.

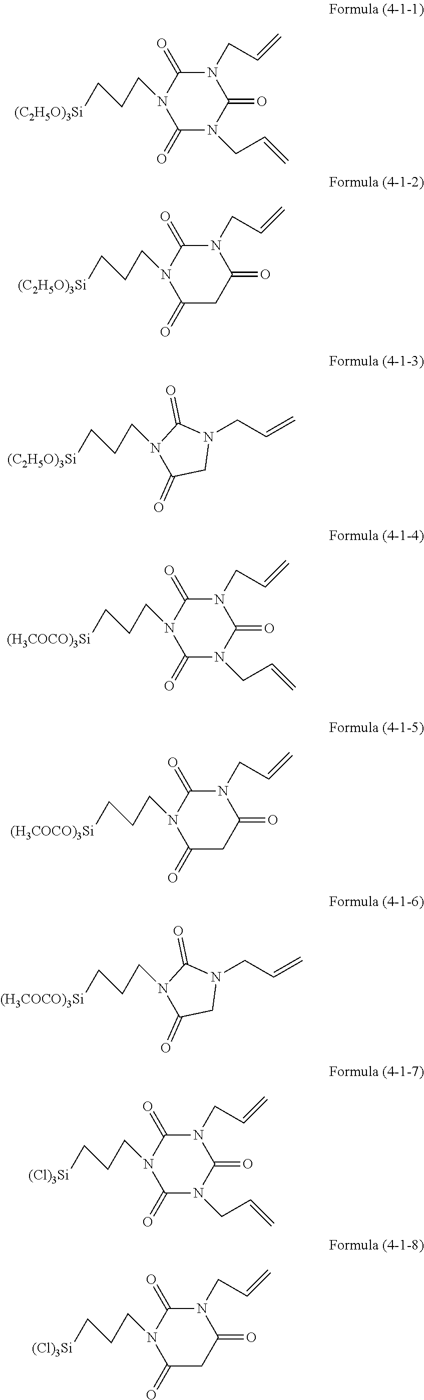

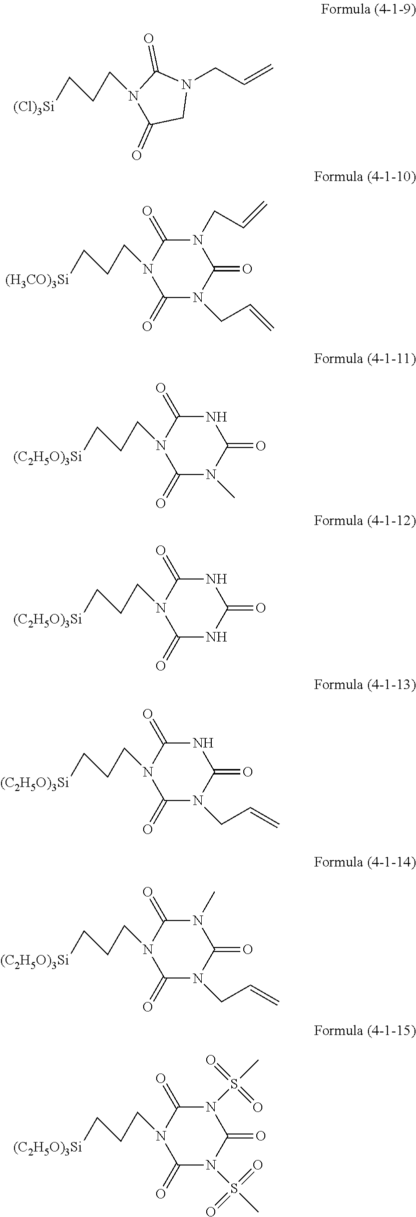

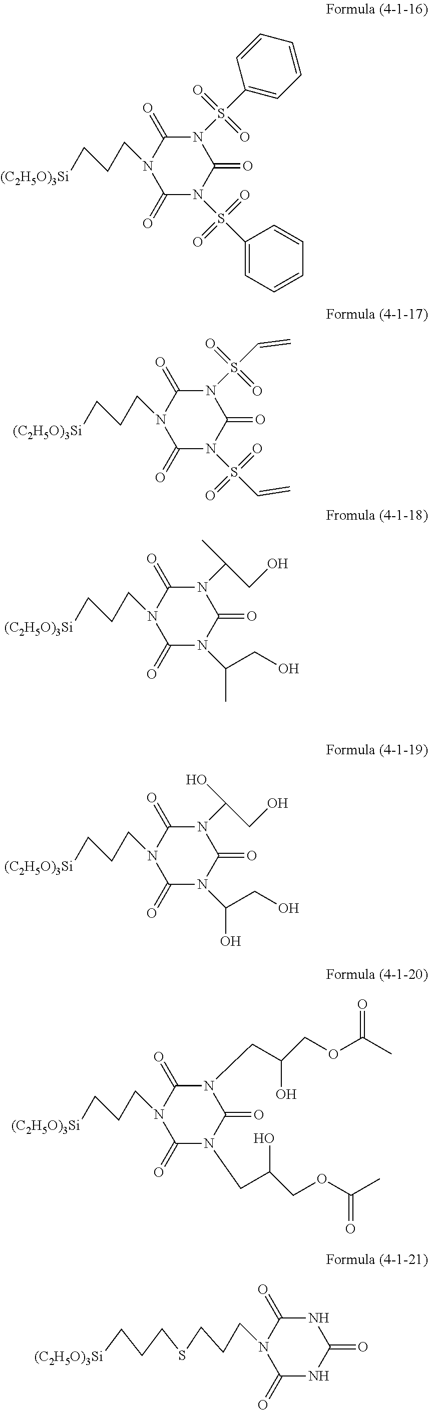

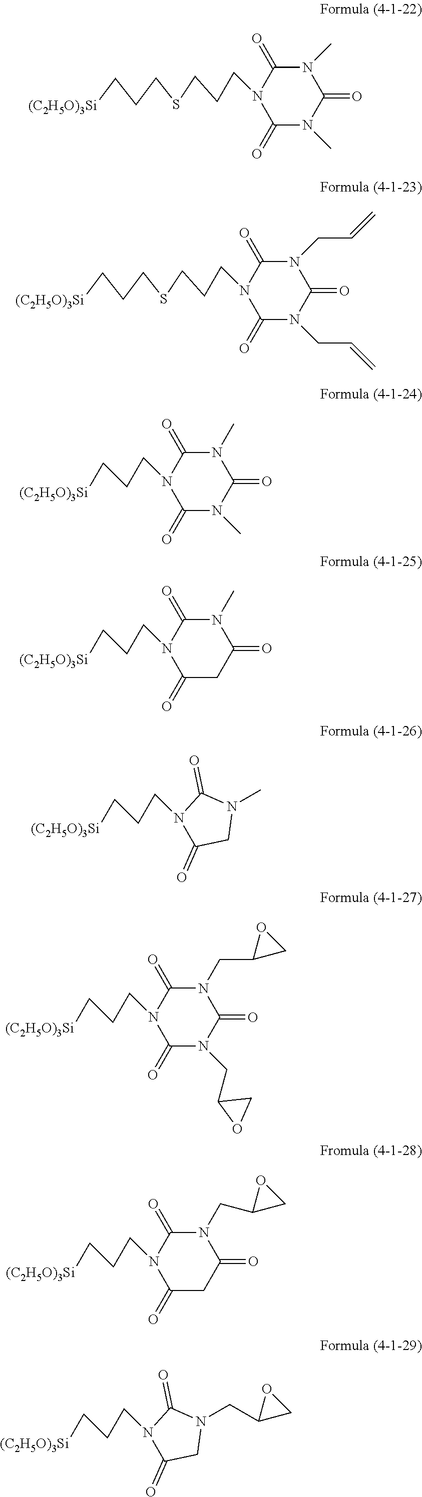

[A] the polysiloxane and [A′] the polysiloxane may be a hydrolysis condensate of hydrolyzable silanes including another silane compound other than those exemplified above or a modified product thereof as long as the effect of the present invention is not impaired.

As described above, as [A] the polysiloxane and [A′] the polysiloxane, a modified product in which at least a part of silanol groups of the hydrolysis condensate is modified may be used. For example, a modified product in which a part of silanol groups is modified with alcohol or a modified product protected with acetal may be used.

Examples of the polysiloxane as the modified products include, in a hydrolysis condensate of the hydrolyzable silane described above, a reaction product obtained by a reaction between at least a part of silanol groups of the condensate and the hydroxy group of an alcohol, a dehydration reaction product between the condensate and an alcohol, and a modified product obtained by protecting at least a part of silanol groups of the condensate with an acetal group.

As the alcohol, a monohydric alcohol can be used, and examples thereof include methanol, ethanol, 2-propanol, 1-butanol, 2-butanol, isobutyl alcohol, tert-butyl alcohol, 1-pentanol, 2-pentanol, 3-pentanol, 1-heptanol, 2-heptanol, tert-amyl alcohol, neopentyl alcohol, 2-methyl-1-propanol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, and cyclohexanol.

For example, alkoxy group-containing alcohols such as 3-methoxybutanol, ethylene glycol monomethyl ether, ethylene glycol monoethyl ether, diethylene glycol monomethyl ether, diethylene glycol monoethyl ether, propylene glycol monomethyl ether (1-methoxy-2-propanol), propylene glycol monoethyl ether (1-ethoxy-2-propanol), and propylene glycol monobutyl ether (1-butoxy-2-propanol) may be used.

Regarding the reaction between the silanol group of the hydrolysis condensate and the hydroxy group of the alcohol, the hydrolysis condensate and the alcohol are brought into contact with each other and reacted at a temperature of 40 to 160° C., for example, 60° C., for 0.1 to 48 hours, for example, 24 hours, whereby a modified product whose silanol group is capped is obtained. At this time, the alcohol as the capping agent can be used as a solvent in the composition containing the polysiloxane.

The dehydration reaction product of the hydrolysis condensate of the hydrolyzable silane and an alcohol can be produced by reacting the hydrolysis condensate with an alcohol in the presence of an acid as a catalyst, capping the silanol group with the alcohol, and removing water generated by dehydration to the outside of the reaction system.

As the acid, an organic acid having an acid dissociation constant (pka) of −1 to 5, preferably 4 to 5 can be used. Examples of the acid include trifluoroacetic acid, maleic acid, benzoic acid, isobutyric acid, and acetic acid, and among them, benzoic acid, isobutyric acid, and acetic acid can be exemplified.

As the acid, an acid having a boiling point of 70 to 160° C. can be used, and examples thereof include trifluoroacetic acid, isobutyric acid, acetic acid, and nitric acid.

As described above, the acid preferably has a physical property of an acid dissociation constant (pka) of 4 to 5 or a boiling point of 70 to 160° C. That is, one having a weak acidity or one having a strong acidity but having a low boiling point may be used.

It is possible to use any property from acid dissociation constant and boiling point as the acid.

For acetal protection of the silanol group of the hydrolysis condensate, a vinyl ether, for example, a vinyl ether represented by the following formula (5) can be used, and a partial structure represented by the following formula (6) can be introduced into the polysiloxane by a reaction therebetween.

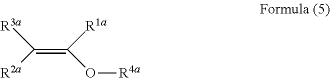

In the formula (5), R^{1a}, R^{2a}, and R^{3a} each represent a hydrogen atom or an alkyl group having 1 to 10 carbon atoms, R^{4a} represents an alkyl group having 1 to 10 carbon atoms, and R^{2a} and R^{4a} may be bonded to each other to form a ring. The alkyl group can be exemplified as described above.

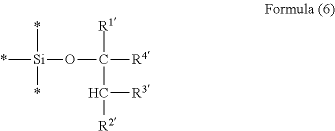

In the formula (6), R^{1′}, R^{2′}, and R^{3′} each represent a hydrogen atom or an alkyl group having 1 to 10 carbon atoms, R^{4′} represents an alkyl group having 1 to 10 carbon atoms, and R^{2′} and R^{4′} may be bonded to each other to form a ring. In the formula (6), * represents a bond to an adjacent atom. Examples of the adjacent atom include an oxygen atom of a siloxane bond, an oxygen atom of a silanol group, and a carbon atom derived from R¹ of the formula (1). The alkyl group can be exemplified as described above.

Examples of the vinyl ether represented by the formula (5) include aliphatic vinyl ether compounds such as methyl vinyl ether, ethyl vinyl ether, isopropyl vinyl ether, normal butyl vinyl ether, 2-ethylhexyl vinyl ether, tert-butyl vinyl ether, and cyclohexyl vinyl ether, and cyclic vinyl ether compounds such as 2,3-dihydrofuran, 4-methyl-2,3-dihydrofuran, and 3,4-dihydro-2H-pyran. In particular, ethyl vinyl ether, propyl vinyl ether, butyl vinyl ether, ethylhexyl vinyl ether, cyclohexyl vinyl ether, 3,4-dihydro-2H-pyran, or 2,3-dihydrofuran may be preferably used.

The acetal protection of the silanol group can be performed using the hydrolysis condensate, a vinyl ether, and an aprotic solvent such as propylene glycol monomethyl ether acetate, ethyl acetate, dimethylformamide, tetrahydrofuran, or 1,4-dioxane as a solvent, and using a catalyst such as pyridium p-toluenesulfonic acid, trifluoromethanesulfonic acid, p-toluenesulfonic acid, methanesulfonic acid, hydrochloric acid, or sulfuric acid.

Alcohol capping and acetal protection of the silanol group may be performed simultaneously with hydrolysis and condensation of the hydrolyzable silane described later.

The weight average molecular weight of the hydrolysis condensate of the hydrolyzable silane or a modified product thereof can be, for example, 500 to 1 million. From the viewpoint of suppressing precipitation of the hydrolysis condensate or a modified product thereof in the composition, etc., the weight average molecular weight can be preferably 500,000 or less, more preferably 250,000 or less, and still more preferably 100,000 or less, and from the viewpoint of achieving both storage stability and coatability, etc., the weight average molecular weight can be preferably 700 or more, and more preferably 1,000 or more.

The weight average molecular weight is a molecular weight obtained in terms of polystyrene by GPC analysis. The GPC analysis can be performed using, for example, a GPC apparatus (Trade name: HLC-8220GPC, manufactured by Tosoh Corporation), a GPC column (Trade name: Shodex (registered trademark) KF803L, KF802, KF801, manufactured by Showa Denko K.K.), a column temperature of 40° C., tetrahydrofuran as an eluent (elution solvent), a flow amount (flow rate) of 1.0 mL/min, and polystyrene (Shodex (registered trademark) manufactured by Showa Denko K.K.) as a standard sample.

The hydrolysis condensate of the hydrolyzable silane is obtained by hydrolyzing and condensing the above-mentioned silane compound (hydrolyzable silane).

The above-mentioned silane compound (hydrolyzable silane) contains an alkoxy group, an aralkyloxy group, an acyloxy group, or a halogen atom directly bonded to a silicon atom, that is, an alkoxysilyl group, an aralkyloxysilyl group, an acyloxysilyl group, or a halogenated silyl group (hereinafter, referred to as a hydrolyzable group).

For the hydrolysis of these hydrolyzable groups, usually 0.1 to 100 mol, for example, 0.5 to 100 mol, preferably 1 to 10 mol of water is used per 1 mol of the hydrolyzable groups.

At the time of hydrolysis and condensation, a hydrolysis catalyst may be used for the purpose of accelerating the reaction, or hydrolysis and condensation may be performed without using a hydrolysis catalyst. When a hydrolysis catalyst is used, usually 0.0001 to 10 mol, preferably 0.001 to 1 mol, of the hydrolysis catalyst can be used per 1 mol of the hydrolyzable group.

The reaction temperature at the time of performing hydrolysis and condensation is usually in a range that is equal to or higher than room temperature and equal to or lower than the reflux temperature at normal pressure of an organic solvent that can be used for hydrolysis, and can be, for example, 20 to 110° C. or 20 to 80° C.

For the hydrolysis, hydrolysis may be performed completely, that is, all hydrolyzable groups may be changed to silanol groups. Alternatively, hydrolysis may be performed partially, that is, unreacted hydrolyzable groups may be left.

Examples of the hydrolysis catalyst that can be used in hydrolysis and condensation include metal chelate compounds, organic acids, inorganic acids, organic bases, and inorganic bases.

Examples of the metal chelate compound as the hydrolysis catalyst include: titanium chelate compounds such as triethoxy·mono(acetylacetonate) titanium, tri-n-propoxy·mono(acetylacetonate) titanium, tri-i-propoxy·mono(acetylacetonate) titanium, tri-n-butoxy·mono(acetylacetonate) titanium, tri-sec-butoxy·mono(acetylacetonate) titanium, tri-t-butoxy·mono(acetylacetonate) titanium, diethoxy·bis(acetylacetonate) titanium, di-n-propoxy·bis(acetylacetonate) titanium, di-i-propoxy·bis(acetylacetonate) titanium, di-n-butoxy·bis(acetylacetonate) titanium, di-sec-butoxy·bis(acetylacetonate) titanium, di-t-butoxy·bis(acetylacetonate) titanium, monoethoxy·tris(acetylacetonate) titanium, mono-n-propoxy·tris(acetylacetonate) titanium, mono-i-propoxy·tris(acetylacetonate) titanium, mono-n-butoxy·tris(acetylacetonate) titanium, mono-sec-butoxy·tris(acetylacetonate) titanium, mono-t-butoxy·tris(acetylacetonate) titanium, tetrakis(acetylacetonate) titanium, triethoxy·mono(ethylacetoacetate) titanium, tri-n-propoxy·mono(ethylacetoacetate) titanium, tri-i-propoxy·mono(ethylacetoacetate) titanium, tri-n-butoxy·mono(ethylacetoacetate) titanium, tri-sec-butoxy·mono(ethylacetoacetate) titanium, tri-t-butoxy·mono(ethylacetoacetate) titanium, diethoxy·bis(ethylacetoacetate) titanium, di-n-propoxy·bis(ethylacetoacetate) titanium, di-i-propoxy·bis(ethylacetoacetate) titanium, di-n-butoxy·bis(ethylacetoacetate) titanium, di-sec-butoxy·bis(ethylacetoacetate) titanium, di-t-butoxy·bis(ethylacetoacetate) titanium, monoethoxy·tris(ethylacetoacetate) titanium, mono-n-propoxy·tris(ethylacetoacetate) titanium, mono-i-propoxy·tris(ethylacetoacetate) titanium, mono-n-butoxy·tris(ethylacetoacetate) titanium, mono-sec-butoxy·tris(ethylacetoacetate) titanium, mono-t-butoxy·tris(ethylacetoacetate) titanium, tetrakis(ethylacetoacetate) titanium, mono(acetylacetonate)tris(ethylacetoacetate) titanium, bis(acetylacetonate)bis(ethylacetoacetate) titanium, and tris(acetylacetonate)mono(ethylacetoacetate) titanium; zirconium chelate compounds such as triethoxy·mono(acetylacetonate) zirconium, tri-n-propoxy·mono(acetylacetonate) zirconium, tri-i-propoxy·mono(acetylacetonate) zirconium, tri-n-butoxy·mono(acetylacetonate) zirconium, tri-sec-butoxy·mono(acetylacetonate) zirconium, tri-t-butoxy·mono(acetylacetonate) zirconium, diethoxy·bis(acetylacetonate) zirconium, di-n-propoxy·bis(acetylacetonate) zirconium, di-i-propoxy·bis(acetylacetonate) zirconium, di-n-butoxy·bis(acetylacetonate) zirconium, di-sec-butoxy·bis(acetylacetonate) zirconium, di-t-butoxy·bis(acetylacetonate) zirconium, monoethoxy·tris(acetylacetonate) zirconium, mono-n-propoxy·tris(acetylacetonate) zirconium, mono-i-propoxy·tris(acetylacetonate) zirconium, mono-n-butoxy·tris(acetylacetonate) zirconium, mono-sec-butoxy·tris(acetylacetonate) zirconium, mono-t-butoxy·tris(acetylacetonate) zirconium, tetrakis(acetylacetonate) zirconium, triethoxy·mono(ethylacetoacetate) zirconium, tri-n-propoxy·mono(ethylacetoacetate) zirconium, tri-i-propoxy·mono(ethylacetoacetate) zirconium, tri-n-butoxy·mono(ethylacetoacetate) zirconium, tri-sec-butoxy·mono(ethylacetoacetate) zirconium, tri-t-butoxy·mono(ethylacetoacetate) zirconium, diethoxy·bis(ethylacetoacetate) zirconium, di-n-propoxy·bis(ethylacetoacetate) zirconium, di-i-propoxy·bis(ethylacetoacetate) zirconium, di-n-butoxy·bis(ethylacetoacetate) zirconium, di-sec-butoxy·bis(ethylacetoacetate) zirconium, di-t-butoxy·bis(ethylacetoacetate) zirconium, monoethoxy·tris(ethylacetoacetate) zirconium, mono-n-propoxy·tris(ethylacetoacetate) zirconium, mono-i-propoxy·tris(ethylacetoacetate) zirconium, mono-n-butoxy·tris(ethylacetoacetate) zirconium, mono-sec-butoxy·tris(ethylacetoacetate) zirconium, mono-t-butoxy·tris(ethylacetoacetate) zirconium, tetrakis(ethylacetoacetate) zirconium, mono(acetylacetonate)tris(ethylacetoacetate) zirconium, bis(acetylacetonate)bis(ethylacetoacetate) zirconium, and tris(acetylacetonate)mono(ethylacetoacetate) zirconium; and aluminum chelate compounds such as tris(acetylacetonate) aluminum and tris(ethylacetoacetate) aluminum, but are not limited thereto.

Examples of the organic acid as the hydrolysis catalyst include, but are not limited to, acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid.

Examples of the inorganic acid as the hydrolysis catalyst include, but are not limited to, hydrochloric acid, nitric acid, sulfuric acid, hydrofluoric acid, and phosphoric acid.

Examples of the organic base as the hydrolysis catalyst include, but are not limited to, pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide.

Examples of the inorganic base as the hydrolysis catalyst include, but are not limited to, ammonia, sodium hydroxide, potassium hydroxide, barium hydroxide, and calcium hydroxide.

Among these catalysts, metal chelate compounds, organic acids, and inorganic acids are preferable, and these may be used alone or in combination of two or more.

Among them, in the present invention, nitric acid can be suitably used as the hydrolysis catalyst. By using nitric acid, the storage stability of the reaction solution after hydrolysis and condensation can be improved, and in particular, a change in the molecular weight of the hydrolysis condensate or its modified product can be suppressed. It has been found that the stability of the hydrolysis condensate or its modified product in the liquid depends on the pH of the solution. As a result of intensive studies, it has been found that the pH of the solution is in a stable region by using an appropriate amount of nitric acid.

In addition, as described above, nitric acid can also be used in obtaining a modified product of the hydrolysis condensate, for example, in capping the silanol group with an alcohol, and thus is also preferable from the viewpoint of being able to contribute to both reactions of hydrolysis and condensation of the hydrolyzable silane and alcohol capping of the hydrolysis condensate.

When hydrolysis and condensation are performed, an organic solvent may be used as a solvent, and specific examples thereof include: aliphatic hydrocarbon-based solvents such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon-based solvents such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, and n-amylnaphthalene; monoalcohol-based solvents such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, n-heptanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol-based solvents such as ethylene glycol, propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin; ketone-based solvents such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchon; ether-based solvents such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, propylene glycol monomethyl ether (1-methoxy-2-propanol), propylene glycol monoethyl ether (1-ethoxy-2-propanol), propylene glycol monopropyl ether, propylene glycol monobutyl ether, propylene glycol monomethyl ether acetate (1-methoxy-2-propanol monoacetate), dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester-based solvents such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethylene glycol diacetate, triethylene glycol methyl ether acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents such as N-methylformamide, N,N-dimethylformamide, N,N-diethylformamide, acetamide, N-methylacetamide, N,N-dimethylacetamide, N-methylpropionamide, and N-methyl-2-pyrrolidone; and sulfur-containing solvents such as dimethyl sulfide, diethyl sulfide, thiophene, tetrahydrothiophene, dimethyl sulfoxide, sulfolane, and 1,3-propane sultone, but are not limited thereto. These solvents can be used singly or in combination of two or more kinds thereof.

After completion of the hydrolysis and condensation reaction, the reaction solution is left as it is or diluted or concentrated; neutralized; and treated using an ion exchange resin, whereby a hydrolysis catalyst such as an acid or a base used for hydrolysis and condensation can be removed. In addition, before or after such treatment, alcohol and water as by-products, the hydrolysis catalyst used, and the like can be removed from the reaction solution by distillation under reduced pressure or the like.

The thus-obtained hydrolysis condensate or a modified product thereof (hereinafter, also referred to as polysiloxane) is obtained in the form of a polysiloxane varnish dissolved in an organic solvent, and can be used as it is for preparing the composition for forming a silicon-containing resist underlayer film. That is, the reaction solution can be used as it is (or diluted) for the preparation of the composition for forming a silicon-containing resist underlayer film, and at this time, the hydrolysis catalyst used for hydrolysis and condensation, by-products, and the like may remain in the reaction solution as long as the effect of the present invention is not impaired. For example, the hydrolysis catalyst or nitric acid used at the time of alcohol capping of the silanol group may remain in the polymer varnish solution in an amount of about 100 ppm to 5,000 ppm.

The obtained polysiloxane varnish may be subjected to solvent substitution or may be appropriately diluted with a solvent. If the storage stability of the obtained polysiloxane varnish is not poor, the organic solvent can be distilled off to set the concentration of the film-forming component to 100%. The film-forming component refers to a component obtained by removing the solvent component from all components of the composition.

The organic solvent used for solvent substitution, dilution, or the like of the polysiloxane varnish may be the same as or different from the organic solvent used for the hydrolysis and condensation reaction of the hydrolyzable silane. The diluting solvent is not particularly limited, and one kind or two or more kinds can be arbitrarily selected and used.

### <Component [C]: Solvent>

In the first embodiment, the solvent as the component [C] can be used without any particular limitation as long as it is a solvent capable of dissolving and mixing the component [A] and, if necessary, other components contained in the composition for forming a silicon-containing resist underlayer film.

In the second embodiment, the solvent as the component [C] can be used without particular limitation as long as it is a solvent capable of dissolving and mixing the component [A′] and the component [B] and, if necessary, other components contained in the composition for forming a silicon-containing resist underlayer film.

[C] the solvent is preferably an alcohol-based solvent, more preferably an alkylene glycol monoalkyl ether, which is an alcohol-based solvent, and still more preferably a propylene glycol monoalkyl ether. Since these solvents are also a capping agent for a silanol group of the hydrolysis condensate, it is possible to prepare the composition for forming a silicon-containing resist underlayer film from a solution obtained by preparing [A] the polysiloxane or [A′] the polysiloxane without requiring solvent substitution or the like.

Examples of the alkylene glycol monoalkyl ether include ethylene glycol monomethyl ether, ethylene glycol monoethyl ether, ethylene glycol monopropyl ether, ethylene glycol monobutyl ether, propylene glycol monomethyl ether (1-methoxy-2-propanol), propylene glycol monoethyl ether (1-ethoxy-2-propanol), methyl isobutyl carbinol, and propylene glycol monobutyl ether.

Specific examples of another [C] the solvent include methyl cellosolve acetate, ethyl cellosolve acetate, propyrene glycol propylene glycol monomethyl ether acetate (1-methoxy-2-propanol monoacetate), propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methyl butyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methyl-2-pyrrolidone, 4-methyl-2-pentanol, and γ-butyrolactone, and the solvent can be used alone or in combination of two or more.

The composition for forming a silicon-containing resist underlayer film of the present invention may contain water as a solvent. When water is contained as the solvent, the content thereof can be, for example, 30 mass % or less, preferably 20 mass % or less, and still more preferably 15 mass % or less with respect to the total mass of the solvent contained in the composition.

### <Component [D]: Curing Catalyst>

The composition for forming a silicon-containing resist underlayer film can be a composition not containing a curing catalyst, but preferably contains a curing catalyst (component [D]).

As the curing catalyst, ammonium salts, phosphines, phosphonium salts, sulfonium salts, and the like can be used. The following salts described as an example of the curing catalyst may be added in the form of a salt or may form a salt in the composition (one that is added as a separate compound at the time of addition and forms a salt in the system).

Examples of the ammonium salt include a quaternary ammonium salt having a structure represented by the formula (D-1):

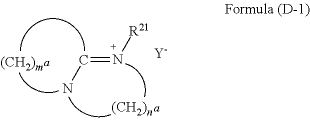

wherein m^{a} represents an integer of 2 to 11, n^{a} represents an integer of 2 to 3, R²¹ represents an alkyl group, an aryl group, or an aralkyl group, and Y⁻ represents an anion;
a quaternary ammonium salt having a structure represented by the formula (D-2):

R²²R²³R²⁴R²⁵N⁺Y⁻ Formula (D-2)
wherein R²², R²³, R²⁴, and R²⁵ each independently represent an alkyl group, an aryl group, or an aralkyl group, Y⁻ represents an anion, and R²², R²³, R²⁴, and R²⁵ are each bonded to the nitrogen atom;
a quaternary ammonium salt having a structure represented by the formula (D-3):

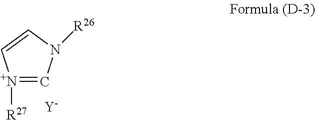

wherein R²⁶ and R²⁷ each independently represent an alkyl group, an aryl group, or an aralkyl group, and Y⁻ represents an anion;
a quaternary ammonium salt having a structure represented by the formula (D-4):

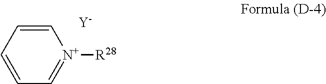

wherein R²⁸ represents an alkyl group, an aryl group, or an aralkyl group, and Y⁻ represents an anion;
a quaternary ammonium salt having a structure represented by the formula (D-5):

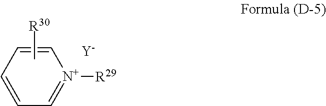

wherein R²⁹ and R³⁰ each independently represent an alkyl group, an aryl group, or an aralkyl group, and Y⁻ represents an anion; and
a tertiary ammonium salt having a structure represented by the formula (D-6):

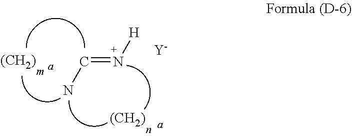

wherein m^{a} represents an integer of 2 to 11, n^{a} represents an integer of 2 to 3, and Y⁻ represents an anion.

Examples of the phosphonium salt include a quaternary phosphonium salt represented by the formula (D-7):

R³¹R³²R³³R³⁴P⁺Y⁻ Formula (D-7)
wherein R³¹, R³², R³³, and R³⁴ each independently represent an alkyl group, an aryl group, or an aralkyl group, Y⁻ represents an anion, and R³¹, R³², R³³, and R³⁴ are each bonded to the phosphorus atom.

Examples of the sulfonium salt include a tertiary sulfonium salt represented by the formula (D-8):

R³⁵R³⁶R³⁷S⁺Y⁻ Formula (D-8)
wherein R³⁵, R³⁶, and R³⁷ each independently represent an alkyl group, an aryl group, or an aralkyl group, Y⁻ represents an anion, and R³⁵, R³⁶, and R³⁷ are each bonded to the sulfur atom.

The compound of the formula (D-1) is a quaternary ammonium salt derived from an amine, m^{a} represents an integer of 2 to 11, and n^{a} represents an integer of 2 to 3. R²¹ of this quaternary ammonium salt represents, for example, an alkyl group having 1 to 18 and preferably 2 to 10 carbon atoms, an aryl group having 6 to 18 carbon atoms, or an aralkyl group having 7 to 18 carbon atoms, and examples thereof include a linear alkyl group such as an ethyl group, a propyl group, or a butyl group, a benzyl group, a cyclohexyl group, a cyclohexylmethyl group, a dicyclopentadienyl group, and the like. Examples of the anion (Y⁻) include halide ions such as a chlorine ion (Cl⁻), a bromine ion (Br⁻), and an iodine ion (I⁻), and acid groups such as carboxylate (—COO⁻), sulfonate (−SO₃⁻), and alcoholate (—O⁻).

The compound of the formula (D-2) is a quaternary ammonium salt represented by R²²R²³R²⁴R²⁵N⁺Y⁻. R²², R²³, R²⁴, and R²⁵ of this quaternary ammonium salt are, for example, an alkyl group having 1 to 18 carbon atoms such as an ethyl group, a propyl group, a butyl group, a cyclohexyl group, and a cyclohexylmethyl group, an aryl group having 6 to 18 carbon atoms such as a phenyl group, or an aralkyl group having 7 to 18 carbon atoms such as a benzyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). This quaternary ammonium salt can be obtained as a commercially available product, and examples thereof include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of the formula (D-3) is a quaternary ammonium salt derived from a 1-substituted imidazole, the number of carbon atoms of R²⁶ and R²⁷ is, for example, 1 to 18, and the total number of carbon atoms of R²⁶ and R²⁷ is preferably 7 or more. Examples of R²⁶ include an alkyl group such as a methyl group, an ethyl group, and a propyl group, an aryl group such as a phenyl group, and an aralkyl group such as a benzyl group, and examples of R²⁷ include an aralkyl group such as a benzyl group, and an alkyl group such as an octyl group and an octadecyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃), and alcoholate (—O⁻). This compound can also be obtained as a commercially available product, but can be produced by reacting an imidazole-based compound such as 1-methylimidazole or 1-benzylimidazole with an aralkyl halide, an alkyl halide, or an aryl halide such as benzyl bromide, methyl bromide, or benzene bromide.

The compound of the formula (D-4) is a quaternary ammonium salt derived from pyridine, and R²⁸ is, for example, an alkyl group having 1 to 18 carbon atoms and preferably 4 to 18 carbon atoms, an aryl group having 6 to 18 carbon atoms, or an aralkyl group having 7 to 18 carbon atoms, and examples thereof may include a butyl group, an octyl group, a benzyl group, and a lauryl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃), and alcoholate (—O⁻). This compound can also be obtained as a commercially available product, but can be produced, for example, by reacting pyridine with an alkyl halide or an aryl halide such as lauryl chloride, benzyl chloride, benzyl bromide, methyl bromide, or octyl bromide. Examples of the compound include N-laurylpyridinium chloride and N-benzylpyridinium bromide.

The compound of the formula (D-5) is a quaternary ammonium salt derived from a substituted pyridine represented by picoline or the like, and R²⁹ is, for example, an alkyl group having 1 to 18 carbon atoms, preferably 4 to 18 carbon atoms, an aryl group having 6 to 18 carbon atoms, or an aralkyl group having 7 to 18 carbon atoms, and examples thereof may include a methyl group, an octyl group, a lauryl group, and a benzyl group. R³⁰ is, for example, an alkyl group having 1 to 18 carbon atoms, an aryl group having 6 to 18 carbon atoms, or an aralkyl group having 7 to 18 carbon atoms, and for example, when the compound represented by the formula (D-5) is a quaternary ammonium derived from picoline, R³⁰ is a methyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). This compound can also be obtained as a commercially available product, but can be produced, for example, by reacting a substituted pyridine such as picoline with an alkyl halide or an aryl halide such as methyl bromide, octyl bromide, lauryl chloride, benzyl chloride, or benzyl bromide. Examples of the compound include N-benzylpicolinium chloride, N-benzylpicolinium bromide, and N-laurylpicolinium chloride.

The compound of the formula (D-6) is a tertiary ammonium salt derived from an amine, m^{a} represents an integer of 2 to 11, and n^{a} represents 2 or 3. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). The present compound can be produced by a reaction of an amine with a weak acid such as a carboxylic acid or phenol. Examples of the carboxylic acid include formic acid and acetic acid, and when formic acid is used, the anion (Y⁻) is (HCOO⁻), and when acetic acid is used, the anion (Y⁻) is (CH₃COO⁻). When phenol is used, the anion (Y⁻) is (C₆H₅O⁻).

The compound of the formula (D-7) is a quaternary phosphonium salt having the structure of R³¹R³²R³³R³⁴P⁺Y⁻. R³¹, R³², R³³, and R³⁴ are, for example, an alkyl group having 1 to 18 carbon atoms such as an ethyl group, a propyl group, a butyl group, and cyclohexylmethyl, an aryl group having 6 to 18 carbon atoms such as a phenyl group, or an aralkyl group having 7 to 18 carbon atoms such as a benzyl group, and preferably, three of four substituents: R³¹ to R³⁴ are an unsubstituted phenyl group or a substituted phenyl group, and for example, a phenyl group or a tolyl group can be exemplified, and the remaining one is an alkyl group having 1 to 18 carbon atoms, an aryl group having 6 to 18 carbon atoms, or an aralkyl group having 7 to 18 carbon atoms. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). This compound can be obtained as a commercial product, and examples thereof include: tetraalkylphosphonium halides such as tetra-n-butylphosphonium halides and tetra-n-propylphosphonium halides; trialkylbenzylphosphonium halides such as triethylbenzylphosphonium halides; triphenylmonoalkylphosphonium halides such as triphenylmethylphosphonium halides and triphenylethylphosphonium halides; triphenylbenzylphosphonium halides, tetraphenylphosphonium halides, tritolylmonoarylphosphonium halides, and tritolylmonoalkylphosphonium halides (In the above, the halogen atom is a chlorine atom or a bromine atom.). In particular, triphenylmonoalkylphosphonium halides such as triphenylmethylphosphonium halides and triphenylethylphosphonium halides; triphenylmonoarylphosphonium halides such as triphenylbenzylphosphonium halides; tritolylmonoarylphosphonium halides such as tritolylmonophenylphosphonium halides; and tritolylmonoalkylphosphonium halides such as tritolylmonomethylphosphonium halides (In the above, the halogen atom is a chlorine atom or a bromine atom.) are preferable.

Examples of the phosphines include: primary phosphines such as methylphosphine, ethylphosphine, propylphosphine, isopropylphosphine, isobutylphosphine, and phenylphosphine; secondary phosphines such as dimethylphosphine, diethylphosphine, diisopropylphosphine, diisoamylphosphine, and diphenylphosphine; and tertiary phosphines such as trimethylphosphine, triethylphosphine, triphenylphosphine, methyldiphenylphosphine, and dimethylphenylphosphine.

The compound of the formula (D-8) is a tertiary sulfonium salt having the structure of R³⁵R³⁶R³⁷S⁺Y⁻. R³⁵, R³⁶, and R³⁷ are, for example, an alkyl group having 1 to 18 carbon atoms such as an ethyl group, a propyl group, a butyl group, and cyclohexylmethyl, an aryl group having 6 to 18 carbon atoms such as a phenyl group, or an aralkyl group having 7 to 18 carbon atoms such as a benzyl group, and preferably, two of three substituents: R³⁵ to R³⁷ are an unsubstituted phenyl group or a substituted phenyl group, and for example, a phenyl group or a tolyl group can be exemplified, and the remaining one is an alkyl group having 1 to 18 carbon atoms, an aryl group having 6 to 18 carbon atoms, or an aralkyl group having 7 to 18 carbon atoms. Examples of the anion (Y⁻) include halide ions such as chlorine ion (Cl⁻), bromine ion (Br⁻), and iodine ion (I⁻), and acid groups such as carboxylate (—COO⁻), sulfonate (—SO₃⁻), alcoholate (—O⁻), maleate anion, and nitrate anion. This compound can be obtained as a commercially available product, and examples thereof include trialkylsulfonium halides such as tri-n-butylsulfonium halide and tri-n-propylsulfonium halide; dialkylbenzylsulfonium halides such as diethylbenzylsulfonium halide; diphenylmonoalkylsulfonium halides such as diphenylmethylsulfonium halide and diphenylethylsulfonium halide; triphenylsulfonium halide (In the above, the halogen atom is a chlorine atom or a bromine atom.); trialkylsulfonium carboxylates such as tri-n-butylsulfonium carboxylate and tri-n-propylsulfonium carboxylat; dialkylbenzylsulfonium carboxylates such as diethylbenzylsulfonium carboxylate; diphenylmonoalkylsulfonium carboxylates such as diphenylmethylsulfonium carboxylate and diphenylethylsulfonium carboxylate; and triphenylsulfonium carboxylate. Triphenylsulfonium halides and triphenylsulfonium carboxylates can be preferably used.

In addition, a nitrogen-containing silane compound can be added as a curing catalyst. Examples of the nitrogen-containing silane compound include imidazole ring-containing silane compounds such as N-(3-triethoxysilypropyl)-4,5-dihydroimidazole.

The content of [D] the curing catalyst in the composition for forming a silicon-containing resist underlayer film as the first embodiment is preferably 0.1 to 30 parts by mass, more preferably 0.5 to 25 parts by mass, and still more preferably 1 to 20 parts by mass with respect to 100 parts by mass of [A] the polysiloxane from the viewpoint of more sufficiently obtaining the effect of the present invention.

The content of [D] the curing catalyst in the composition for forming a silicon-containing resist underlayer film as the second embodiment is preferably 0.1 to 30 parts by mass, more preferably 0.5 to 25 parts by mass, and still more preferably 1 to 20 parts by mass with respect to 100 parts by mass of [A′] the polysiloxane from the viewpoint of more sufficiently obtaining the effect of the present invention.

### <Component [E]: Nitric Acid>

The composition for forming a silicon-containing resist underlayer film preferably contains [E] nitric acid.

[E] nitric acid may be added at the time of preparing the composition for forming a silicon-containing resist underlayer film, but in the production of the polysiloxane described above, the nitric acid is used as a hydrolysis catalyst or at the time of alcohol capping of a silanol group, and the nitric acid remaining in the polysiloxane varnish can also be treated as [E] nitric acid.

The blending amount of [E] the nitric acid (residual nitric acid amount) can be, for example, 0.0001 mass % to 1 mass %, 0.001 mass % to 0.1 mass %, or 0.005 mass % to 0.05 mass % based on the total mass of the composition for forming a silicon-containing resist underlayer film.

### <Other Additives>

In the composition for forming a silicon-containing resist underlayer film, various additives can be blended depending on the use of the composition.

Examples of the additive include known additives blended in a material (composition) for forming various films that can be used for manufacturing a semiconductor device, such as a resist underlayer film, an antireflection film, and a pattern inversion film, such as a crosslinking agent, a crosslinking catalyst, a stabilizer (organic acids, water, alcohols, etc.), an organic polymer, an acid generator, a surfactant (nonionic surfactants, anionic surfactants, cationic surfactants, silicon-based surfactants, fluorine-based surfactants, UV-curable surfactants, etc.), a pH adjuster, a metal oxide, a rheology modifier, and an adhesion aid.

Hereinafter, various additives will be exemplified, but the additives are not limited thereto.

### «Stabilizer»

The stabilizer may be added for the purpose of stabilizing the hydrolysis condensate of the hydrolyzable silanes, and as a specific example thereof, an organic acid, water, alcohol, or a combination thereof may be added.

Examples of the organic acid include oxalic acid, malonic acid, methylmalonic acid, succinic acid, maleic acid, malic acid, tartaric acid, phthalic acid, citric acid, glutaric acid, lactic acid, and salicylic acid. Among them, oxalic acid and maleic acid are preferable. When the organic acid is added, the addition amount thereof is 0.1 to 5.0 mass % with respect to the mass of the hydrolysis condensate of the hydrolyzable silanes. These organic acids can also serve as a pH adjuster.

As the water, pure water, ultrapure water, ion-exchanged water, or the like can be used, and when used, the addition amount thereof may be 1 to 20 parts by mass with respect to 100 parts by mass of the composition for forming a silicon-containing resist underlayer film.

The alcohol is preferably one that easily scatters by heating after application, and examples thereof include methanol, ethanol, propanol, i-propanol, and butanol. When an alcohol is added, the addition amount thereof may be 1 to 20 parts by mass with respect to 100 parts by mass of the composition for forming a silicon-containing resist underlayer film.

### «Organic Polymer»

The organic polymer added to the composition for forming a silicon-containing resist underlayer film can adjust the dry etching rate (amount of reduction in film thickness per unit time) of a film formed from the composition (resist underlayer film), the attenuation coefficient, the refractive index, and the like. The organic polymer is not particularly limited, and is appropriately selected from various organic polymers (polycondensation polymers and addition polymerization polymers) according to the purpose of addition.

Specific examples thereof include addition polymerization polymers and polycondensation polymers such as polyester, polystyrene, polyimide, acrylic polymers, methacrylic polymers, polyvinyl ether, phenol novolac, naphthol novolac, polyether, polyamide, and polycarbonate.

In the present invention, an organic polymer containing an aromatic ring or a heteroaromatic ring such as a benzene ring, a naphthalene ring, an anthracene ring, a triazine ring, a quinoline ring, or a quinoxaline ring, each of which functions as an absorption site, can also be suitably used when such a function is required. Specific examples of such an organic polymer include, but are not limited to, addition polymerization polymers containing an addition polymerizable monomer such as benzyl acrylate, benzyl methacrylate, phenyl acrylate, naphthyl acrylate, anthryl methacrylate, anthryl methyl methacrylate, styrene, hydroxystyrene, benzyl vinyl ether, and N-phenyl maleimide as a structural unit thereof, and polycondensation polymers such as phenol novolac and naphthol novolac.

When an addition polymerization polymer is used as the organic polymer, the polymer may be either a homopolymer or a copolymer.

An addition polymerizable monomer is used in the production of the addition polymerization polymer, and specific examples of such an addition polymerizable monomer include, but are not limited to, acrylic acid, methacrylic acid, an acrylic ester compound, a methacrylic ester compound, an acrylamide compound, a methacrylamide compound, a vinyl compound, a styrene compound, a maleimide compound, maleic anhydride, and acrylonitrile.

Specific examples of the acrylic ester compound include methyl acrylate, ethyl acrylate, normal hexyl acrylate, i-propyl acrylate, cyclohexyl acrylate, benzyl acrylate, phenyl acrylate, anthryl methyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantyl acrylate, 5-acryloyloxy-6-hydroxynorbornene-2-carboxylic-6-lactone, 3-acryloxypropyl triethoxysilane, and glycidyl acrylate, but are not limited thereto.

Specific examples of the methacrylic ester compound include, but are not limited to, methyl methacrylate, ethyl methacrylate, normal hexyl methacrylate, i-propyl methacrylate, cyclohexyl methacrylate, benzyl methacrylate, phenyl methacrylate, anthryl methyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantyl methacrylate, 5-methacryloyloxy-6-hydroxynorbornene-2-carboxylic-6-lactone, 3-methacryloxypropyl triethoxysilane, glycidyl methacrylate, 2-phenylethyl methacrylate, hydroxyphenyl methacrylate, and bromophenyl methacrylate.

Specific examples of the acrylamide compound include, but are not limited to, acrylamide, N-methylacrylamide, N-ethylacrylamide, N-benzylacrylamide, N-phenylacrylamide, N,N-dimethylacrylamide, and N-anthrylacrylamide.

Specific examples of the methacrylamide compound include, but are not limited to, methacrylamide, N-methylmethacrylamide, N-ethylmethacrylamide, N-benzylmethacrylamide, N-phenylmethacrylamide, N,N-dimethylmethacrylamide, and N-anthrylmethacrylamide.

Specific examples of the vinyl compound include, but are not limited to, vinyl alcohol, 2-hydroxyethyl vinyl ether, methyl vinyl ether, ethyl vinyl ether, benzyl vinyl ether, vinyl acetic acid, vinyl trimethoxysilane, 2-chloroethyl vinyl ether, 2-methoxyethyl vinyl ether, vinyl naphthalene, and vinyl anthracene.

Specific examples of the styrene compound include, but are not limited to, styrene, hydroxystyrene, chlorostyrene, bromostyrene, methoxystyrene, cyanostyrene, and acetylstyrene.

Examples of the maleimide compound include, but are not limited to, maleimide, N-methylmaleimide, N-phenylmaleimide, N-cyclohexylmaleimide, N-benzylmaleimide, and N-hydroxyethylmaleimide.

When a polycondensation polymer is used as the polymer, examples of such a polymer include a polycondensation polymer of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride. In addition, examples thereof include polyesters, polyamides, and polyimides such as polypyrromellitimide, poly(p-phenylene terephthalamide), polybutylene terephthalate, and polyethylene terephthalate, but are not limited thereto.

When the organic polymer contains a hydroxy group, the hydroxy group can undergo a crosslinking reaction with the hydrolysis condensate or the like.

The weight average molecular weight of the organic polymer can be usually 1,000 to 1 million. When an organic polymer is blended, the weight average molecular weight thereof can be, for example, 3,000 to 300,000, 5,000 to 300,000, or 10,000 to 200,000 from the viewpoint of sufficiently obtaining the effect of the function as a polymer and suppressing precipitation in the composition.

Such organic polymers may be used singly or in combination of two or more kinds thereof.

When the composition for forming a silicon-containing resist underlayer film contains an organic polymer, the content thereof is appropriately determined in consideration of the function of the organic polymer and the like, and thus cannot be generally defined. However, usually, the content thereof can be in the range of 1 to 200 mass % with respect to the mass of [A] the polysiloxane or [A′] the polysiloxane. From the viewpoint of suppressing precipitation in the composition and the like, the content can be, for example, 100 mass % or less, preferably 50 mass % or less, and more preferably 30 mass % or less. From the viewpoint of sufficiently obtaining the effect and the like, the content can be, for example, 5 mass % or more, preferably 10 mass % or more, and more preferably 30 mass % or more.

### «Acid Generator»

Examples of the acid generator include a thermal acid generator and a photoacid generator, and a photoacid generator can be preferably used.

Examples of the photoacid generator include, but are not limited to, onium salt compounds, sulfonimide compounds, and disulfonyldiazomethane compounds. The photoacid generator may also function as a curing catalyst depending on the type thereof, for example, a nitrate, a carboxylate such as a maleate, and a hydrochloride in the onium salt compound described later.

Examples of the thermal acid generator include, but are not limited to, tetramethylammonium nitrate.

Specific examples of the onium salt compound include: iodonium salt compounds such as diphenyliodonium hexafluorophosphate, diphenyliodonium trifluoromethanesulfonate, diphenyliodonium nonafluoronormal butanesulfonate, diphenyliodonium perfluoronormal octanesulfonate, diphenyliodonium camphor sulfonate, bis(4-t-butylphenyl) iodonium camphor sulfonate, and bis(4-t-butylphenyl) iodonium trifluoromethanesulfonate; and sulfonium salt compounds such as triphenylsulfonium hexafluoroantimonate, triphenylsulfonium nonafluoronormal butanesulfonate, triphenylsulfonium camphor sulfonate, triphenylsulfonium trifluoromethanesulfonate, triphenylsulfonium nitrate, triphenylsulfonium trifluoroacetate, triphenylsulfonium maleate, and triphenylsulfonium chloride, but are not limited thereto.

Specific examples of the sulfonimide compound include N-(trifluoromethanesulfonyloxy) succinimide, N-(nonafluoronormalbutanesulfonyloxy) succinimide, N-(camphorsulfonyloxy) succinimide, and N-(trifluoromethanesulfonyloxy) naphthalimide, but are not limited thereto.

Specific examples of the disulfonyl diazomethane compound include bis(trifluoromethylsulfonyl) diazomethane, bis(cyclohexylsulfonyl) diazomethane, bis(phenylsulfonyl) diazomethane, bis(p-toluenesulfonyl) diazomethane, bis(2,4-dimethylbenzenesulfonyl) diazomethane, methylsulfonyl-p-toluenesulfonyl diazomethane, and the like, but are not limited thereto.

When the composition for forming a silicon-containing resist underlayer film contains an acid generator, the content thereof is appropriately determined in consideration of the type of the acid generator and the like, and thus cannot be generally defined, but is usually in the range of 0.01 to 5 mass % with respect to the mass of [A] the polysiloxane or [A′] the polysiloxane, and is preferably 3 mass % or less, more preferably 1 mass % or less from the viewpoint of suppressing precipitation of the acid generator in the composition and the like, and is preferably 0.1 mass % or more, more preferably 0.5 mass % or more from the viewpoint of sufficiently obtaining the effect and the like.

The acid generator can be used singly or in combination of two or more kinds thereof, and a photoacid generator and a thermal acid generator may be used in combination.

### «Surfactant»

The surfactant is effective for suppressing generation of pinholes, striation, and the like when the composition for forming a silicon-containing resist underlayer film is applied to a substrate. Examples of the surfactant include a nonionic surfactant, an anionic surfactant, a cationic surfactant, a silicon-based surfactant, a fluorine-based surfactant, and a UV-curable surfactant. More specific examples thereof include: nonionic surfactants such as polyoxyethylene alkyl ethers such as polyoxyethylene lauryl ether, polyoxyethylene stearyl ether, polyoxyethylene cetyl ether, and polyoxyethylene oleyl ether; polyoxyethylene alkyl aryl ethers such as polyoxyethylene octylphenol ether and polyoxyethylene nonylphenol ether; polyoxyethylene-polyoxypropylene block copolymers; sorbitan fatty acid esters such as sorbitan monolaurate, sorbitan monopalmitate, sorbitan monostearate, sorbitan monooleate, sorbitan trioleate, and sorbitan tristearate; and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants such as trade names EFTOP (registered trademark) EF301, EF303, and EF352 (manufactured by Mitsubishi Materials Electronic Chemicals Co., Ltd. (former TOCHEM PRODUCTS)), trade names MEGAFACE (registered trademark) F171, F173, R-08, R-30, R-30N, and R-40 LM (manufactured by DIC Corporation), Fluorad FC430 and FC431 (manufactured by 3M Japan Limited), trade name AsahiGuard (registered trademark) AG710 (manufactured by AGC Inc.), and Surflon (registered trademark) S-382, SC101, SC102, SC103, SC104, SC105, and SC106 (manufactured by AGC SEIMI CHEMICAL CO., LTD.); and organosiloxane polymer-KP341 (manufactured by Shin-Etsu Chemical Co., Ltd.), but are not limited thereto.

The surfactant may be used singly or in combination of two or more kinds thereof.

When the composition for forming a silicon-containing resist underlayer film contains a surfactant, the content thereof is usually 0.0001 to 5 mass %, preferably 0.001 to 4 mass %, and more preferably 0.01 to 3 mass % with respect to the mass of [A] the polysiloxane or [A′] the polysiloxane.

### «Rheology Modifier»

The rheology modifier is added mainly for the purpose of improving the fluidity of the composition for forming a silicon-containing resist underlayer film, and particularly in the baking step, for the purpose of improving the film thickness uniformity of the film to be formed and improving the filling property of the composition into a hole. Specific examples thereof include phthalic acid derivatives such as dimethyl phthalate, diethyl phthalate, di-i-butyl phthalate, dihexyl phthalate, and butyl i-decyl phthalate; adipic acid derivatives such as di-n-butyl adipate, di-i-butyl adipate, di-i-octyl adipate, and octyl decyl adipate; maleic acid derivatives such as di-n-butyl malate, diethyl malate, and dinonyl malate; oleic acid derivatives such as methyl olate, butyl olate, and tetrahydrofurfuryl olate; and stearic acid derivatives such as n-butyl stearate and glyceryl stearate.

When these rheology modifiers are used, the addition amount thereof is usually less than 30 mass % with respect to all film-forming components of the composition for forming a silicon-containing resist underlayer film.

### «Adhesion Aid»

The adhesion aid is added mainly for the purpose of improving adhesion between the substrate or the resist and the film (resist underlayer film) formed from the composition for forming a silicon-containing resist underlayer film, and particularly for the purpose of suppressing or preventing peeling of the resist in development. Specific examples include: chlorosilanes such as trimethylchlorosilane, dimethylvinylchlorosilane, methyldiphenylchlorosilane, and chloromethyldimethylchlorosilane; alkoxysilanes such as trimethylmethoxysilane, dimethyldiethoxysilane, methyldimethoxysilane, and dimethylvinylethoxysilane; silazanes such as hexamethyldisilazane, N,N′-bis(trimethylsilyl) urea, dimethyltrimethylsilylamine, and trimethylsilyl imidazole; other silanes such as γ-chloropropyltrimethoxysilane, γ-aminopropyltriethoxysilane, and γ-glycidoxypropyltrimethoxysilane; heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; ureas such as 1,1-dimethylurea and 1,3-dimethylurea; and thiourea compounds.

When these adhesion aids are used, the addition amount thereof is usually less than 5 mass %, preferably less than 2 mass %, based on the film-forming components of the composition for forming a silicon-containing resist underlayer film.

### «pH Adjuster»

In addition, examples of the pH adjuster can include acids having one or two or more carboxylic acid groups such as the organic acid mentioned above as the stabilizer, and others. When the pH adjuster is used, the addition amount thereof may be 0.01 to 20 parts by mass, 0.01 to 10 parts by mass, or 0.01 to 5 parts by mass with respect to 100 parts by mass of [A] the polysiloxane or [A′] the polysiloxane.

### «Metal Oxide»

Examples of the metal oxide that can be added to the composition for forming a silicon-containing resist underlayer film include, but are not limited to, an oxide of one kind or a combination of two or more kinds among metals such as tin (Sn), titanium (Ti), aluminum (Al), zirconium (Zr), zinc (Zn), niobium (Nb), tantalum (Ta), and tungsten (W), and metalloids such as boron (B), silicon (Si), germanium (Ge), arsenic (As), antimony (Sb), and tellurium (Te).

The concentration of the film-forming component in the composition for forming a silicon-containing resist underlayer film can be, for example, 0.1 to 50 mass %, 0.1 to 30 mass %, 0.1 to 25 mass %, or 0.5 to 20.0 mass % with respect to the total mass of the composition.

The content of [A] the polysiloxane or [A′] the polysiloxane in the film-forming component is usually 20 mass % to 100 mass %, but from the viewpoint of obtaining the effect of the present invention with good reproducibility or the like, the lower limit thereof is preferably 50 mass %, more preferably 60 mass %, still more preferably 70 mass %, and still more preferably 80 mass %, the upper limit thereof is preferably 99 mass %, and the rest thereof can be used as an additive described later.

In addition, the composition for forming a silicon-containing resist underlayer film preferably has a pH of 2 to 5, and more preferably has a pH of 3 to 4.

The composition for forming a silicon-containing resist underlayer film of the first embodiment can be produced by mixing [A] a polysiloxane, [C] the solvent, and if other components are contained as desired, the other components. At this time, a solution containing [A] the polysiloxane may be prepared in advance, and this solution may be mixed with [C] the solvent or other components.

The mixing order is not particularly limited. For example, the solution containing [A] the polysiloxane may be added with [C] the solvent and mixed, and other components may be added to the mixture, or the solution containing [A] the polysiloxane, [C] the solvent, and other components may be simultaneously mixed.

If necessary, [C] the solvent may be further added at the end, or some components relatively soluble in [C] the solvent may not be included in the mixture, and the components may be added at the end. However, from the viewpoint of suppressing aggregation and separation of the components and preparing a composition excellent in uniformity with good reproducibility, it is preferable to prepare a solution in which [A] the polysiloxane is dissolved well in advance, and prepare the composition using the solution. Note that [A] the polysiloxane may aggregate or precipitate when mixed, depending on the type and amount of [C] the solvent to be mixed together, the amount and properties of other components, and the like. In addition, when the composition is prepared using a solution in which [A] the polysiloxane is dissolved, it is also noted that it is necessary to determine the concentration of the solution of [A] the polysiloxane and the use amount thereof so that [A] the polysiloxane in the finally obtained composition is in a desired amount.

In preparation of the composition, heating may be appropriately performed as long as the components are not decomposed or altered.

The composition for forming a silicon-containing resist underlayer film of the second embodiment can be produced by mixing [A′] the polysiloxane, [B] the hydrolyzable silane (A) having an alkyl iodide group, [C] the solvent, and if other components are contained as desired, the other components. At this time, a solution containing [A′] the polysiloxane may be prepared in advance, and this solution may be mixed with [B] the hydrolyzable silane (A) having an alkyl iodide group, [C] the solvent, and other components.

The mixing order is not particularly limited. For example, the solution containing [A′] the polysiloxane may be added and mixed with [B] the hydrolyzable silane (A) having an alkyl iodide group and [C] the solvent, and other components may be added to the mixture, or the solution containing [A′] the polysiloxane, [B] the hydrolyzable silane (A) having an alkyl iodide group, [C] the solvent, and other components may be simultaneously mixed.

If necessary, [C] the solvent may be further added at the end, or some components relatively soluble in [C] the solvent may not be included in the mixture, and the components may be added at the end. However, from the viewpoint of suppressing aggregation and separation of the components and preparing a composition excellent in uniformity with good reproducibility, it is preferable to prepare a solution in which [A′] the polysiloxane is dissolved well in advance, and prepare the composition using the solution. Note that [A′] the polysiloxane may aggregate or precipitate when mixed, depending on the type and amount of [B] the hydrolyzable silane (A) having an alkyl iodide group and [C] the solvent to be mixed together, the amount and properties of other components, and the like. In addition, when the composition is prepared using a solution in which [A′] the polysiloxane is dissolved, it is also noted that it is necessary to determine the concentration of the solution of [A′] the polysiloxane and the use amount thereof so that [A′] the polysiloxane in the finally obtained composition is in a desired amount.

In preparation of the composition, heating may be appropriately performed as long as the components are not decomposed or altered.

In the present invention, filtration may be performed using a submicrometer-order filter or the like at a stage in the middle of producing the composition for forming a silicon-containing resist underlayer film or after mixing all the components. Although the material type of the filter used at this time is not limited, for example, a nylon filter, a fluororesin filter, or the like can be used.

The composition for forming a silicon-containing resist underlayer film of the present invention can be suitably used as a composition for forming a resist underlayer film used in a lithography process.

### (Resist Underlayer Film, Substrate for Semiconductor Processing, Patterning Process, and Method for Manufacturing Semiconductor Device)

Hereinafter, as one embodiment of the present invention, a resist underlayer film, a substrate for semiconductor processing, a patterning process, and a method for manufacturing a semiconductor device using the composition for forming a silicon-containing resist underlayer film of the present invention will be described.

The resist underlayer film of the present invention is a cured product of the composition for forming a silicon-containing resist underlayer film of the present invention.

The substrate for semiconductor processing of the present invention includes the resist underlayer film of the present invention.

The method for manufacturing a semiconductor element includes:
a step of forming an organic underlayer film on a substrate;
a step of forming a resist underlayer film on the organic underlayer film using the composition for forming a silicon-containing resist underlayer film of the present invention; and
a step of forming a resist film on the resist underlayer film.

The patterning process of the present invention includes:
a step of forming an organic underlayer film on a semiconductor substrate;
a step of forming a resist underlayer film by applying and baking the composition for forming a silicon-containing resist underlayer film of the present invention on the organic underlayer film;
a step of forming a resist film by applying a composition for forming a resist film on the resist underlayer film;
a step of obtaining a resist pattern by exposing and developing the resist film;
a step of etching the resist underlayer film by using the resist pattern as a mask; and
a step of etching the organic underlayer film by using the patterned resist underlayer film as a mask.

First, the composition for forming a silicon-containing resist underlayer film of the present invention is applied onto a substrate used for manufacturing a precision integrated circuit element [for example, a semiconductor substrate such as a silicon wafer coated with a silicon oxide film, a silicon nitride film, or a silicon oxynitride film, a silicon nitride substrate, a quartz substrate, a glass substrate (including alkali-free glass, low-alkali glass, and crystallized glass), a glass substrate on which an indium tin oxide (ITO) film or an indium zinc oxide (IZO) film is formed, a plastic (polyimide, PET, etc.) substrate, a low dielectric constant material (low-k material)-coated substrate, a flexible substrate, or the like] by an appropriate application method such as a spinner or a coater, and then baked using a heating means such as a hot plate to form a cured product of the composition, thereby forming a resist underlayer film. Hereinafter, in the present specification, the resist underlayer film refers to a film formed from the composition for forming a silicon-containing resist underlayer film of the present invention.

The baking conditions are appropriately selected from a baking temperature of 40 to 400° C., or 80 to 250° C., and a baking time of 0.3 to 60 minutes. Preferably, the baking temperature is 150 to 250° C., and the baking time is 0.5 to 2 minutes.

The thickness of the resist underlayer film formed here is, for example, 10 to 1,000 nm, 20 to 500 nm, 50 to 300 nm, 100 to 200 nm, or 10 to 150 nm.

As the composition for forming a silicon-containing resist underlayer film to be used at the time of forming the resist underlayer film, a composition for forming a silicon-containing resist underlayer film filtered through a nylon filter can be used. Here, the composition for forming a silicon-containing resist underlayer film that has been subjected to nylon filter filtration refers to a composition that has been subjected to nylon filter filtration at a stage in the middle of producing the composition for forming a silicon-containing resist underlayer film or after mixing all the components.

In the present invention, an embodiment is adopted in which an organic underlayer film is formed on a substrate and then a resist underlayer film is formed thereon, but an embodiment may be adopted in which an organic underlayer film is not provided in some cases.

The organic underlayer film used here is not particularly limited, and can be arbitrarily selected and used from those conventionally used in lithography process.

In an embodiment in which a substrate is provided with an organic underlayer film thereon, a resist underlayer film thereon, and a resist film to be described later thereon, a photoresist film thinly covering to prevent pattern collapse due to narrowed photoresist film pattern width makes it possible to process the substrate by selecting an appropriate etching gas to be described later. For example, the resist underlayer film can be processed using a fluorine-based gas having a sufficiently high etching rate with respect to the photoresist film as an etching gas, the organic underlayer film can be processed using an oxygen-based gas having a sufficiently high etching rate with respect to the resist underlayer film as an etching gas, and the substrate can be processed using a fluorine-based gas having a sufficiently high etching rate with respect to the organic underlayer film as an etching gas.

Note that the substrate and the coating method that can be used at this time are the same as those described above.

Next, for example, a layer of a photoresist material (resist film) is formed on the resist underlayer film. The resist film can be formed by a known method, that is, by applying and baking a coating type resist material (a composition for forming a resist film) on the resist underlayer film.

The thickness of the resist film is, for example, 10 to 10,000 nm, 100 to 2,000 nm, 200 to 1,000 nm, or 30 to 200 nm.

The photoresist material used for the resist film formed on the resist underlayer film is not particularly limited as long as it is sensitive to light (for example, KrF excimer laser, ArF excimer laser, or the like) used for exposure, and both a negative photoresist material and a positive photoresist material can be used. Examples thereof include: a positive photoresist material containing a novolak resin and 1,2-naphthoquinone diazide sulfonic acid ester; a chemically amplified photoresist material containing a binder having a group that is decomposed by an acid to increase the alkali dissolution rate and a photoacid generator; a chemically amplified photoresist material containing a low molecular compound that is decomposed by an acid to increase the alkali dissolution rate of the photoresist material, an alkali-soluble binder, and a photoacid generator; and a chemically amplified photoresist material containing a binder having a group that is decomposed by an acid to increase the alkali dissolution rate, a low molecular compound that is decomposed by an acid to increase the alkali dissolution rate of the photoresist material, and a photoacid generator.

Specific examples of commercially available products include APEX-E (trade name) manufactured by SIPLAY, PAR710 (trade name) manufactured by SUMITOMO CHEMICAL COMPANY, LIMITED, AR2772JN (trade name) manufactured by JSR Corporation, and SEPR430 (trade name) manufactured by Shin-Etsu Chemical Co., Ltd., but are not limited thereto. Further, examples thereof include a fluorine-containing atomic polymer-based photoresist material as described in Proc. SPIE, Vol. 3999, 330-334 (2000), Proc. SPIE, Vol. 3999, 357-364 (2000), or Proc. SPIE, Vol. 3999, 365-374 (2000).

For the resist film formed on the resist underlayer film, a resist film for electron beam lithography (also referred to as an electron beam resist film) or a resist film for EUV lithography (also referred to as an EUV resist film) can be used instead of the photoresist film, that is, the composition for forming a silicon-containing resist underlayer film of the present invention can be used for forming a resist underlayer film for electron beam lithography or for forming a resist underlayer film for EUV lithography. In particular, it is suitable as a composition for forming a resist underlayer film for EUV lithography.

As the electron beam resist material for forming an electron beam resist film, either a negative type material or a positive type material can be used. Specific examples thereof include: a chemically amplified resist material containing an acid generator and a binder having a group that is decomposed by an acid to change the alkali dissolution rate; a chemically amplified resist material containing an alkali-soluble binder, an acid generator, and a low-molecular compound that is decomposed by an acid to change the alkali dissolution rate of the resist material; a chemically amplified resist material containing an acid generator, a binder having a group that is decomposed by an acid to change the alkali dissolution rate, and a low-molecular compound that is decomposed by an acid to change the alkali dissolution rate of the resist material; a non-chemically amplified resist material containing a binder having a group that is decomposed by an electron beam to change the alkali dissolution rate; and a non-chemically amplified resist material containing a binder having a site that is cut by an electron beam to change the alkali dissolution rate. Even in the case of using these electron beam resist materials, a resist film pattern can be formed similarly to the case of using a photoresist material with an electron beam as an irradiation source.

As the EUV resist material for forming an EUV resist film, a methacrylate resin-based resist material or a metal oxide resist material can be used.

Examples of the metal oxide resist material include a coating composition containing a metal oxo-hydroxo network having an organic ligand through a metal carbon bond and/or a metal carboxylate bond described in JP 2019-113855 A.

In EUV lithography, LWR and sensitivity are usually in a trade-off relationship, and thus the composition for forming a silicon-containing resist underlayer film of the present invention capable of improving the sensitivity of the resist without lowering the LWR of the resist is suitable for EUV lithography and more suitable for EUV lithography using a metal oxide resist.

Next, the resist film formed on the resist underlayer film is exposed through a predetermined mask (reticle). For the exposure, a KrF excimer laser (wavelength: 248 nm), an ArF excimer laser (wavelength: 193 nm), an F₂ excimer laser (wavelength: 157 nm), EUV (wavelength: 13.5 nm), an electron beam, or the like can be used.

After the exposure, post exposure bake may be performed as necessary. The post exposure bake is performed under conditions appropriately selected from a heating temperature of 70 to 150° C. and a heating time of 0.3 to 10 minutes.

Next, development is performed with a developer (for example, an alkaline developer). As a result, for example, when a positive photoresist film is used, the photoresist film of the exposed portion is removed, and a photoresist film pattern is formed.

Examples of the developer (alkaline developer) include alkaline aqueous solutions (alkaline developers) such as: aqueous solutions of alkali metal hydroxides such as potassium hydroxide and sodium hydroxide; aqueous solutions of quaternary ammonium hydroxides such as tetramethylammonium hydroxide, tetraethylammonium hydroxide, and choline; and aqueous amine solutions such as ethanolamine, propylamine, and ethylenediamine. Furthermore, a surfactant or the like can be added to these developers. The conditions for development are appropriately selected from a temperature of 5 to 50° C. and a time of 10 to 600 seconds.

In the present invention, an organic solvent can be used as the developer, and development is performed with the developer (solvent) after exposure. As a result, for example, when a negative photoresist film is used, the photoresist film of the unexposed portion is removed, and a photoresist film pattern is formed.

Examples of the developer (organic solvent) include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Furthermore, a surfactant or the like can be added to these developers. As conditions for development, the temperature is appropriately selected from 5 to 50° C., and the time is appropriately selected from 10 to 600 seconds.

The pattern of the photoresist film (upper layer) thus formed is used as a protective film to remove the resist underlayer film (intermediate layer), and then the film including the patterned photoresist film and the patterned resist underlayer film (intermediate layer) is used as a protective film to remove the organic underlayer film (lower layer). Finally, the substrate is processed using the patterned resist underlayer film (intermediate layer) and the patterned organic underlayer film (lower layer) as protective films.

Removal (patterning) of the resist underlayer film (intermediate layer) performed using the pattern of the resist film (upper layer) as a protective film is performed by dry etching, and gases such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane can be used.

A halogen-based gas is preferably used for dry etching of the resist underlayer film. In dry etching using a halogen-based gas, a resist film (photoresist film) basically made of an organic substance is hardly removed. On the other hand, a resist underlayer film containing a large amount of silicon atoms is quickly removed with a halogen-based gas. Therefore, a decrease in the film thickness of the photoresist film due to dry etching of the resist underlayer film can be suppressed. As a result, the photoresist film can be used as a thin film. Therefore, dry etching of the resist underlayer film is preferably performed with a fluorine-based gas, and examples of the fluorine-based gas include tetrafluoromethane (CF₄), perfluorocyclobutane (C₄F₈), perfluoropropane (C₃F₈), trifluoromethane, and difluoromethane (CH₂F₂), but are not limited thereto.

When the organic underlayer film is provided between the substrate and the resist underlayer film, the organic underlayer film (lower layer) is preferably removed (patterned) by dry etching with an oxygen-based gas (oxygen gas, oxygen/carbonyl sulfide (COS) mixed gas, and the like), which is subsequently performed using the film including the patterned resist film (upper layer) and the patterned resist underlayer film (intermediate layer) as a protective film (together with the patterned resist film (upper layer) when it remains). This is because the resist underlayer film of the present invention containing a large amount of silicon atoms is hardly removed by dry etching using an oxygen-based gas.

Thereafter, the processing (patterning) of the (semiconductor) substrate performed using the patterned resist underlayer film (intermediate layer) and, if desired, the patterned organic underlayer film (lower layer) as protection films is preferably performed by dry etching using a fluorine-based gas.

Examples of the fluorine-based gas include tetrafluoromethane (CF₄), perfluorocyclobutane (C₄F₈), perfluoropropane (C₃F₈), trifluoromethane, and difluoromethane (CH₂F₂).

After the removal (patterning) of the organic underlayer film or after the processing (patterning) of the substrate, the organic underlayer film may be removed. The resist underlayer film can be removed by dry etching or wet etching (wet method).

The dry etching of the resist underlayer film is preferably performed with a fluorine-based gas as mentioned in the patterning, and examples thereof include tetrafluoromethane (CF₄), perfluorocyclobutane (C₄F₈), perfluoropropane (C₃F₈), trifluoromethane, and difluoromethane (CH₂F₂), but are not limited thereto.

Examples of the chemical liquid used for wet etching of the resist underlayer film include alkaline solutions such as dilute fluorinated acid (hydrofluoric acid), buffered fluorinated acid (mixed solution of HF and NH₄F), an aqueous solution containing hydrochloric acid and hydrogen peroxide (SC-2 chemical liquid), an aqueous solution containing sulfuric acid and hydrogen peroxide (SPM chemical liquid), an aqueous solution containing fluorinated acid and hydrogen peroxide (FPM chemical liquid), and an aqueous solution containing ammonia and hydrogen peroxide (SC-1 chemical liquid). Examples of the alkaline solution include, in addition to the ammonia hydrogen peroxide obtained by mixing ammonia, hydrogen peroxide water, and water (chemical liquid of SC-1), an aqueous solution containing 1 to 99 mass % of ammonia, tetramethylammonium hydroxide (TMAH), tetraethylammonium hydroxide, tetrapropylammonium hydroxide, tetrabutylammonium hydroxide, choline hydroxide, benzyltrimethylammonium hydroxide, benzyltriethylammonium hydroxide, DBU (diazabicycloundecene), DBN (diazabicyclononene), hydroxylamine, 1-butyl-1-methylpyrrolidinium hydroxide, 1-propyl-1-methylpyrrolidinium hydroxide, 1-butyl-1-methylpiperidinium hydroxide, 1-propyl-1-methylpiperidinium hydroxide, mepiquatonium hydroxide, trimethylsulfonium hydroxide, hydrazines, ethylenediamines, or guanidine. These chemical liquids can also be used in mixture.

An organic antireflection film can be formed on the resist underlayer film before the resist film is formed. The antireflection film composition to be used is not particularly limited, and for example, can be arbitrarily selected and used from those conventionally used in a lithography process, and the antireflection film can be formed by a commonly used method, for example, coating and baking by a spinner and a coater.

In addition, the substrate to which the composition for forming a silicon-containing resist underlayer film is applied may have an organic or inorganic antireflection film formed by a CVD method or the like on the surface thereof, and the resist underlayer film may be formed thereon. When the organic underlayer film is formed on the substrate and then the resist underlayer film of the present invention is formed thereon, the substrate to be used may have an organic or inorganic antireflection film formed by a CVD method or the like on the surface thereof.

The resist underlayer film formed from the composition for forming a silicon-containing resist underlayer film may also absorb light depending on the wavelength of the light used in the lithography process. In such a case, it is possible to function as an antireflection film having an effect of preventing reflected light from the substrate.

Furthermore, the resist underlayer film can also be used as a layer for preventing interaction between the substrate and the resist film (such as a photoresist film), a layer having a function of preventing a bad effect on the substrate of a material used for the resist film or a substance generated at the time of exposure to the resist film, a layer having a function of preventing diffusion of a substance generated from the substrate to the resist film at the time of heating and baking, a barrier layer for reducing the poising effect of the resist film by the semiconductor substrate dielectric layer, and the like.

The resist underlayer film can be applied to a substrate on which via holes used in the dual damascene process are formed, and can be used as a hole-filling material (filling material) capable of filling the holes without gaps. In addition, it can also be used as a planarizing material for planarizing the surface of a semiconductor substrate having irregularities.

In addition, the resist underlayer film of the present invention serves as an underlayer film for an EUV resist film and, for example, can prevent reflection of exposure light undesirable for EUV exposure (wavelength 13.5 nm), for example, UV (ultraviolet) light or DUV (deep ultraviolet) light (ArF light and KrF light) from the substrate or the interface without intermixing with the EUV resist film, in addition to the function as a hard mask. Therefore, in order to form an underlayer antireflection film of the EUV resist film, the composition for forming a silicon-containing resist underlayer film of the present invention can be suitably used. That is, reflection can be efficiently prevented as an underlayer of the EUV resist film. When used as the EUV resist underlayer film, the process can be performed in the same manner as the underlayer film for a photoresist.

By using the above described substrate for semiconductor processing including the resist underlayer film of the present invention and a semiconductor substrate, a semiconductor substrate can be suitably processed.

In addition, according to the above described method for manufacturing a semiconductor element, the method including: a step of forming an organic underlayer film; a step of forming a resist underlayer film on the organic underlayer film using the composition for forming a silicon-containing resist underlayer film of the present invention; and a step of forming a resist film on the resist underlayer film, a semiconductor substrate can be reproducibly processed with high accuracy, and it is expected that a semiconductor element can be stably produced.

### EXAMPLES

Hereinafter, the present invention will be described more specifically with reference to Synthesis Examples and Examples, but the present invention is not limited to only the following examples.

In Examples, devices and conditions used for analyzing physical properties of a sample are as follows.

### (1) Molecular Weight Measurement

The molecular weight of the polysiloxane used in the present invention is a molecular weight obtained in terms of polystyrene by GPC analysis.

The GPC measurement conditions can be performed using, for example, a GPC apparatus (trade name: HLC-8220GPC, manufactured by Tosoh Corporation), a GPC column (trade name: Shodex (registered trademark) KF803L, KF802, KF801, manufactured by Showa Denko K.K.), a column temperature of 40° C., tetrahydrofuran as an eluent (elution solvent), a flow amount (flow rate) of 1.0 mL/min, and polystyrene (manufactured by Showa Denko K.K.) as a standard sample.

### (2) ¹H-NMR

Evaluation was performed using a nuclear magnetic resonance apparatus ¹H-NMR (400 MHZ) manufactured by JEOL, and d6-Acetone as a solvent.

### [1] Synthesis of Polymer (Hydrolysis Condensate)

### Synthesis Example 1

A 300 ml flask was charged with 20.8 g of tetraethoxysilane, 5.9 g of methyltriethoxysilane, 4.2 g of 3-iodopropyltrimethoxysilane, and 55.9 g of propylene glycol monoethyl ether, and 8.4 g of a 0.2 M nitric acid aqueous solution was added dropwise to the resulting mixed solution while being stirred with a magnetic stirrer.

After the dropwise addition, the flask was transferred to an oil bath adjusted to 60° C. and refluxed for 20 hours. Thereafter, ethanol, methanol, and water as reaction by-products were distilled off under reduced pressure and concentrated to obtain a hydrolysis condensate (polymer) aqueous solution.

Further, propylene glycol monoethyl ether was added, the concentration was adjusted to 20 mass percent in terms of solid residue at 150° C. and the solvent ratio of propylene glycol monoethyl ether 100%, and filtration was performed with a nylon filter (pore size: 0.1 μm). The obtained polymer contained a structure represented by the following formula (E1), and the weight average molecular weight thereof was Mw: 2,300 in terms of polystyrene by GPC.

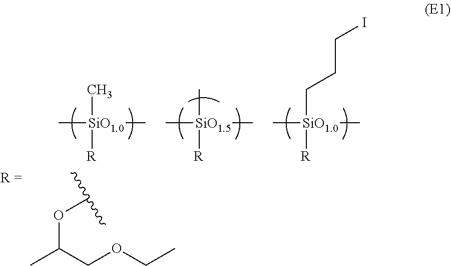

### Synthesis Example 2

A 300 ml flask was charged with 20.8 g of tetraethoxysilane, 2.6 g of methyltriethoxysilane, 4.2 g of 3-iodopropyltrimethoxysilane, 2.8 g of phenyltrimethoxysilane, and 56.4 g of propylene glycol monoethyl ether, and 8.4 g of a 0.2 M nitric acid aqueous solution was added dropwise to the resulting mixed solution while being stirred with a magnetic stirrer.

After the dropwise addition, the flask was transferred to an oil bath adjusted to 60° C. and refluxed for 20 hours. Thereafter, ethanol, methanol, and water as reaction by-products were distilled off under reduced pressure and concentrated to obtain a hydrolysis condensate (polymer) aqueous solution.

Further, propylene glycol monoethyl ether was added, the concentration was adjusted to 20 mass percent in terms of solid residue at 150° C. and the solvent ratio of propylene glycol monoethyl ether 100%, and filtration was performed with a nylon filter (pore size: 0.1 μm). The obtained polymer contained a structure represented by the following formula (E2), and the weight average molecular weight thereof was Mw: 2,700 in terms of polystyrene by GPC.

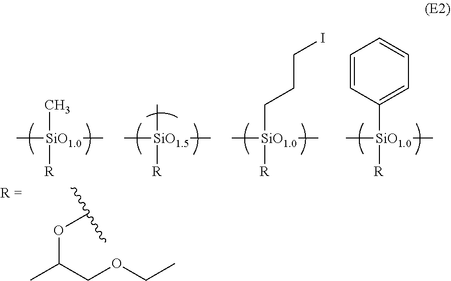

### Synthesis Example 3

A 300 ml flask was charged with 20.8 g of tetraethoxysilane, 2.6 g of methyltriethoxysilane, 4.2 g of 3-iodopropyltrimethoxysilane, 5.9 g of diallyl isocyanurate propyltriethoxysilane, and 62.1 g of propylene glycol monoethyl ether, and 8.4 g of a 0.2 M nitric acid aqueous solution was added dropwise to the resulting mixed solution while being stirred with a magnetic stirrer.

After the dropwise addition, the flask was transferred to an oil bath adjusted to 60° C. and refluxed for 20 hours. Thereafter, ethanol, methanol, and water as reaction by-products were distilled off under reduced pressure and concentrated to obtain a hydrolysis condensate (polymer) aqueous solution.

Further, propylene glycol monoethyl ether was added, the concentration was adjusted to 20 mass percent in terms of solid residue at 150° C. and the solvent ratio of propylene glycol monoethyl ether 100%, and filtration was performed with a nylon filter (pore size: 0.1 μm). The obtained polymer contained a structure represented by the following formula (E3), and the weight average molecular weight thereof was Mw: 2,200 in terms of polystyrene by GPC.

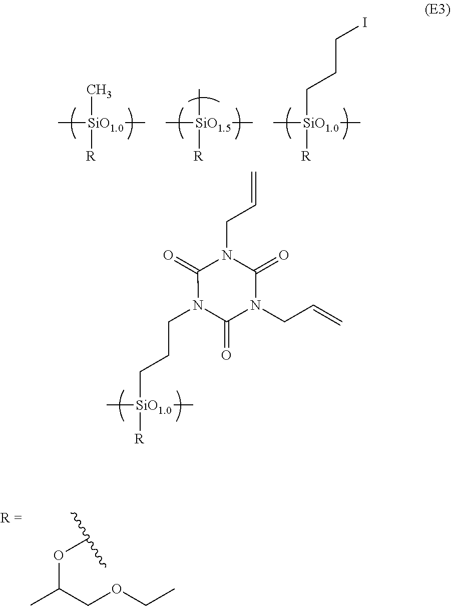

### Synthesis Example 4

A 300 ml flask was charged with 20.8 g of tetraethoxysilane, 2.6 g of methyltriethoxysilane, 4.2 g of 3-iodopropyltrimethoxysilane, 4.4 g of 2-[3-(triethoxysilyl) propyl]succinic anhydride, and 62.1 g of propylene glycol monoethyl ether, and 8.4 g of a 0.2 M nitric acid aqueous solution was added dropwise to the resulting mixed solution while being stirred with a magnetic stirrer.

After the dropwise addition, the flask was transferred to an oil bath adjusted to 60° C. and refluxed for 20 hours. Thereafter, ethanol, methanol, and water as reaction by-products were distilled off under reduced pressure and concentrated to obtain a hydrolysis condensate (polymer) aqueous solution.

Further, propylene glycol monoethyl ether was added, the concentration was adjusted to 20 mass percent in terms of solid residue at 150° C. and the solvent ratio of propylene glycol monoethyl ether 100%, and filtration was performed with a nylon filter (pore size: 0.1 μm). The obtained polymer contained a structure represented by the following formula (E4), and the weight average molecular weight thereof was Mw: 2,700 in terms of polystyrene by GPC.

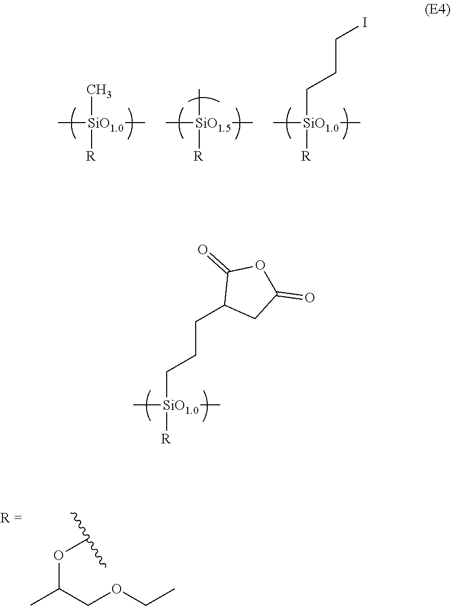

### Synthesis Example 5

A 300 ml flask was charged with 20.8 g of tetraethoxysilane, 7.6 g of methyltriethoxysilane, and 62.1 g of propylene glycol monoethyl ether, and 8.4 g of a 0.2 M nitric acid aqueous solution was added dropwise to the resulting mixed solution while being stirred with a magnetic stirrer.

After the dropwise addition, the flask was transferred to an oil bath adjusted to 60° C. and refluxed for 20 hours. Thereafter, ethanol and water as reaction by-products were distilled off under reduced pressure and concentrated to obtain a hydrolysis condensate (polymer) aqueous solution.

Further, propylene glycol monoethyl ether was added, the concentration was adjusted to 20 mass percent in terms of solid residue at 150° C. and the solvent ratio of propylene glycol monoethyl ether 100%, and filtration was performed with a nylon filter (pore size: 0.1 μm). The obtained polymer contained a structure represented by the following formula (E5), and the weight average molecular weight thereof was Mw: 2,400 in terms of polystyrene by GPC.

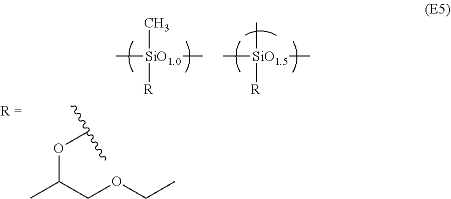

### Comparative Synthesis Example 1

A 300 ml flask was charged with 20.8 g of tetraethoxysilane, 5.1 g of methyltriethoxysilane, 11.3 g of 2-hydroxy-4-(2-(triethoxysilyl)ethyl)cyclohexyl-2,3,5-triiodobenzolate, and 52.8 g of propylene glycol monoethyl ether, and 8.4 g of a 0.2 M nitric acid aqueous solution was added dropwise to the resulting mixed solution while being stirred with a magnetic stirrer.

After the dropwise addition, the flask was transferred to an oil bath adjusted to 60° C. and refluxed for 20 hours. Thereafter, ethanol and water as reaction by-products were distilled off under reduced pressure and concentrated to obtain a hydrolysis condensate (polymer) aqueous solution.

Further, propylene glycol monoethyl ether was added, the concentration was adjusted to 20 mass percent in terms of solid residue at 150° C. and the solvent ratio of propylene glycol monoethyl ether 100%, and filtration was performed with a nylon filter (pore size: 0.1 μm). The obtained polymer contained a structure represented by the following formula (E6), and the weight average molecular weight thereof was Mw: 2, 800 in terms of polystyrene by GPC.

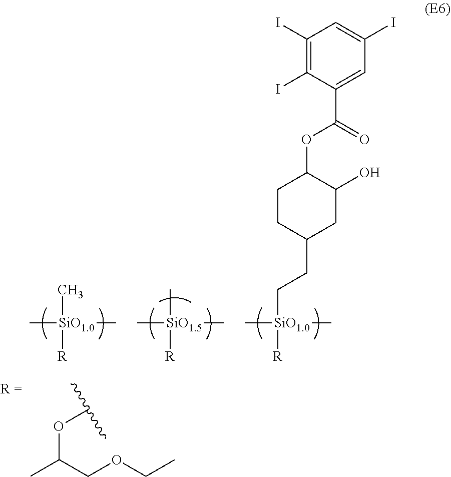

### Synthesis Example 6

A 300 ml flask was charged with 20.8 g of tetraethoxysilane, 2.6 g of methyltriethoxysilane, 4.2 g of 3-iodopropyltrimethoxysilane, 3.7 g of 5-(triethoxysilyl)-2-norbornene, and 57.9 g of propylene glycol monoethyl ether, and 8.4 g of a 0.2 M nitric acid aqueous solution was added dropwise to the resulting mixed solution while being stirred with a magnetic stirrer.

After the dropwise addition, the flask was transferred to an oil bath adjusted to 60° C. and refluxed for 20 hours. Thereafter, ethanol, methanol, and water as reaction by-products were distilled off under reduced pressure and concentrated to obtain a hydrolysis condensate (polymer) aqueous solution.

Further, propylene glycol monoethyl ether was added, the concentration was adjusted to 20 mass percent in terms of solid residue at 150° C. and the solvent ratio of propylene glycol monoethyl ether 100%, and filtration was performed with a nylon filter (pore size: 0.1 μm). The obtained polymer contained a structure represented by the following formula (E7), and the weight average molecular weight thereof was Mw: 2, 100 in terms of polystyrene by GPC.

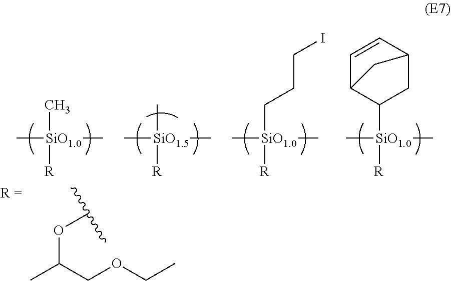

### Synthesis Example 7

A 300 ml flask was charged with 20.8 g of tetraethoxysilane, 2.6 g of methyltriethoxysilane, 4.2 g of 3-iodopropyltrimethoxysilane, 2.1 g of vinyltrimethoxysilane, and 55.5 g of propylene glycol monoethyl ether, and 8.4 g of a 0.2 M nitric acid aqueous solution was added dropwise to the resulting mixed solution while being stirred with a magnetic stirrer.

After the dropwise addition, the flask was transferred to an oil bath adjusted to 60° C. and refluxed for 20 hours. Thereafter, ethanol, methanol, and water as reaction by-products were distilled off under reduced pressure and concentrated to obtain a hydrolysis condensate (polymer) aqueous solution.

Further, propylene glycol monoethyl ether was added, the concentration was adjusted to 20 mass percent in terms of solid residue at 150° C. and the solvent ratio of propylene glycol monoethyl ether 100%, and filtration was performed with a nylon filter (pore size: 0.1 μm). The obtained polymer contained a structure represented by the following formula (E8), and the weight average molecular weight thereof was Mw: 2,700 in terms of polystyrene by GPC.

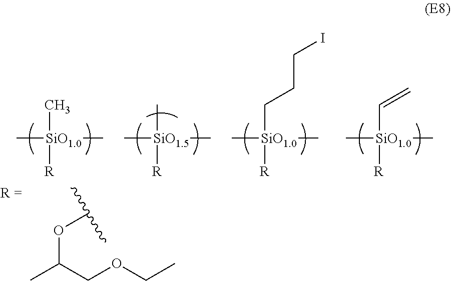

### Synthesis Example 8

A 300 ml flask was charged with 20.8 g of tetraethoxysilane, 2.6 g of methyltriethoxysilane, 4.2 g of 3-iodopropyltrimethoxysilane, 3.6 g of 3-(trimethoxysilyl) propyl methacrylate, and 57.7 g of propylene glycol monoethyl ether, and 8.4 g of a 0.2 M nitric acid aqueous solution was added dropwise to the resulting mixed solution while being stirred with a magnetic stirrer.

After the dropwise addition, the flask was transferred to an oil bath adjusted to 60° C. and refluxed for 20 hours. Thereafter, ethanol, methanol, and water as reaction by-products were distilled off under reduced pressure and concentrated to obtain a hydrolysis condensate (polymer) aqueous solution.

Further, propylene glycol monoethyl ether was added, the concentration was adjusted to 20 mass percent in terms of solid residue at 150° C. and the solvent ratio of propylene glycol monoethyl ether 100%, and filtration was performed with a nylon filter (pore size: 0.1 μm). The obtained polymer contained a structure represented by the following formula (E9), and the weight average molecular weight thereof was Mw: 2,500 in terms of polystyrene by GPC.

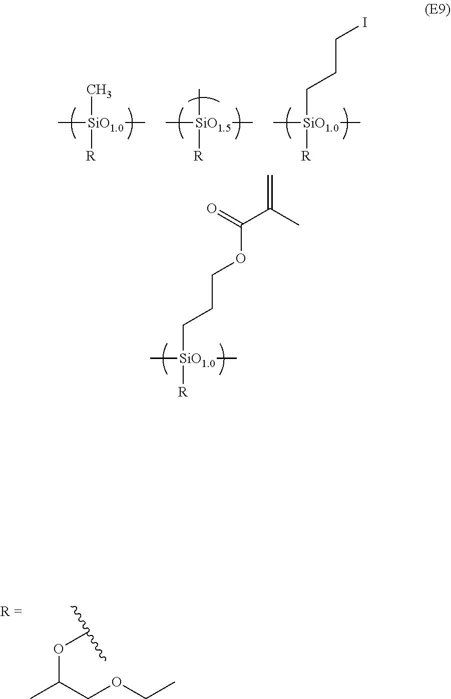

### [2] Preparation of Composition Applied to Resist Pattern

The polysiloxane (polymer) obtained in the above Synthesis Example, an acid (additive 1), a condensation catalyst (additive 2), a high-boiling-point glycol compound (additive 3), an iodine additive (additive 4), and a solvent were mixed in the ratio shown in Table 1, and the mixture was filtered with a 0.1 μm fluororesin filter to prepare each composition to be applied to a resist pattern. Each addition amount in Table 1 is shown in parts by mass.

The compositions were prepared under the condition that the hydrolysis condensate (polymer) was a solution containing the condensate obtained in Synthesis Example. However, the addition ratio of the polymer in Table 1 is not the addition amount of the polymer solution but the addition amount of the polymer itself.

DIW means ultrapure water, PGEE means propylene glycol monoethyl ether, and PGME means propylene glycol monomethyl ether.

Further, MA means maleic acid, IMTEOS means triethoxysilylpropyl-4,5-dihydroimidazole, TPSNO3 means triphenylsulfonium nitrate, TEGEE means triethylene glycol monoethyl ether, IPTMOS means 3-iodopropyltrimethoxysilane, 4-IBA means 4-iodobenzyl alcohol, IX means 1-N, 3-N-bis(2,3-dihydroxypropyl)-5-[N-(2,3-dihydroxypropyl) acetamide]-2,4,6-triiodobenzene-1,3-dicarboxamide, and IA means 3-amino-α-ethyl-2,4,6-triiodohydro cinnamic acid.

TABLE 1

| | | Additive | Additive | Additive | Additive | | | |
|---|---|---|---|---|---|---|---|---|
| Example | Polymer | 1 | 2 | 3 | 4 | Solvent | | |
| Example 1 | Synthesis | MA | TPSN03 | | | PGEE | PGME | DIW |
| | Example 1 | | | | | | | |
| (parts by mass) | 0.5 | 0.005 | 0.005 | | | 80 | 8 | 12 |
| Example 2 | Synthesis | MA | IMTEOS | | | PGEE | PGME | DIW |
| | Example 1 | | | | | | | |
| (parts by mass) | 0.5 | 0.005 | 0.0015 | | | 80 | 8 | 12 |
| Example 3 | Synthesis | MA | TPSN03 | TEGEE | | PGEE | PGME | DIW |
| | Example 1 | | | | | | | |
| (parts by mass) | 0.5 | 0.005 | 0.005 | 0.05 | | 80 | 8 | 12 |
| Example 4 | Synthesis | MA | TPSN03 | | | PGEE | PGME | DIW |
| | Example 2 | | | | | | | |
| (parts by mass) | 0.5 | 0.005 | 0.005 | | | 80 | 8 | 12 |
| Example 5 | Synthesis | MA | TPSN03 | | | PGEE | PGME | DIW |
| | Example 3 | | | | | | | |
| (parts by mass) | 0.5 | 0.005 | 0.005 | | | 80 | 8 | 12 |
| Example 6 | Synthesis | MA | TPSN03 | | | PGEE | PGME | DIW |
| | Example 4 | | | | | | | |
| (parts by mass) | 0.5 | 0.005 | 0.005 | | | 80 | 8 | 12 |
| Example 7 | Synthesis | MA | TPSN03 | | IPTMOS | PGEE | PGME | DIW |
| | Example 5 | | | | | | | |
| (parts by mass) | 0.5 | 0.005 | 0.005 | | 0.05 | 80 | 8 | 12 |
| Example 8 | Synthesis | MA | TPSN03 | | IPTMOS | PGEE | PGME | DIW |
| | Example 5 | | | | | | | |
| (parts by mass) | 0.5 | 0.005 | 0.005 | | 0.1 | 80 | 8 | 12 |
| Example 9 | Synthesis | MA | TPSN03 | | | PGEE | PGME | DIW |
| | Example 6 | | | | | | | |
| (parts by mass) | 0.5 | 0.005 | 0.005 | | | 80 | 8 | 12 |
| Example 10 | Synthesis | MA | TPSN03 | | | PGEE | PGME | DIW |
| | Example 7 | | | | | | | |
| (parts by mass) | 0.5 | 0.005 | 0.005 | | | 80 | 8 | 12 |
| Example 11 | Synthesis | MA | TPSN03 | | | PGEE | PGME | DIW |
| | Example 8 | | | | | | | |
| (parts by mass) | 0.5 | 0.005 | 0.005 | | | 80 | 8 | 12 |
| Comparative | Synthesis | MA | TPSN03 | | | PGEE | PGME | DIW |
| Example 1 | Example 5 | | | | | | | |
| (parts by mass) | 0.5 | 0.005 | 0.005 | | | 80 | 8 | 12 |
| Comparative | Comparative | MA | TPSN03 | | | PGEE | PGME | DIW |
| Example 2 | Synthesis | | | | | | | |
| | Example 1 | | | | | | | |
| (parts by mass) | 0.5 | 0.005 | 0.005 | | | 80 | 8 | 12 |
| Comparative | Synthesis | MA | TPSN03 | | 4-IBA | PGEE | PGME | DIW |
| Example 3 | Example 5 | | | | | | | |
| (parts by mass) | 0.5 | 0.005 | 0.005 | | 0.05 | 80 | 8 | 12 |
| Comparative | Synthesis | MA | TPSN03 | | IX | PGEE | PGME | DIW |
| Example 4 | Example 5 | | | | | | | |
| (parts by mass) | 0.5 | 0.005 | 0.005 | | 0.05 | 80 | 8 | 12 |
| Comparative | Synthesis | MA | TPSN03 | | IA | PGEE | PGME | DIW |
| Example 5 | Example 5 | | | | | | | |
| (parts by mass) | 0.5 | 0.005 | 0.005 | | 0.05 | 80 | 8 | 12 |

*Examples 1 to 11 and Comparative Examples 1 to 5 further contain nitric acid contained in the polymer solution prepared in Synthesis Examples.

### [3] Preparation of Composition for Forming Organic Underlayer Film

Carbazole (6.69 g, 0.040 mol, manufactured by Tokyo Chemical Industry Co., Ltd.), 9-fluorenone (7.28 g, 0.040 mol, manufactured by Tokyo Chemical Industry Co., Ltd.), and p-toluenesulfonic acid monohydrate (0.76 g, 0.0040 mol, manufactured by Tokyo Chemical Industry Co., Ltd.) were added to a 100 ml four-necked flask under nitrogen, and 1,4-dioxane (6.69 g, manufactured by KANTO CHEMICAL CO., INC.) was charged and stirred. The temperature was raised to 100° C., and the mixture was dissolved to initiate polymerization. After 24 hours, the mixture was allowed to cool to 60° C.

Chloroform (34 g, manufactured by KANTO CHEMICAL CO., INC.) was added to the cooled reaction mixture for dilution and the diluted mixture was added to methanol (168 g, manufactured by KANTO CHEMICAL CO., INC.) for precipitation.

The obtained precipitate was recovered by filtration, and the recovered solid was dried in a vacuum dryer at 80° C. for 24 hours to obtain 9.37 g of a desired polymer represented by the formula (X) (hereinafter, abbreviated as PCzFL).

The ¹H-NMR measurement results of PCzFL were as follows.

¹H-NMR (400 MHZ, DMSO-d₆): δ7.03-7.55 (br, 12H), δ7.61-8.10 (br, 4H), δ11.18 (br, 1H)

The weight average molecular weight Mw of PCzFL was 2,800 in terms of polystyrene by GPC, and the polydispersity Mw/Mn was 1.77.

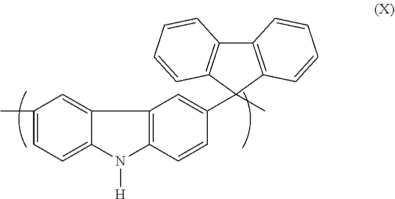

Twenty grams of PCzFL, 3.0 g of tetramethoxymethyl glycoluril (POWDER LINK 1174 (trade name); manufactured by NIPPON CYTEC INDUSTRIES (former MITSUI CYTEC)) as a crosslinking agent, 0.30 g of pyridinium paratoluenesulfonate as a catalyst, and 0.06 g of MEGAFACE R-30 (manufactured by DIC Corporation, trade name) as a surfactant were mixed, and the resulting mixture was dissolved in 88 g of propylene glycol monomethyl ether acetate to prepare a solution. Thereafter, the obtained solution was filtered using a polyethylene microfilter having a pore size of 0.10 μm, and further filtered using a polyethylene microfilter having a pore size of 0.05 μm to prepare a composition for forming an organic underlayer film.

### [4] Solvent Resistance Test

The compositions prepared in Examples 1 to 11 and Comparative Examples 1 to 5 were each applied onto a silicon wafer using a spinner. Si-containing resist underlayer films were each formed by heating at 215° C. for 1 minute on a hot plate, and the film thickness of the obtained resist underlayer film was measured. The film thickness was approximately 10 nm.

Thereafter, a mixed solvent of propylene glycol monomethyl ether/propylene glycol monomethyl ether acetate (7/3 (V/V)) was applied onto each resist underlayer film, and spin-dried. The film thickness of the underlayer film after application was measured, and the ratio (%) of the change in film thickness after application of the mixed solvent was calculated based on the film thickness before application of the mixed solvent (100%). A film having a film thickness change ratio of 1% or less before and after application of the mixed solvent was evaluated as “good”, and a film having a film thickness change ratio of more than 1% was evaluated as “not cured”.

The obtained results are shown in Table 2.

TABLE 2

| | Solvent resistance |
|---|---|
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Example 9 | Good |
| Example 10 | Good |
| Example 11 | Good |
| Comparative Example 1 | Good |
| Comparative Example 2 | Good |
| Comparative Example 3 | Good |
| Comparative Example 4 | Good |
| Comparative Example 5 | Good |

### [4] Formation of Resist Pattern by EUV Exposure: Positive Alkaline Development

The composition for forming an organic underlayer film was spin-coated on a silicon wafer, and heated on a hot plate at 215° C. for 1 minute to form an organic underlayer film (layer A) (film thickness: 90 nm).

The composition obtained in Example 1 was applied thereon by spin coating, and heated on a hot plate at 215° C. for 1 minute to form a resist underlayer film (B) layer (film thickness: 10 nm).

Further, a resist solution for EUV (tin oxide-based resist) was spin-coated thereon, and heated at 130° C. for 1 minute to form an EUV resist layer (C) layer. Thereafter, the layer was exposed using an EUV exposure apparatus (NXE3300B) manufactured by ASML under the conditions of NA=0.33, σ=0.67/0.90, and Dipole. At the time of exposure, exposure was performed through a mask set so that the line width and the inter-line width (space width) of the EUV resist were 16 nm after the following development, that is, so that a 16 nm line-and-space (L/S)=1/1 dense line was formed.

After the exposure, the film was subjected to post exposure bake (PEB, 170° C. for 1 min), cooled on a cooling plate to room temperature, developed for 60 seconds using an organic solvent (propylene glycol monomethyl ether acetate), and rinsed to form a resist pattern.

In the same procedure, a resist pattern was formed using each of the compositions obtained in Examples 2 to 11 and Comparative Examples 1 to 5.

Using a CD-SEM (CG4100) manufactured by Hitachi High-Technologies Corporation, the exposure amount at the time of formation with a line dimension of 16 nm was measured and taken as sensitivity, and the dimension of 60 lines at this time was measured to determine line width roughness (LWR). The results are shown in Table 3.

TABLE 3

| | Sensitivity | Roughness |
|---|---|---|
| | (mJ/cm2) | (nm) |
| Example 1 | 61 | 3.6 |
| Example 2 | 61 | 3.6 |
| Example 3 | 60 | 3.6 |
| Example 4 | 61 | 3.5 |
| Example 5 | 61 | 3.5 |
| Example 6 | 61 | 3.4 |
| Example 7 | 59 | 3.7 |
| Example 8 | 57 | 3.8 |
| Example 9 | 57 | 3.5 |
| Example 10 | 59 | 3.6 |
| Example 11 | 59 | 3.7 |
| Comparative Example 1 | 65 | 3.6 |
| Comparative Example 2 | 66 | 3.7 |
| Comparative Example 3 | 66 | 3.6 |
| Comparative Example 4 | 66 | 3.6 |
| Comparative Example 5 | 66 | 3.6 |

As shown in Table 3, it is found that when a polysiloxane film containing an alkyl group substituted with iodine and formed using the composition for forming a silicon-containing resist underlayer film containing a thermosetting silicon-containing material is used as a resist underlayer film, sensitivity can be improved without deterioration of LWR. On the other hand, the compositions of Comparative Examples 1 to 5 having no alkyl group substituted with iodine resulted in poor sensitivity.

1. A composition for forming a silicon-containing resist underlayer film, the composition comprising:
component [A]: a polysiloxane; and
component [C]: a solvent,
wherein the polysiloxane contains a constituent unit derived from a hydrolyzable silane (A) having an alkyl iodide group.

2. A composition for forming a silicon-containing resist underlayer film, the composition comprising:
component [A′]: a polysiloxane;
component [B]: a hydrolyzable silane (A) having an alkyl iodide group; and
component [C]: a solvent.

3. The composition for forming a silicon-containing resist underlayer film according to claim 1, wherein the hydrolyzable silane (A) having an alkyl iodide group is a compound represented by the following formula (A-1): 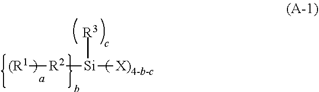
wherein, in the formula (A-1), “a” and “b” each independently represent an integer of 1 to 3,
“c” represents an integer of 0 to 2,
“b+c” represents an integer of 1 to 3,
R¹ represents an alkyl iodide group,
when “a” is 1, R² represents a single bond or a (a+1)-valent group other than a saturated hydrocarbon group, and when “a” is 2 or 3, R² represents a (a+1)-valent group other than a saturated hydrocarbon group,
R³ represents: an optionally substituted alkyl group, an optionally substituted aryl group, an optionally substituted aralkyl group, an optionally substituted halogenated alkyl group (excluding an alkyl iodide group), an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group; an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group; or a combination of two or more thereof,
X represents an alkoxy group, an aralkyloxy group, an acyloxy group, or a halogen atom, and
for a plurality of each of R¹, R², R³, and X, the plurality of R¹, R², R³, and X may be the same or different.

4. The composition for forming a silicon-containing resist underlayer film according to claim 3, wherein the compound represented by the formula (A-1) is a compound represented by the following formula (A-2): 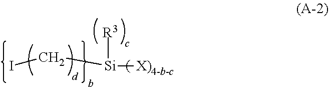
wherein, in the formula (A-2), “b” represents an integer of 1 to 3,
“c” represents an integer of 0 to 2,
“d” represents an integer of 1 to 20,
“b+c” represents an integer of 1 to 3,
R³ represents: an optionally substituted alkyl group, an optionally substituted aryl group, an optionally substituted aralkyl group, an optionally substituted halogenated alkyl group (excluding an alkyl iodide group), an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group; an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group; or a combination of two or more thereof,
X represents an alkoxy group, an aralkyloxy group, an acyloxy group, or a halogen atom, and
for a plurality of each of R³, X, and a group of —(CH₂)_{d}—I, the plurality of R³, X, and a group of —(CH₂)_{d}—I may be the same or different.

5. The composition for forming a silicon-containing resist underlayer film according to claim 1, wherein the component [C] contains an alcohol-based solvent.

6. The composition for forming a silicon-containing resist underlayer film according to claim 5, wherein the component [C] contains propylene glycol monoalkyl ether.

7. The composition for forming a silicon-containing resist underlayer film according to claim 1, the composition further comprising component [D]: a curing catalyst.

8. The composition for forming a silicon-containing resist underlayer film according to claim 1, the composition further comprising component [E]: nitric acid.

9. The composition for forming a silicon-containing resist underlayer film according to claim 1, wherein the component [C] contains water.

10. The composition for forming a silicon-containing resist underlayer film according to claim 1, which is for forming a resist underlayer film for EUV lithography.

11. The composition for forming a silicon-containing resist underlayer film according to claim 1, which is used in EUV lithography using a metal oxide resist.

12. A resist underlayer film, which is a cured product of the composition for forming a silicon-containing resist underlayer film according to claim 1.

13. A substrate for semiconductor processing, comprising: a semiconductor substrate; and the resist underlayer film according to claim 12.

14. A method for manufacturing a semiconductor element, the method comprising:
a step of forming an organic underlayer film on a substrate;
a step of forming a resist underlayer film on the organic underlayer film using the composition for forming a silicon-containing resist underlayer film according to claim 1; and
a step of forming a resist film on the resist underlayer film.

15. The method for manufacturing a semiconductor element according to claim 14, wherein, in the step of forming a resist underlayer film, a composition for forming a silicon-containing resist underlayer film filtered through a nylon filter is used.

16. A patterning process comprising:
a step of forming an organic underlayer film on a semiconductor substrate;
a step of forming a resist underlayer film by applying and baking the composition for forming a silicon-containing resist underlayer film according to claim 1 on the organic underlayer film;
a step of forming a resist film by applying a composition for forming a resist film on the resist underlayer film;
a step of obtaining a resist pattern by exposing and developing the resist film;
a step of etching the resist underlayer film by using the resist pattern as a mask; and
a step of etching the organic underlayer film by using the patterned resist underlayer film as a mask.

17. The patterning process according to claim 16, further comprising
a step of removing the resist underlayer film by a wet method using a chemical liquid after the step of etching the organic underlayer film.

18. The composition for forming a silicon-containing resist underlayer film according to claim 2, wherein the hydrolyzable silane (A) having an alkyl iodide group is a compound represented by the following formula (A-1): 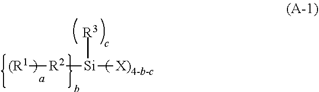
wherein, in the formula (A-1), “a” and “b” each independently represent an integer of 1 to 3,
“c” represents an integer of 0 to 2,
“b+c” represents an integer of 1 to 3,
R¹ represents an alkyl iodide group,
when “a” is 1, R² represents a single bond or a (a+1)-valent group other than a saturated hydrocarbon group, and when “a” is 2 or 3, R² represents a (a+1)-valent group other than a saturated hydrocarbon group,
R³ represents: an optionally substituted alkyl group, an optionally substituted aryl group, an optionally substituted aralkyl group, an optionally substituted halogenated alkyl group (excluding an alkyl iodide group), an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group; an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group; or a combination of two or more thereof,
X represents an alkoxy group, an aralkyloxy group, an acyloxy group, or a halogen atom, and
for a plurality of each of R¹, R², R³, and X, the plurality of R¹, R², R³, and X may be the same or different.

19. The composition for forming a silicon-containing resist underlayer film according to claim 18, wherein the compound represented by the formula (A-1) is a compound represented by the following formula (A-2): 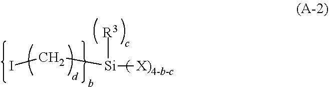
wherein, in the formula (A-2), “b” represents an integer of 1 to 3,
“c” represents an integer of 0 to 2,
“d” represents an integer of 1 to 20,
“b+c” represents an integer of 1 to 3,
R³ represents: an optionally substituted alkyl group, an optionally substituted aryl group, an optionally substituted aralkyl group, an optionally substituted halogenated alkyl group (excluding an alkyl iodide group), an optionally substituted halogenated aryl group, an optionally substituted halogenated aralkyl group, an optionally substituted alkoxyalkyl group, an optionally substituted alkoxyaryl group, an optionally substituted alkoxyaralkyl group, or an optionally substituted alkenyl group; an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group; or a combination of two or more thereof,
X represents an alkoxy group, an aralkyloxy group, an acyloxy group, or a halogen atom, and
for a plurality of each of R³, X, and a group of —(CH₂)_{d}—I, the plurality of R³, X, and a group of —(CH₂)_{d}—I may be the same or different.

20. The composition for forming a silicon-containing resist underlayer film according to claim 2, which is for forming a resist underlayer film for EUV lithography.

21. The composition for forming a silicon-containing resist underlayer film according to claim 2, which is used in EUV lithography using a metal oxide resist.

22. A resist underlayer film, which is a cured product of the composition for forming a silicon-containing resist underlayer film according to claim 2.

23. A substrate for semiconductor processing, comprising: a semiconductor substrate; and the resist underlayer film according to claim 22.

24. A method for manufacturing a semiconductor element, the method comprising:
a step of forming an organic underlayer film on a substrate;
a step of forming a resist underlayer film on the organic underlayer film using the composition for forming a silicon-containing resist underlayer film according to claim 2; and
a step of forming a resist film on the resist underlayer film.

25. The method for manufacturing a semiconductor element according to claim 24, wherein, in the step of forming a resist underlayer film, a composition for forming a silicon-containing resist underlayer film filtered through a nylon filter is used.

26. A patterning process comprising:
a step of forming an organic underlayer film on a semiconductor substrate;
a step of forming a resist underlayer film by applying and baking the composition for forming a silicon-containing resist underlayer film according to claim 2 on the organic underlayer film;
a step of forming a resist film by applying a composition for forming a resist film on the resist underlayer film;
a step of obtaining a resist pattern by exposing and developing the resist film;
a step of etching the resist underlayer film by using the resist pattern as a mask; and
a step of etching the organic underlayer film by using the patterned resist underlayer film as a mask.

27. The patterning process according to claim 26, further comprising
a step of removing the resist underlayer film by a wet method using a chemical liquid after the step of etching the organic underlayer film.
